(19) United States
(12) Patent Application Publication
(10) Pub. No.: US 2020/0343453 A1
(43) Pub. Date: Oct. 29, 2020

(54) LIGHT-EMITTING MATERIAL, ORGANIC LIGHT-EMITTING ELEMENT, AND COMPOUND

(71) Applicants: KYUSHU UNIVERSITY, NATIONAL UNIVERSITY CORPORATION, Fukuoka-shi, Fukuoka (JP); HODOGAYA CHEMICAL CO., LTD., Tokyo (JP)

(72) Inventors: Youichi TSUCHIYA, Fukuoka-shi (JP); Yan GENG, Fukuoka-shi (JP); Hin Wai MO, Fukuoka-shi (JP); Chihaya ADACHI, Fukuoka-shi (JP); Takehiro TAKAHASHI, Tokyo (JP)

(73) Assignees: Kyushu University, University Corporation, Fukuoka-shi, Fukuoka (JP); Hodogaya Chemical Co., Ltd., Tokyo (JP)

(21) Appl. No.: 16/083,633

(22) PCT Filed: Mar. 10, 2017
(86) PCT No.: PCT/JP2017/009762

§ 371 Date: Sep. 10, 2018

(30) Foreign Application Priority Data
Mar. 11, 2016 (JP) 2016-048057

(51) Int. Cl. H01L 51/00; H01L 51/50

(52) U.S. Cl. CPC H01L 51/0072; H01L 2251/552; H01L 51/0069; H01L 51/5004

(57) ABSTRACT

A compound having two or more donor groups differing in the structure and a linking group that links these donor groups, wherein the linking group is an aromatic group composed of one or more benzene rings optionally substituted with an alkyl group or a halogeno group, has good light-emitting characteristics.

### TECHNICAL FIELD

The present invention relates to a compound useful as a light-emitting material, and to an organic light-emitting device using the compound.

### BACKGROUND ART

Studies for enhancing the light emission efficiency of organic light-emitting devices such as organic electroluminescent devices (organic EL devices) are being made actively. In particular, investigations of molecular structures of organic compounds to the light-emitting materials have been actively promoted, focusing on the charge transfer and the energy state in molecules, and as a result, some compound groups capable of providing a high light emission efficiency have been found out.

For example, as such a compound group, there has been proposed a compound group having a linked structure of a donor group and an acceptor group. When the compound having such a structure is made to be in an excited state by the carrier recombination energy supplied from each electrode of an organic electroluminescent device, an electron transfers from the donor group to the acceptor group. Subsequently, the compound in an excited state deactivates while emitting light, and at the same time, the electron transferred. to the acceptor group returns back to the donor group. In that manner, the compounds included in the compound group have such a characteristic that an electron moves between the donor group and the acceptor group depending on the energy state, and by changing the chemical structure and the configuration of the donor group and the acceptor group, various energy levels can be controlled. Accordingly, it is said that light emission efficiency can be markedly improved (NPL 1).

### CITATION LIST

### Non-Patent Literature

NPL 1: Nature 492, 234-238

### SUMMARY OF INVENTION

### Technical Problem

Heretofore, various organic compounds have been proposed for light-emitting materials, but as mentioned above, it has been considered that organic compounds capable of realizing efficient light emission would be compounds having a donor group and an acceptor group. Consequently, in recent development and molecular design of light-emitting materials, search of useful compounds has been made entirely on the presumption that they have a donor group and an acceptor group.

Given the situation, the present inventors have promoted studies of a compound group having a donor group but not having an acceptor group in point of the usefulness thereof as a light-emitting material, and have repeated the studies for finding out a compound excellent in light emission characteristics. With that, the inventors have drawn a conclusion about a common characteristic of the structure of a compound useful as a light-emitting material, and have further promoted assiduous studies for the purpose of generalizing the structure of an organic light-emitting device having a high light emission efficiency.

### Solution to Problem

As a result of assiduous studies, the present inventors have found that a compound which has two or more donor groups differing from each. other in point of the structure and linking to each other via a linking group and which does not have an acceptor group has an excellent property as a light-emitting material. In addition, the inventors have clarified that by using such a compound as a light-emitting material, an organic light-emitting device having a high light emission efficiency can be provided. Based on these findings, the present inventors have achieved the present invention as mentioned below, as a means for solving the above-mentioned problems.
[1] A light-emitting material containing a compound having two or more donor groups and one or more linking groups, wherein:

the compound has donor groups differing from each other in point of the structure, and

the linking group is an aromatic group composed of one or more benzene rings optionally substituted with an alkyl group or a halogen group.
[2] The light-emitting material according to [1], wherein the compound has donor groups differing from each other in point of the structure.
[3] The light-emitting material according to [1] or [2], wherein the compound has a structure represented by the following general formula (1).

L¹[-D¹{-L²-(D^{2′}-L^{2′})ₙ₁-D²}ₙ₂]ₘ General Formula (1)
[In the general formula (1), L¹, L² and L^{2′} each independently represent an aromatic group composed of one or more benzene rings optionally substituted with an alkyl group or a halogeno group. D¹, D² and D^{2′} each independently represent a donor group. However, at least two donor groups existing in the molecule of the compound having the structure represented by the general formula (1) each have a different structure. m represents an integer of 2 or more. n1 represents an integer of 0 or more, and n2 represents an integer of 0 or more. When m is 2 or more, plural D¹s, L²s, D^{2′}s, L^{2′}s, D²s, n1's and n2's each may be the same or different. When n1 is 2 or more, plural D^{2′}s and L^{2′}s each may be the same or different. When n2 is 2 or more, plural L²s, D^{2′}s, L^{2′}s, D²s and n1's each may be the same or different.]
[4] The light-emitting material according to [1] or [2], wherein the compound has a structure represented by the following general formula (2).

D^{1′}-L¹-D¹{-L²-D²}_{n2′} General Formula (2)
[In the general formula (2), L¹ and L² each independently represent an aromatic group composed of one or more benzene rings optionally substituted with an alkyl group or a halogeno group. D^{1′}, D¹ and D² each independently represent a donor group. However, at least two donor groups existing in the molecule of the compound having the structure represented by the general formula (2) each have a different structure. n2′ represents 0 or 1.]
[5] The light-emitting material according to [3] or [4], wherein L¹ represents a phenylene group or a biphenylene group optionally substituted with an alkyl group or a halogeno group.
[6] The light-emitting material according to [1] or [2], wherein the compound has a structure represented by the following general formula (3).

D^{1′}-Ph¹-D¹{-L²-D²}_{n2′} General Formula (3)
[In the general formula (3), Ph¹ represents a phenylene group optionally substituted with an alkyl group or a halogen group. D^{1′}, D¹ and D² each independently represent a donor group except a substituted or unsubstituted diarylamino group. However, at least two donor groups existing in the molecule of the compound having the structure represented by the general formula (3) each have a different structure. n2′ represents 0 or 1.]
[7] The light-emitting material according to any one of [4] to [6], wherein D^{1′}, D¹ and D² each independently have an aromatic polycyclic structure.
[8] The light-emitting material according to [7], wherein the aromatic polycyclic structure is an aromatic polycondensed cyclic structure.
[9] The light-emitting material according to any one of [4] to [8], wherein D^{1′}, D¹ and D² each independently represent a group composed of only two or more kinds of atoms selected from the group consisting of a hydrogen atom, a carbon atom, a nitrogen atom, an oxygen atom and a sulfur atom.
[10] The light-emitting material according to [9], wherein at least one of D^{1′}, D¹ and D² is a group composed of only a hydrogen atom and a carbon atom, and at least the remaining one is a group composed of only a hydrogen atom, a carbon atom and a nitrogen atom, or a group composed of only one or more atoms selected from an oxygen atom and a sulfur atom, and a hydrogen atom, a carbon atom and a nitrogen atom.
[11] The light-emitting material according to any one of [4] to [10], wherein D¹ is a group bonding to the linking group via a nitrogen atom, and D^{1′} is a group bonding to the linking group via a carbon atom.
[12] The light-emitting material according to [11], wherein D² is a group bonding to the linking. group via a carbon atom.
[13] The light-emitting material according to any one of [4] to [10], wherein D¹ is a group bonding to the linking group via a carbon atom, and D^{1′} is a group bonding to the linking group via a nitrogen atom.
[14] The light-emitting material according to [13], wherein D² is a group bonding to the linking group via a nitrogen atom.
[15] The light-emitting material according to any one of [11] to [14], wherein the group bonding to the linking group via a carbon atom is a group bonding to the linking group via the carbon atom constituting the ring structure of a benzene ring.
[16] The light-emitting material according to any one of [11] to [15], wherein the group bonding to the linking group via a nitrogen atom is a group represented by the following general formula (4) or (5).

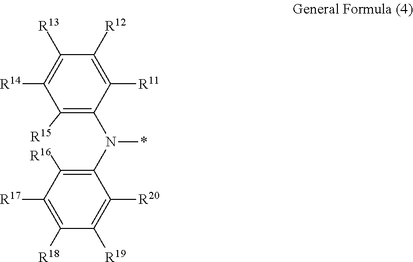

[In the general formula (4), R¹¹ to R²⁰ each independently represent a hydrogen atom or a substituent. R¹⁵ and R¹⁶ bond to each other to form a cyclic structure. R¹¹ and R¹², R¹² and R¹³, R¹³ and R¹⁴, R¹⁷ and R¹⁸, R¹⁸ and R¹⁹, and R¹⁹ and R²⁰ each may bond to each other to form a cyclic structure. * represents a bonding position to the linking group. In the case where the group bonding to the linking group via the nitrogen atom is divalent, the group further bonds at any of R¹¹ to R²⁰.]

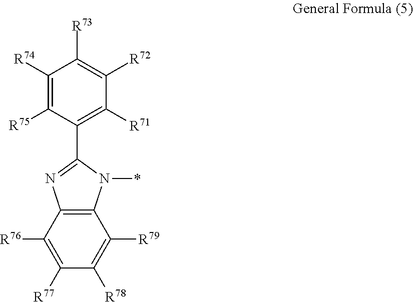

[In the general formula (5), R⁷¹ to R⁷⁹ each independently represent a hydrogen atom or a substituent. R⁷¹ and R⁷², R⁷² and R⁷³, R⁷³ and R⁷⁴, R⁷⁴ and R⁷⁵, R⁷⁶ and R⁷⁷, R⁷⁷ and R⁷⁸, and R⁷⁸ and R⁷⁹ each may bond to each other to form a cyclic structure. * represents a bonding position to the linking group. In the case where the group bonding to the linking group via the nitrogen atom is divalent, the group further bonds at any of R⁷¹ to R⁷⁹.]
[17] The light-emitting material according to any one of [11] to [15], wherein the group bonding to the linking group via the nitrogen atom is a group represented by any of the following general formulae (6) to (10).

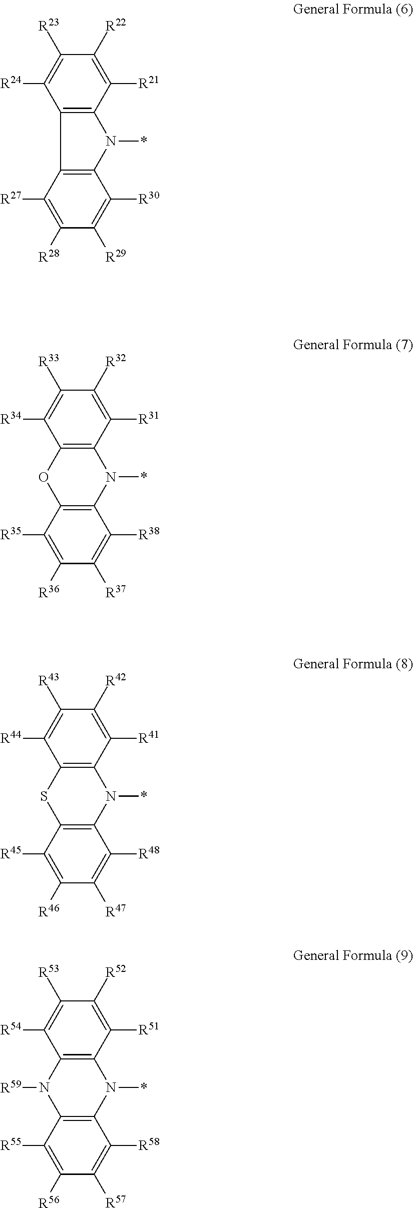

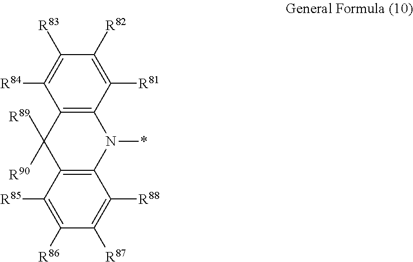

[In the general formulae (6) to (10), R²¹ to R²⁴, R²⁷ to R³⁸, R⁴¹ to R⁴⁸, R⁵¹ to R⁵⁹, and R⁸¹ to R⁹⁰ each independently represent a hydrogen atom or a substituent. R²¹ and R²², R²² and R²³, R²³ and R²⁴, R²⁷ and R²⁸, R²⁸ and R²⁹, R²⁹ and R³⁰, R³¹ and R³², R³² and R³³, R³³ and R³⁴, R³⁵ and R³⁶, R³⁶ and R³⁷, R³⁷ and R³⁸, R⁴¹ and R⁴², R⁴² and R⁴³, R⁴³ and R⁴⁴, R⁴⁵ and R⁴⁶, R⁴⁶ and R⁴⁷, R⁴⁷ and R⁴⁸, R⁵¹ and R⁵², R⁵² and R⁵³, R⁵³ and R⁵⁴, R⁵⁵ and R⁵⁶, R⁵⁶ and R⁵⁷, R⁵⁷ and R⁵⁸, R⁵⁴ and R⁵⁹, R⁵⁵ and R⁵⁹, R⁸¹ and R⁸², R⁸² and R⁸³, R⁸³ and R⁸⁴, R⁸⁵ and R⁸⁶, R⁸⁶ and R⁸⁷, R⁸⁷ and R⁸⁸, and R⁸⁹ and R⁹⁰ each may bond to each other to form a cyclic structure. * represents a bonding position to the linking group. In the case where the group bonding to the linking group via the nitrogen atom is divalent, the group further bonds at any of R²¹ to R²⁴, R²⁷ to R³⁸, R⁴¹ to R⁴⁸, R⁵¹ to R⁵⁹, and R⁸¹ to R⁹⁰.]
[18] The light-emitting material according to any one of [11] to [17], wherein the group bonding to the linking group via a carbon atom is a group represented by the following general formulae (11).

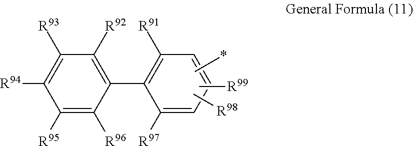

[In the general formula (11), R⁹¹ to R⁹⁹ each independently represent a hydrogen atom or a substituent. R⁹¹ and R⁹², R⁹² and R⁹³, R⁹³ and R⁹⁴, R⁹⁴ and R⁹⁵, R⁹⁵ and R⁹⁶, R⁹⁶ and R⁹⁷, R⁹⁷ and R⁹⁸, R⁹⁸ and R⁹⁹, and R⁹¹ and R⁹⁹ each may bond to each other to form a cyclic structure. * represents a bonding position to the linking group. In the case where the group bonding to the linking group via a carbon atom is divalent, the group further bonds at any of R⁹¹ to R⁹⁹.]
[19] The light-emitting material according to any one of [1] to [18], wherein the energy difference between HOMO and LUMO of the compound is 2.5 to 3.6 eV.
[20] The light-emitting material according to any one of [1] to [19], wherein the energy level of HOMO of the compound is −5.7 eV or more.
[21] The light-emitting material according to any one of [1] to [19], wherein the energy level of HOMO of the compound is −5.3 eV or more.
[22] The light-emitting material according to any one of [1] to [21], wherein the difference ΔE_{ST} between the lowest excited singlet energy level E_{S1} and the lowest excited triplet energy level E_{T1} of the compound is 0.3 eV or less.
[23] An organic light-emitting device containing the light-emitting material of any one of [1] to [22] in the light-emitting layer as a light emitting material therein.
[24] A compound represented by the general formula (3).

### Advantageous Effects of Invention

The light-emitting material of the present invention is, though composed of a compound not having an acceptor group, able to emit light efficiently.

The compound of the present invention is useful as a light-emitting material. The organic light-emitting device using the compound of the present invention as a light-emitting material can realize a high light emission efficiency.

### BRIEF DESCRIPTION OF DRAWINGS

FIG. 1 This is a schematic cross-sectional view showing a layer configuration example of an organic electroluminescent device.

FIG. 2 This shows light emission spectra of a solid organic thin film of the compound 2 (Example 12) and an organic electroluminescent device using the compound 2 in the light-emitting layer (Example 14).

FIG. 3 This is a graph showing a current density-external quantum efficiency characteristic of an organic electroluminescent device using the compound 2 in the light-emitting layer (Example 14).

FIG. 4 This shows light emission spectra of a solid organic thin film of the compound 11 and DPEPO (Example 13) and an organic electroluminescent device using the compound 11 and DPEPO in the light-emitting layer (Example 18).

FIG. 5 This is a graph showing a voltage-current density-luminance characteristic of an organic electroluminescent device using the compound 11 and DPEPO in the light-emitting layer (Example 18).

FIG. 6 This is a graph showing a current density-external quantum efficiency characteristic of an organic electroluminescent device using the compound 11 and DPEPO in the light-emitting layer (Example 18).

### DESCRIPTION OF EMBODIMENTS

The contents of the invention will be described in detail below. The constitutional elements may be described below with reference to representative embodiments and specific examples of the invention, but the invention is not limited to the embodiments and the examples. In the description, a numerical value range expressed using “A to B” denotes a range including numerical values before and after “to” as a minimum value and a maximum value, respectively. The hydrogen atom that is present in a molecule of the compound used in the invention is not particularly limited in isotope species, and for example, all the hydrogen atoms in the molecule may be ¹H, and all or a part of them may be ²H (deuterium D).

### [Light-Emitting Material]

The light-emitting material of the present invention is a light-emitting material composed of a compound having two or more donor groups and one or more linking group (hereinafter referred to as “the compound of the present invention”). The compound of the present invention has donor groups differing from each other in point of the structure. The linking group is an aromatic group that links at least. two donor groups, and is composed of one or more benzene rings optionally substituted with an alkyl group or a halogeno group.

The “donor group” constituting the compound of the present invention means an atom or an atomic group that constitutes a part of the compound and has a function of donating the electron that the atom has, to the atomic group constituting the other part of the compound. The compound of the present invention has two or more such donor groups in the molecule. The number of the donor groups that the compound has is preferably 2 or more, more preferably 2 to 4, and even more preferably 2 or 3.

The compound of the present invention has donor groups differing from each other in point of the structure. Specifically, each donor group that the compound of the present invention has differs from at least one other donor group that the compound has in point of the structure. Each donor group that the compound of the present invention has may differ to all the other donor groups that the compound has in point of the structure, or may differ from only a part of the other donor groups in point of the structure and may be the same as the other part thereof in point of the structure.

The donor groups differing from each other in point of the structure differ from each other in point of the electron-donating intensity. For the electron-donating intensity, an oxidation-reduction potential may be referred to as an index. For example, plural compounds each having the following structure and having a different donor group D are synthesized, and the oxidation-reduction potential thereof is measured, and the electron-donating intensity of each donor group D may be thereby compared with each other. The donor groups differing from each other in point of the structure and existing in the compound of the present invention are preferably such that the difference in the oxidation-reduction potential thus measured between them is 0.01 V or more, more preferably, 0.05 V or more, even more preferably 0.1 V or more, still more preferably 0.2 V or more. Also preferably, the difference in the oxidation-reduction potential between the donor groups differing from each other in the structure is 1.5 V or less, more preferably 1.2 V or less, even more preferably 1.0 V or less.

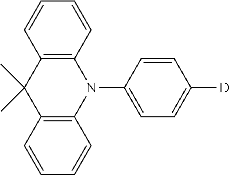 [SMILES: [2H]c1ccc(N2c3ccccc3C(C)(C)c3ccccc32)cc1]

The donor groups existing in the compound of the present invention each have a Hammett σₚ⁺ value of less than 0, preferably less than −0.15, more preferably less than −0.3, even more preferably −0.45 or less, still more preferably −0.6 or less.

The “Hammett σₚ⁺ value” in the present invention is one advocated by L. P. Hammett, and is one that quantifies the influence of the substituent on the reaction speed or the equilibrium of a para-substituted benzene derivative. Specifically, the value is a constant (σₚ) specific to the substituent in the following formula that indicates the relationship between the substituent in a para-substituted benzene derivative and the reaction speed constant or the equilibrium constant of the derivative.

log(k/k₀)=ρσₚ or log(K/K₀)=ρσₚ

In the above formulae, k represents a speed constant of a benzene derivative not having a substituent, k₀ represents a speed constant of a benzene derivative substituted with a substituent, K represents an equilibrium constant of a benzene derivative not having a substituent, K₀ represents an equilibrium constant of a benzene derivative substituted with a substituent, and ρ represents a reaction constant to be determined depending on the kind of the reaction and the condition thereof. Regarding the description relating to the Hammett σₚ⁺ value and the numerical value of each substituent, reference is made to J. A. Dean, “Lange's Handbook of Chemistry, 13th Ed.”, 1985, pp. 3-132 to 3-137, McGraw-Hill.

Regarding the preferred range of the chemical structure of the donor group, the preferred range of the donor group that may be represented by D¹, D² and D^{2′} in the general formula (1) to be mentioned below may be referred to.

The linking group in the compound of the present invention is one that links at least two donor groups to each other. The compound of the present invention contains such a linking group and donor groups, and is characterized in that the compound does not contain a group having a high electron-accepting performance (acceptor group) which has heretofore been considered to be indispensable in conventional light-emitting materials. In the present invention, such a compound is used in a light-emitting material, and accordingly, the range of the compound that may be used in a light-emitting material is enlarged and, in addition, the light-emitting material containing the compound of the type is expected to have light emission characteristics not attained by conventional light-emitting materials, that is, the present invention can realize a light-emitting material having an extremely high utility value.

In the present invention, the term “acceptor group” means a group not belonging to any of the above-mentioned donor group and the linking group. The “donor group” in the present invention does not contain the alkyl group and the halogeno group with which the benzene ring to constitute the linking group is substituted.

The compound of the present invention does not have a group having a Hammett σₚ⁺ value of more than 0.3 in the molecule, and preferably does not have a group having a Hammett σₚ⁺ value of more than 0.2 in the molecule, even more preferably does not have a group having a Hammett σₚ⁺ value of more than 0.1 in the molecule, further more preferably dues not have a group having a Hammett σₚ⁺ value of more than 0.05 in the molecule, and still further more preferably does not have a group having a Hammett σₚ⁺ value of more than 0 in the molecule.

The linking group may link two donor groups, or may radially link three or more donor groups. The number of the donor groups that the linking group links is preferably 2 to 6, more preferably 2 to 4, even more preferably 2 or 3, and especially preferably 2. Along with donor groups, the linking group may form a linear structure in which the donor groups and the linking groups repeatedly and sequentially bond to each other.

The linking group is an aromatic group composed of one or more benzene rings optionally substituted with an alkyl group or a halogeno group. The alkyl group referred to herein is preferably an alkyl group having 1 to 20 carbon atoms, more preferably an alkyl group having 1 to 6 carbon atoms. Specifically, examples thereof include a methyl group, an ethyl group, an n-propyl group, an isopropyl group, an n-butyl group, an isobutyl group, and a t-butyl group. The halogeno group includes a group of a fluorine atom, a chlorine atom, a bromine atom or an iodine atom. Between the halogeno group and the alkyl group, the alkyl group is preferably employed. An unsubstituted form where the benzene group is riot substituted may also be employed here.

One benzene ring may constitute the aromatic group, or 2 or more benzene rings may constitute it. In the case where 2 or more benzene rings constitute the aromatic group, the benzene rings may bond to each other, or may be condensed. Preferably, the benzene rings bond to each other. One example of the type is a biphenylene structure. Preferably, the aromatic group is composed of a benzene ring optionally substituted with an alkyl group or a halogeno group, and more preferably, the aromatic group is composed of a benzene ring optionally substituted with an alkyl group.

The compound of the present invention has one or more such linking groups in the molecule. The number of the linking groups that the compound of the present invention has is preferably 1 to 5, more preferably 1 to 3, and even more preferably 1 or 2.

The compound that constitutes the light-emitting material of the present invention preferably has a structure represented by the following general formula (1).

L¹[-D¹{-L²-(D^{2′}-L^{2′})ₙ₁-D²}ₙ₂]ₘ General Formula (1)

In the general formula (1), L¹, L² and L^{2′} each independently represent an aromatic group composed of one or more benzene rings optionally substituted with an alkyl group or a halogeno group. The aromatic group as referred to herein is a linking group having a stricture derived from an aromatic compound composed of one or more benzene rings by removing therefrom the hydrogen atom corresponding to the bonding position of D¹, D² and D^{2′}.

The valence of L² and L^{2′} is 2. The valence of L¹ is the same as in and is 2 or more. Preferably, the valence of L¹ is 2 to 6, more preferably 2 to 4, even more preferably 2 or 3, and especially preferably 2.

D¹, D² and D^{2′} each independently represent a donor group. However, at least two donor groups existing in the molecule of the compound having a structure represented by the general formula (1) each have a different structure.

Preferably, D¹, D² and D^{2′} each have an aromatic ring, more preferably an aromatic polycyclic structure. The aromatic polycyclic structure may be a polycyclic structure to constitute an aromatic hydrocarbon group, or a polycyclic structure to constitute a heteroaromatic group. The “polycyclic structure” in the aromatic polycyclic structure may be a polycyclic condensed structure, or may be a cyclic aggregate structure where plural aromatic rings link to each other via a single bond, but is preferably a polycyclic condensed structure. The carbon number of the aromatic polycyclic structure is preferably 8 to 40, more preferably 12 to 20. The hetero atom in the polycyclic structure to constitute a heteroaromatic group includes a nitrogen atom, an oxygen atom and a sulfur atom, and the polycyclic structure to constitute the heteroaromatic group preferably contains at least one nitrogen atom.

Also preferably, D¹, D² and D^{2′} each are a group composed of two or more kinds of atoms selected from the group consisting of a hydrogen atom, a carbon atom, a nitrogen atom, an oxygen atom and a sulfur atom. The combination of two or more kinds of atoms includes a binary combination composed of a hydrogen atom and a carbon atom, a ternary combination composed of a hydrogen atom, a carbon atom and a nitrogen atom, a quaternary combination composed of a hydrogen atom, a carbon atom, a nitrogen atom and an oxygen atom, a quaternary combination composed of a hydrogen atom, a carbon atom, a nitrogen atom and a sulfur atom, and a quinary combination composed of a hydrogen atom, a carbon atom, a nitrogen atom, an oxygen atom and a sulfur atom. A binary combination composed of a hydrogen atom and a carbon atom, a ternary combination composed of a hydrogen atom, a carbon atom and a nitrogen atom, and a quaternary combination composed of a hydrogen atom, a carbon atom, a nitrogen atom and an oxygen atom are preferred. The group composed of these atoms alone may have any form of a linear, branched or cyclic structure, but preferably forms a cyclic structure, more preferably forms an aromatic ring, and even more preferably forms an aromatic polycyclic structure. The carbon number of the group composed of two or more kinds of atoms selected from the group consisting of a hydrogen atom, a carbon atom, a nitrogen atom, an oxygen atom and a sulfur atom is preferably 8 to 40, more preferably 12 to 24.

At least two donor groups existing in the molecule of the compound having a structure represented by the general formula (1) each have a different structure. Regarding the description of the donor groups each having a different structure, the description relating to the “donor groups differing from each other in the structure” mentioned hereinabove may be referred to. Preferred examples of the embodiment having at least two donor groups each having a different structure are described below.

Specifically, a group where at least one of D¹, D² and D^{2′} is composed of a hydrogen atom and a carbon atom alone, and at least the remaining one is a group composed of a hydrogen atom, a carbon atom and a nitrogen atom alone, or a group composed of one or more kinds of atoms selected from an oxygen atom and a sulfur atom, and a hydrogen atom, a carbon atom and a nitrogen atom alone is preferred.

Also preferably, at least one of D¹, D² and D^{2′} is a donor group composed of an aromatic hydrocarbon ring, and at least the remaining one is a donor group composed of a nitrogen atom-containing heteroaromatic ring.

Further, also preferably, at least one of D¹, D² and D^{2′} is a group bonding to the linking group via a nitrogen atom, and at least the remaining one is a group bonding to the linking group via a carbon atom.

The group bonding to the linking group via a nitrogen atom is preferably a group represented by the following general formulae (4) to (10), and the group bonding to the linking group via a carbon atom is preferably a group bonding to the linking group via the carbon atom that constitutes the ring skeleton of a benzene ring, and is more preferably a group represented by the following general formula (11).

m represents an integer of 2 or more, preferably 2 to 6, more preferably 2 to 4, even more preferably 2 or 3, and especially preferably 2.

n1 represents an integer of 0 or more, preferably 0 to 4, more preferably 0 or 1, and especially preferably 0.

n2 represents an integer of 0 or more, preferably 0 to 5, more preferably 0 to 3, even more preferably 0 to 2, and especially preferably 0 or 1.

In the structure represented by the general formula (1), for example, where n1 is 2, the partial structure represented by -(D^{2′}-L^{2′})ₙ₁- forms a linear structure represented by -D^{2′}-L^{2′}-D^{2′}-L^{2′}-, and the terminal L^{2′} in the linear structure bonds to D². In this case, the two L^{2′}s may be the same or different, and the two D^{2′}s may also be the same or different. For example, in the case where n2 is 3 and n1 is 0, the partial structure represented by -D¹{-L²-(D^{2′}-L^{2′})ₙ₁-D²}ₙ₂ is a structure represented by -D¹{-L²-D²}₃, that is, a structure where four bonds radially extend from D¹ and -L²-D² bonds to each of three of those bonds and the remaining one bond bonds to L¹. Also in this case, the three (-L²-D²)s may be the same or different.

When m is 2 or more, plural D¹s, L²s, D^{2′}s, L^{2′}s, D²s, n1's and n2's each may be the same as or different from each other. When n1 is 2 or more, plural D^{2′}s, and L^{2′}s each may be the same as or different from each other. When n2 is 2 or more, plural L²s, D^{2′}s, L^{2′}s, D²s, and n1's may be the same as or different from each other.

More preferably, the compound that constitutes the light-emitting material of the present invention has a structure represented by the following general formula (2).

D^{1′}-L¹-D¹{-L²-D²}_{n2′} General Formula (2)

In the general formula (2), L¹ and L² each independently represent an aromatic group composed of one or more benzene rings optionally substituted with an alkyl group or a halogeno group. Regarding the description, the preferred range and the specific examples of L¹ and L², the description, the preferred range and the specific examples of the linking group of the compound of the present invention and those of L¹ and L² in the general formula (1) given hereinabove may be referred to.

D^{1′}, D¹ and D² each independently represent a donor group. However, at least two donor groups existing in the molecule of the compound having a structure represented by the general formula (2) each have a different structure. Regarding the description and the preferred range of D^{1′}, D¹ and D², the description and the preferred range of D¹ and D² in the general formula (1) mentioned hereinabove may be referred to. Regarding the description relating to the wording “at least two donor groups each have a different structure”, the corresponding description given hereinabove to the general formula (1) may be referred to.

n2′ represents 0 or 1, preferably 0.

In the structure represented by the general formula (2), where n2′ is 0, D^{1′} and D¹ each are a donor group having a different structure. On the other hand, when n2′ is 1, all of D¹′, D¹ and D² may be donor groups each having a different structure from that of the other two donor groups, or two of D^{1′}, D¹ and D² may be donor groups having the same structure and the remaining one may be a donor group having a different structure from that of these donor groups. Among these, preferably, D^{1′} and D² are donor groups having the same structure, and D¹ is a donor group having a different structure from that of D^{1′} and D².

When n2′ is 0, also preferably, any one of D^{1′} and D¹ is a group composed of a hydrogen atom and a carbon atom alone, and the other is a group composed of a hydrogen atom, a carbon atom and a nitrogen atom, or a group composed of one or more kinds of atoms selected from an oxygen atom and a sulfur atom, and a hydrogen atom, a carbon atom and a nitrogen atom alone. On the other hand, when n2′ is 1, also preferably, at least one of D^{1′}, D¹ and D² is a group composed of a hydrogen atom and a carbon atom alone, and the remaining one is a group composed of a hydrogen atom, a carbon atom and a nitrogen atom alone, or a group composed of one or more kinds of atoms selected from an oxygen atom and a sulfur atom, and a hydrogen atom, a carbon atom and a nitrogen atom alone.

Further, when n2′ is 0, preferably, any one of D^{1′} and D¹ is a group bonding to the linking group via a nitrogen atom, and the other is a group bonding to the linking group via a carbon atom. On the other hand, when n2′ is 1, preferably, D¹ is a group bonding to the linking group via a nitrogen atom, and D^{1′} is a group bonding to the linking group via a carbon atom. More preferably, D² is a group bonding to the linking group via a carbon atom. More preferably, D¹ is a group bonding to the linking group via a carbon atom, and D^{1′} is a group bonding to the linking group via a nitrogen atom, and D² is a group bonding to the linking group via a nitrogen atom. Among these, preferably, D¹ is a group bonding to the linking group via a carbon atom, and D^{1′} and D² each are a group bonding to the linking group via a nitrogen atom.

The group bonding to the linking group via a nitrogen atom is preferably a group represented by the following general formulae (4) to (10), and the group bonding to the linking group via a carbon atom is preferably a group bonding to the linking group via a carbon atom that constitutes the ring skeleton of a benzene ring, more preferably a group represented by the following general formula (11).

More preferably, the compound constituting the light-emitting material of the present invention has a structure represented by the following general formula (3).

D^{1′}-Ph¹-D¹{-L²-D²}_{n2′} General Formula (3)

In the general formula (3), Ph¹ represents a phenylene group optionally substituted with an alkyl group or a halogeno group. D^{1′}, D¹ and D² each independently represent a donor group except a substituted or unsubstituted diarylamino group. However, at least two donor groups existing in the molecule of the compound having a structure represented by the general formula (3) each have a different structure. n2′ represents 0 or 1.

L², D^{1′}, D¹, D² and n2 in the general formula (3) have the same meanings as those of L², D^{1′}, D¹, D² and n2, respectively, in the general formula (2), and regarding the description, the preferred range and the specific examples thereof, the corresponding description relating to the structure represented by the general formula (2) may be referred to.

The phenylene group of Ph¹ may be any of a 1,2-phenylene group, a 1,3-phenylene group, or a 1,4-phenylene group, but is preferably a 1,3-phenylene group or a 1,4-phenylene group, more preferably a 1,4-phenylene group. Regarding the alkyl group and the halogeno group with which the phenylene group and the linking group may be substituted, the corresponding description relating to the linking group mentioned hereinabove may be referred to.

When D¹, D² and D^{2′} in the general formula (1) and D^{1′}, D¹ and D² in the general formulae (2) and (3) each are a group bonding to the linking group via a nitrogen atom, the group is preferably represented by the following general formula (4) or (5).

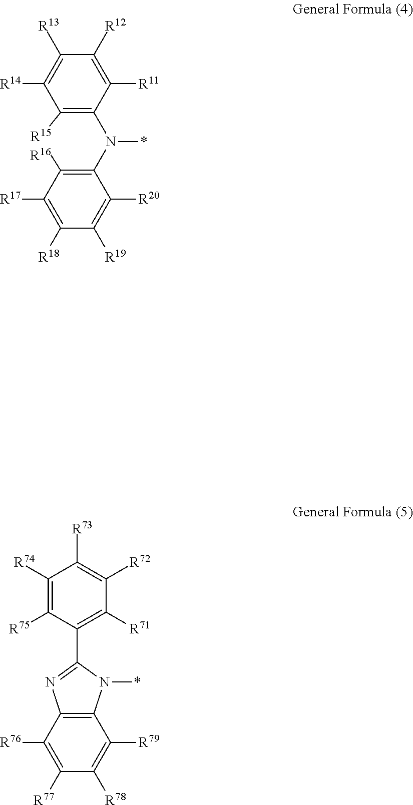

In the general formulae (4) and (5), R¹¹ to R²⁰, and R⁷¹ to R⁷⁹ each independently represent a hydrogen atom or a substituent. R¹⁵ and R¹⁶ bond to each other to form a cyclic structure. The bonding between R¹⁵ and R¹⁶ may form a single bond between the carbon atom to which R¹⁵ bonds and the carbon atom to which R¹⁶ bonds, or may be a bond to form a divalent linking group between the carbon atom to which R¹⁵ bonds and the carbon atom to which R¹⁶ bonds. The divalent linking group includes an alkylene group, an imino group (—NH—), an oxy group (—O—), a thio group (—S—) and a divalent group of a combination of two or more of these groups. Among these linking groups, those that may have a substituent may be substituted with a substituent. Regarding the description and the preferred range of the substituent, the description and the preferred range of the substituent, with which R¹¹ to R¹⁴ may be substituted, may be referred to. In R¹¹ to R¹⁴, R¹⁷ to R²⁰, and R⁷¹ to R⁷⁹, the number of the substituents is not specifically limited, and all of R¹¹ to R¹⁴, R¹⁷ to R²⁰, and R⁷¹ to R⁷⁹ may have no substituent (that is, a hydrogen atom). In the case where two or more of R¹¹ to R¹⁴, and R¹⁷ to R²⁰ are substituents, and in the case where two or more of R⁷¹ to R⁷⁹ are substituents, these plural substituents may be the same as or different from each other. In the case where the general formula (5) has a substituent, the substituent is preferably any of R⁷² to R⁷⁴, R⁷⁷, and R⁷⁸.

Examples of the substituent with which R¹¹ to R¹⁴, R¹⁷ to R²⁰, and R⁷¹ to R⁷⁹ may be substituted include a hydroxyl group, a halogen atom, a cyano group, an alkyl group having 1 to 20 carbon atoms, an alkoxy group having 1 to 20 carbon atoms, an alkylthio group having 1 to 20 carbon atoms, an alkyl-substituted amino group having 1 to 20 carbon atoms, an acyl group having 2 to 20 carbon atoms, an aryl group having 6 to 40 carbon atoms, a heteroaryl group having 3 to 40 carbon atoms, an alkenyl group having 2 to 10 carbon atoms, an alkynyl group having 2 to 10 carbon atoms, an alkoxycarbonyl. group having 2 to 10 carbon atoms, an alkylsulfonyl group having 1 to 10 carbon atoms, a haloalkyl group having 1 to 10 carbon atoms, an amide group, an alkylamide group having 2 to 10 carbon atoms, a trialkylsilyl group having 3 to 20 carbon atoms, a trialkylsilylalkyl group having 4 to 20 carbon atoms, a trialkylsilylalkenyl group having 5 to 20 carbon atoms, a trialkylsilylalkynyl group having 5 to 20 carbon atoms, and a nitro group. Among these specific examples, those that may be further substituted with a substituent may be substituted. More preferred substituents include a halogen atom, a cyano group, a substituted or unsubstituted alkyl group having 1 to 20 carbon atoms, an alkoxy group having 1 to 20 carbon atoms, a substituted or unsubstituted aryl group having 6 to 40 carbon atoms, a substituted or unsubstituted heteroaryl group having 3 to 40 carbon atoms, and a dialkyl-substituted amino group having 1 to 20 carbon atoms. Even more preferred substituents include a fluorine atom, a chlorine atom, a cyano group, a substituted or unsubstituted alkyl group haying 1 to 10 carbon atoms, a substituted or unsubstituted alkoxy group having 1 to 10 carbon atoms, a substituted or unsubstituted aryl group having 6 to 15 carbon atoms, and a substituted or unsubstituted heteroaryl group having 3 to 12 carbon atoms.

R¹¹ and R¹², R¹² and R¹³, R¹³ and R¹⁴, R¹⁷ and R¹⁸, R¹⁸ and R¹⁹, R¹⁹ and R²⁰, R⁷¹ and R⁷², R⁷² and R⁷³, R⁷³ and R⁷⁴, R⁷⁴ and R⁷⁵, R⁷⁶ and R⁷⁷, R⁷⁷ and R⁷⁸, and R⁷⁸ and R⁷⁹ each may bond to each other to form a cyclic structure. The cyclic structure may be an aromatic ring or an aliphatic ring, or may contain a hetero atom, and further, the cyclic structure may be a condensed ring of 2 or more rings. The hetero atom as referred to herein is preferably one selected from the group consisting of a nitrogen atom, an oxygen atom and a sulfur atom. Examples of the formed cyclic structure include a benzene ring, a naphthalene ring, a pyridine ring, a pyridazine ring, a pyrimidine ring, a pyrazine ring, a pyrrole ring, an imidazole ring, a pyrazole ring, a triazole ring, an imidazoline ring, an oxazole ring, an isoxazole ring, a thiazole ring, an isothiazole ring, a cyclohexadiene ring, a cyclohexene ring, a cyclopentane ring, a cycloheptatriene ring, a cycloheptadiene ring, and a cycloheptane ring.

* represents a bonding position to the linking group. The group represented by the general formula (4) and the general formula (5) may be divalent. In the case, the group represented by the general formula (4) may further bond at any of R¹¹ to R²⁰, and the group represented by the general formula (5) may further bond at any of R⁷¹ to R⁷⁹.

The group bonding to the linking group via a nitrogen atom is more preferably a group represented by any of the following general formulae (6) to (10).

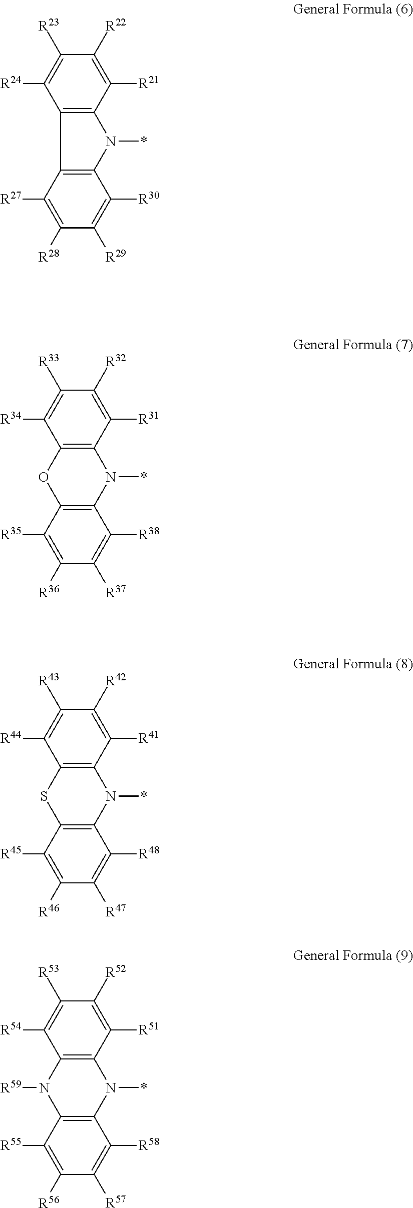

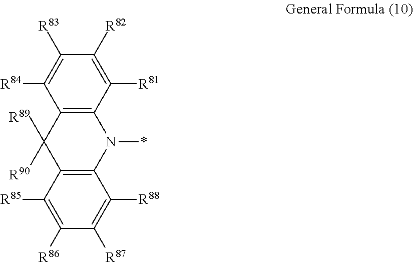

In the general formulae (6) to (10), R²¹ to R²⁴, R²⁷ to R³⁸, R⁴¹ to R⁴⁸, R⁵¹ to R⁵⁹, and R⁸¹ to R⁹⁰ each independently represent a hydrogen atom or a substituent. Regarding the description and the preferred range of the substituent as referred to herein, the description and the preferred range of the substituent, with which R¹¹ to R¹⁴ as mentioned above may be substituted, may be referred to. The number of the substituents in the general formulae (6) to (10) is not specifically limited. Also preferably, R²¹ to R²⁴, R²⁷ to R³⁸, R⁴¹ to R⁴⁸, R⁵¹ to R⁵⁹, R⁸¹ to R⁹⁰, and the above-mentioned R⁷¹ to R⁷⁹ each are independently the group represented by any of the general formulae (5) to (10). All unsubstituted cases (where the group is a hydrogen atom) are also preferred. In the case where the general formulae (6) to (10) each have 2 or more substituents, the substituents may be the same as or different from each other.

A case where a substituent exists in the general formulae (6) to (10) is referred to. The substituent is preferably any of R²² to R²⁴, and R²⁷ to R²⁹ in the general formula (6), more preferably at least one of R²³ and R²⁸; the substituent is preferably any of R³² to R³⁷ in the general formula (7); the substituent is preferably any of R⁴² to R⁴⁷ in the general formula (8); the substituent is preferably any of R⁵² to R⁵⁷, and R⁵⁹ in the general formula (9); the substituent is preferably any of R⁸² to R⁸⁷, R⁸⁹, and R⁹⁰ in the general formula (10), more preferably any of R⁸⁹ and R⁹⁰. The substituents represented by R⁸⁹ and R⁹⁰ each are preferably a substituted or unsubstituted aryl group having 6 to 40 carbon atoms, more preferably a substituted or unsubstituted phenyl group. Also preferably, the substituents represented by R⁸⁹ and R⁹⁰ are the same.

In the general formulae (6) to (10), R²¹ and R²², R²² and R²³, R²³ and R²⁴, R²⁷ and R²⁸, R²⁸ and R²⁹, R²⁹ and R³⁰, R³¹ and R³², R³² and R³³, R³³ and R³⁴, R³⁵ and R³⁶, R³⁶ and R³⁷, R³⁷ and R³⁸, R⁴¹ and R⁴², R⁴² and R⁴³, R⁴³ and R⁴⁴, R⁴⁵ and R⁴⁶, R⁴⁶ and R⁴⁷, R⁴⁷ and R⁴⁸, R⁵¹ and R⁵², R⁵² and R⁵³, R⁵³ and R⁵⁴, R⁵⁵ and R⁵⁶, R⁵⁶ and R⁵⁷, R⁵⁷ and R⁵⁸, R⁵⁴ and R⁵⁹, R⁵⁵ and R⁵⁹, R⁸¹ and R⁸², R⁸² and R⁸³, R⁸³ and R⁸⁴, R⁸⁵ and R⁸⁶, R⁸⁶ and R⁸⁷, R⁸⁷ and R⁸⁸, and R⁸⁹ and R⁹⁰ each may bond to each other to form a cyclic structure. Regarding the description and the preferred range of the cyclic structure, in the general formula (4), the description and the preferred range of the cyclic structure to be formed by R¹¹ and R¹² bonding to each other may be referred to.

* represents a bonding position to the linking group. The group represented by the general formula (6) to the general formula (10) may be divalent. In the case, the group represented by the general formula (6) further bonds at any of R²¹ to R²⁴, and R²⁷ to R³⁰; the group represented by the general formula (7) further bonds at any of R³¹ to R³⁸; the group represented by the general formula (8) further bonds at any of R⁴¹ to R⁴⁸; the group represented by the general formula (9) further bonds at any of R⁵¹ to R⁵⁹; and the group represented by the general formula (10) further bonds at any of R⁸¹ to R⁹⁰.

When D¹, D², and D^{2′} in the general formula (1) and D^{1′}, D¹, and D² in the general formulae (2) and (3) each are a group bonding to the liking group via a carbon atom, the group is preferably represented by the following general formulas (11).

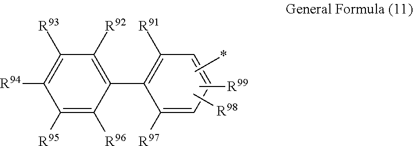

In the general formula (11), R⁹¹ to R⁹⁹ each independently represent a hydrogen atom or a substituent. R⁹¹ and R⁹², R⁹² and R⁹³, R⁹³ and R⁹⁴, R⁹⁴ and R⁹⁵, R⁹⁵ and R⁹⁶, R⁹⁶ and R⁹⁷, R⁹⁷ and R⁹⁸, R⁹⁸ and R⁹⁹, and R⁹¹ and R⁹⁹ each may bond to each other to form a cyclic structure. * represents a bonding position to the linking group. In the case where the group bonding to the linking group via a carbon atom is divalent, the group further bonds at any of R⁹¹ to R⁹⁹.

In the general formula (11), R⁹¹ to R⁹⁹ each independently represent a hydrogen atom or a substituent. Regarding the description and the preferred range of the substituent as referred to herein, the description and the preferred range of the substituent, with which R¹¹ to R¹⁴ as mentioned above may be substituted, may be referred to. The number of the substituents in the general formula (11) is not specifically limited. Also preferably, all of R⁹¹ to R⁹⁹ may be unsubstituted (that is, they are hydrogen atoms). In the case where the general formula (11) has 2 or more substituents, the substituents may be the same as or different from each other.

In the case where the general formula (11) has a substituent, the substituent is preferably any of R⁹³ to R⁹⁶.

In the general formula (11), R⁹¹ and R⁹², R⁹² and R⁹³, R⁹³ and R⁹⁴, R⁹⁴ and R⁹⁵, R⁹⁵ and R⁹⁶, R ⁹⁶ and R⁹⁷, R⁹⁷ and R⁹⁸, R⁹⁸ and R⁹⁹, and R⁹¹ and R⁹⁹ each may bond to each other to form a cyclic structure. Especially preferably, R⁹¹ and R⁹² bond to each other to form a cyclic structure. Regarding the description and the preferred examples of the cyclic structure, in the general formula (4), the description and the preferred examples of the cyclic structure formed by R¹¹ and R¹² bonding to each other may be referred to. In the case where R⁹¹ and R⁹² bond to each other to form a cyclic structure, preferably, R⁹¹ and R⁹² bond to each other to form a linking group between the carbon atom to which R⁹¹ bonds and the carbon atom to which R⁹² bonds, and more preferably, the bonding forms an alkylene group. The carbon number of the alkylene group is preferably 1 to 3, more preferably 1 or 2, even more preferably 1. The alkylene group may be substituted with a substituent. Regarding the description and the preferred range of the substituent, the description and the preferred range of the substituent, with which R¹¹ to R¹⁴ mentioned above may be substituted, may be referred to. Among these, the substituent for the alkylene group is preferably an alkyl group having 1 to 20 carbon atoms, more preferably an alkyl group having 1 to 10 carbon atoms, even more preferably an alkyl group having 1 to 5 carbon atoms.

* represents a bonding position to the linking group. The position of * may be a para-position relative to the bonding position of the other benzene ring (the benzene ring substituted with R⁹² to R⁹⁶), or may also be a meta-position, but is preferably a para-position. R⁹⁸ and R⁹⁹ bond to the other positions than the bonding positions of R⁹¹, R⁹⁷ and * in one benzene ring (the benzene ring substituted with R⁹¹, and R⁹⁷ to R⁹⁹). In the case where the position of * is a para-position relative to the bonding position of the other benzene ring, R⁹⁸ and R⁹⁹ both bond to the meta-position, and in the case where the position of * is a meta-position relative to the bonding position of the other benzene ring, one of R⁹⁸ and R⁹⁹ bonds to the para-position while the other bonds to the meta-position that is line-symmetric to the position of *.

The group represented by the general formula (11) may be a divalent group that further bonds to a linking group differing from the linking group bonding at *, at any of R⁹¹ to R⁹⁹. Among R⁹¹ to R⁹⁹, preferably, any of R⁹³ to R⁹⁵ is the bonding position to the linking group, more preferably R⁹⁴.

Specific examples of the compound to constitute the light-emitting material of the present invention are shown below. However, the compounds usable in the light-emitting material of the present invention should not be limitatively interpreted by these examples.

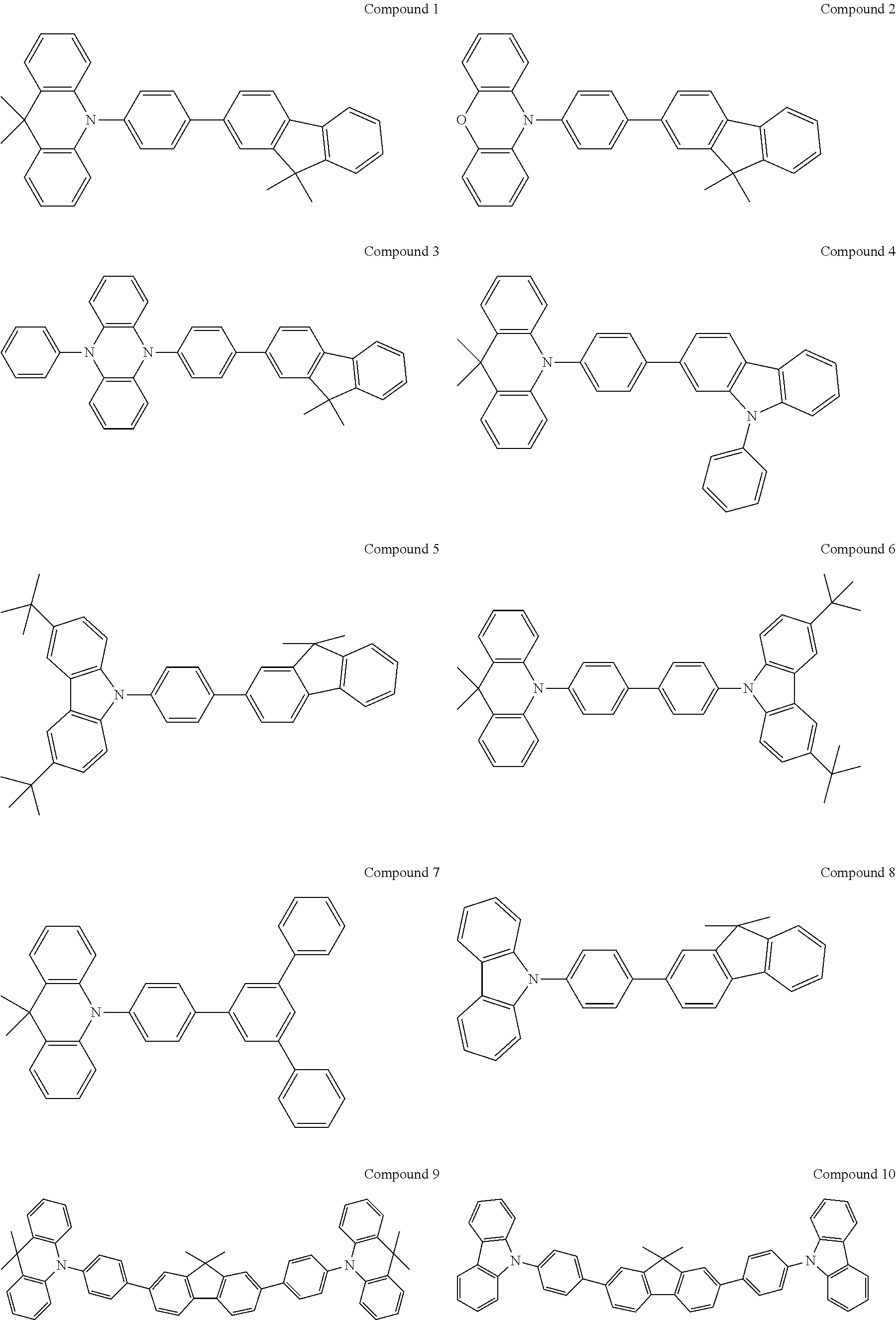

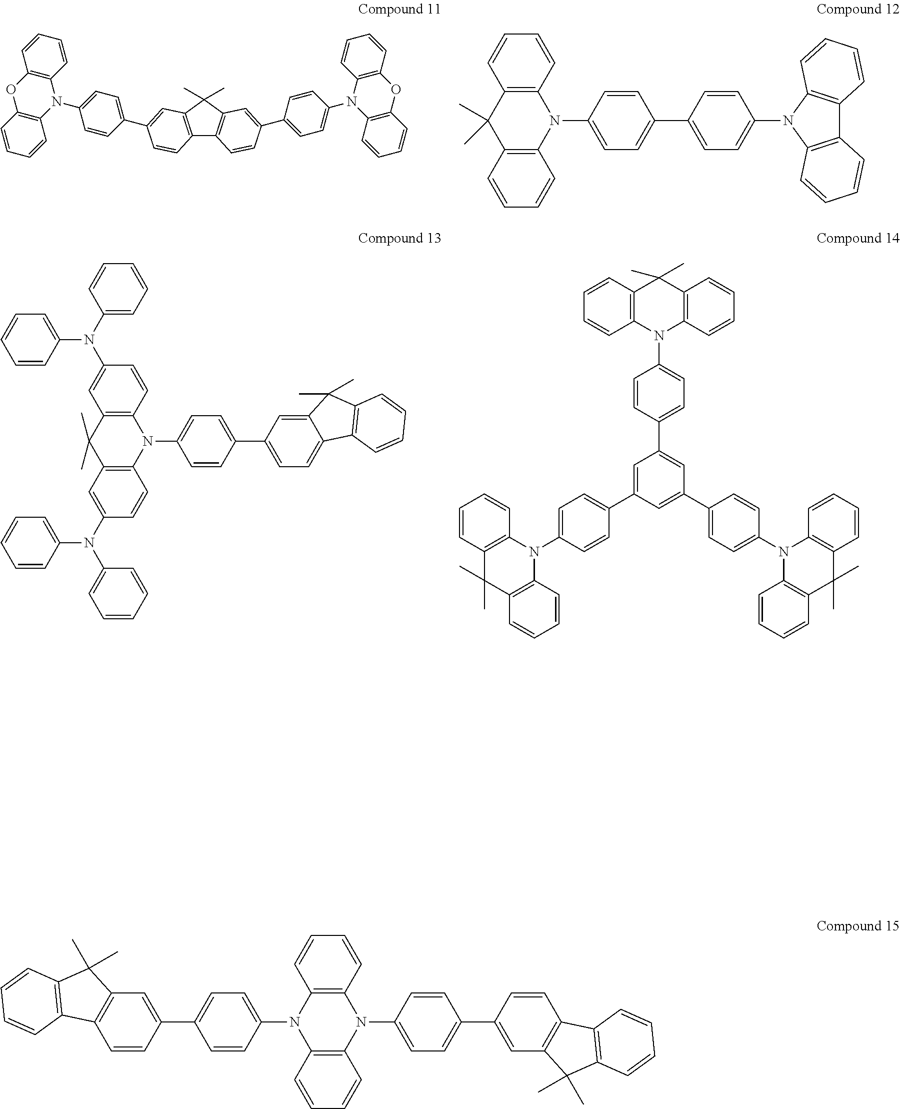 [SMILES: CC1(C)c2cc(-c3ccc(N4c5ccccc5Oc5ccccc54)cc3)ccc2-c2ccc(-c3ccc(N4c5ccccc5Oc5ccccc54)cc3)cc21 ; CC1(C)c2ccccc2N(c2ccc(-c3ccc(-n4c5ccccc5c5ccccc54)cc3)cc2)c2ccccc21 ; CC1(C)c2ccccc2-c2ccc(-c3ccc(N4c5ccc(N(c6ccccc6)c6ccccc6)cc5C(C)(C)c5cc(N(c6ccccc6)c6ccccc6)ccc54)cc3)cc21 ; CC1(C)c2ccccc2N(c2ccc(-c3cc(-c4ccc(N5c6ccccc6C(C)(C)c6ccccc65)cc4)cc(-c4ccc(N5c6ccccc6C(C)(C)c6ccccc65)cc4)c3)cc2)c2ccccc21 ; CC1(C)c2ccccc2-c2ccc(-c3ccc(N4c5ccccc5N(c5ccc(-c6ccc7c(c6)C(C)(C)c6ccccc6-7)cc5)c5ccccc54)cc3)cc21]

The molecular weight of the compound constituting the light-emitting material of the present invention is, for example, in the case where an organic layer containing the compound is intended to be utilized through film formation according to an vapor deposition method, preferably 1500 or less, more preferably 1200 or less, even more preferably 1000 or less, further more preferably 800 or less.

The compound to constitute the light-emitting material may be formed into a film according , to a coating method irrespective of the molecular weight thereof. According to a coating method, a compound having a relatively large molecular weight can be formed into a film.

The energy difference between HOMO and LUMO of the compound constituting the light-emitting material of the present invention is preferably 2.5 to 3.6 eV, more preferably 2.5 to 3.4 eV, even more preferably 2.8 to 3.1 eV. The HOMO energy level of the compound is preferably −5.7 eV or more, more preferably −5.3 eV or more.

Further, the difference ΔE_{ST} between the lowest excited singlet energy level E_{S1} of the compound constituting the light-emitting material of the present invention and the lowest excited triplet energy level E^{T1} thereof is preferably 0.3 eV or less, more preferably 0.2 eV or less, even more preferably 0.1 eV or less.

When the compound constituting the light-emitting material satisfies the above-mentioned energy condition, it can realize a higher light emission efficiency.

Regarding the method of determining the energy level of HOMO and LUMO of the compound, the method described in the section of Examples may be referred to.

In this description, the energy level of HOMO may be expressed as “HOMO level”, and the energy level of LUMO may be expressed as “LUMO level”.

Applying the present invention, a compound containing a plurality of structures each represented by the general formula (1) in the molecule may be considered to be used as a light-emitting material.

For example, a polymerizable group is previously introduced into a structure represented by the general formula (1) and the polymerizable group is polymerized to give a polymer, and the polymer is used as a light-emitting material. Specifically, a monomer containing a polymerizable functional group in any of L¹, L², L^{2′}, D¹, D², and D^{2′} in the general formula (1) is prepared, and this is homo-polymerized or copolymerized with any other monomer to give a polymer having a recurring unit, and the polymer may be used as a light-emitting material. Alternatively, compounds each having a structure represented by the general formula (1) are coupled to give a dimer or a trimer, and it may be used as a light-emitting material.

Examples of the polymer having a recurring unit containing a structure represented by the general formula (1) include polymers containing a structure represented by the following general formula (10) or (11).

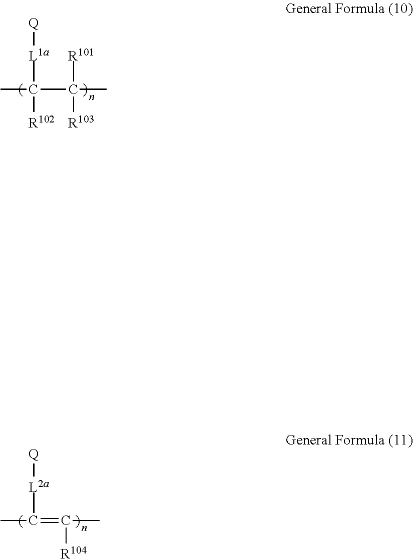

In the general formula (10) or (11), Q represents a group containing a structure represented by the general formula (1), and L^{1a} and L^{2a} each represent a linking group. The carbon number of the linking group is preferably 0 to 20, more preferably 1 to 15, even more preferably 2 to 10. Preferably, the linking group has a structure represented by -X¹¹-L¹¹-. Here, X¹¹ represents an oxygen atom or a sulfur atom and is preferably an oxygen atom. L¹¹ represents a linking group, and is preferably a substituted or unsubstituted alkylene group, or a substituted or unsubstituted arylene group, more preferably a substituted or unsubstituted alkylene group having 1 to 10 carbon atoms, or a substituted or unsubstituted phenylene group.

In the general formula (10) or (11), R¹⁰¹, R¹⁰², R¹⁰³ and R¹⁰⁴ each independently represent a substituent. Preferably, the substituent is a substituted or unsubstituted alkyl group having 1 to 6 carbon atoms, a substituted or unsubstituted alkoxy group having 1 to 6 carbon atoms, or a halogen atom, more preferably an unsubstituted alkyl group having 1 to 3 carbon atoms, an unsubstituted alkoxy group having 1 to 3 carbon atoms, a fluorine atom, or a chlorine atom, and even more preferably an unsubstituted alkyl group having 1 to 3 carbon atoms, or an unsubstituted alkoxy group having 1 to 3 carbon atoms.

The linking group represented by L^{1a} and L^{2a} may bond to any of L¹, L², L^{2′}, D¹, D², and D^{2′} in the structure of the general formula (1) constituting Q, or any of L¹, L², D^{1′}, D¹, and D² in the structure of the general formula (2), or any of Ph¹, L², D^{1′}, D¹, and D² in the structure of the general formula (3). Two or more linking groups may bond to one Q to form a crosslinked structure or a network structure.

Specific structural examples of the recurring unit include structures represented by the following formulae (12) to (15).

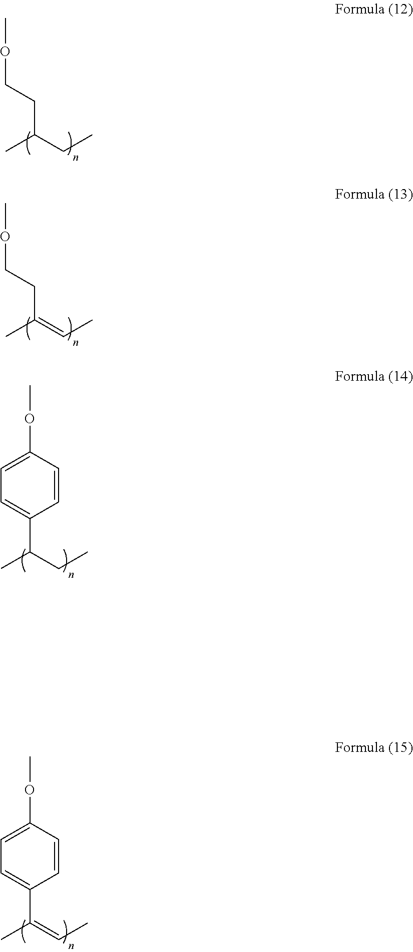

The polymer having a recurring unit containing any of these formulae (12) to (15) may be synthesized by previously introducing a hydroxy group into any of L¹, L², L^{2′}, D¹, D², and D^{2′} in the structure of the general formula (1), then reacting it as a linker with any of the following compound to introduce a polymerizable group thereinto, and polymerizing the polymerizable group.

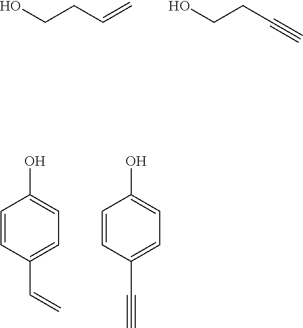

The polymer containing a structure represented by the general formula (1) in the molecule may be a polymer formed of the recurring unit having the structure represented by the general formula (1) or a polymer containing a recurring unit having any other structure. One kind alone or two or more kinds of recurring units having a structure represented by the general formula (1) may be contained in the polymer. The recurring unit riot having a structure represented by the general formula (1) includes those derived from a monomer usable in ordinary copolymerization. Examples thereof include recurring units derived from monomers having an ethylenic unsaturated bond such as ethylene or styrene.

### [Compound Represented by General Formula (3)]

The compound represented by the general formula (3) is a novel compound.

D^{1′}-Ph¹-D¹{-L²-D²}_{n2′} General Formula (3)

In the general formula (3), Ph¹ represents a phenylene group optionally substituted with an alkyl group or a halogeno group. D^{1′}, D¹ and D² each independently represent a donor group except a substituted or unsubstituted diarylamino group. However, at least two donor groups existing in the molecule represented by the general formula (3) each have a different structure. n2′ represents 0 or 1.

The compound represented by the general formula (3) of the present invention is useful as a light-emitting material for an organic light-emitting device. Accordingly, the compound represented by the general formula (3) of the present invention can be effectively used as a light-emitting material in the light-emitting layer of an organic light-emitting device.

### [Method for Synthesis of Compound Represented by General Formula (3)]

The compound represented by the general formula (3) may be synthesized by combining known reactions. For example, a compound of the general formula (3) where D^{1′} is a group represented by the general formula (4), D¹ is a group represented by the general formula (11), Ph¹ is a 1,4-phenylene group and n2′ is 0 can be synthesized by reacting the following two compounds.

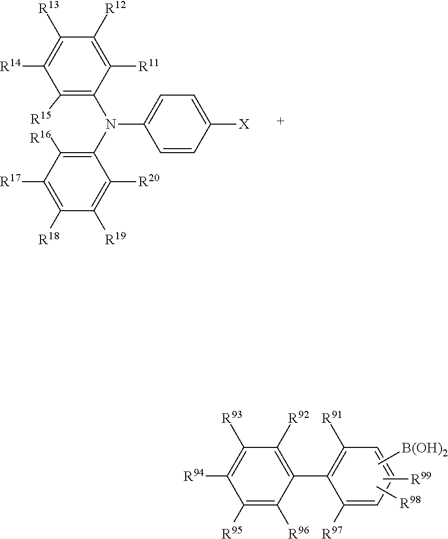

Regarding the description of R¹¹ to R²⁰, and R⁹¹ to R⁹⁹ in the above-mentioned reaction formula, the corresponding description given to the general formula (4) and the general formula (11) may be referred to. X represents a halogen atom, including a fluorine atom, a chlorine atom, a bromine atom and an iodine atom, and is preferably a chlorine atom, a bromine atom or an iodine atom.

In the above reaction, a known coupling reaction is applied, and known reaction conditions may be appropriately selected and used. Regarding the details of the above reaction, Synthesis Examples given below may be referred to. The compound represented by the general formula (3) may also be synthesized by combining any other known synthesis reactions.

### [Organic Light-Emitting Device]

The light-emitting material of the present invention can be effectively used in a light-emitting layer of an organic light-emitting device.

The light-emitting material of the present invention includes a delayed fluorescent material (delayed fluorescent emitter) to emit delayed fluorescence. The light-emitting material for use in a light-emitting layer may be one that emits delayed fluorescence or one that does not emit it, but is preferably one that emits delayed fluorescence. Using a light-emitting material that emits delayed fluorescence in a light-emitting layer realizes a high light emission efficiency, The principle will be described below with reference to an organic electroluminescent device taken as an example.

In an organic electroluminescent device, carriers are injected from an anode and a cathode to a light-emitting material to form an excited state for the light-emitting material, with which light is emitted. In the case of a carrier injection type organic electroluminescent device, in general, excitons that are excited to the excited singlet state are 25% of the total excitons generated, and the remaining 75% thereof are excited to the excited triplet state. Accordingly, the use of phosphorescence, which is light emission from the excited triplet state, provides a high energy utilization. However, the excited triplet state has a long lifetime and thus causes saturation of the excited state and deactivation of energy through mutual action with the excitons in the excited triplet state, and therefore the quantum yield of phosphorescence may generally be often not high. A delayed fluorescent material emits fluorescent light through the mechanism that the energy of excitons transits to the excited triplet state through intersystem crossing or the like, and then transits to the excited singlet state through reverse intersystem crossing due to triplet-triplet annihilation or absorption of thermal energy, thereby emitting fluorescent light. It is considered that among the materials, a thermal activation type delayed fluorescent material emitting light through absorption of thermal energy is particularly useful for an organic electroluminescent device. In the case where a delayed fluorescent material is used in an organic electroluminescent device, the excitons in the excited singlet state normally emit fluorescent light. On the other hand, the excitons in the excited triplet state emit fluorescent light through intersystem crossing to the excited singlet state by absorbing the heat generated by the device. At this time, the light emitted through reverse intersystem crossing from the excited triplet state to the excited singlet state has the same wavelength as fluorescent light since it is light emission from the excited singlet state, but has a longer lifetime (light emission lifetime) than the normal fluorescent light and phosphorescent light, and thus the light is observed as fluorescent light that is delayed from the normal fluorescent light and phosphorescent light. The light may be defined as delayed fluorescent light. The use of the thermal activation type exciton transition mechanism may raise the proportion of the compound in the excited singlet state, which is generally formed in a proportion only of 25%, to 25% or more through the absorption of the thermal energy after the carrier injection. A compound that emits strong fluorescent light and delayed fluorescent light at a low temperature of lower than 100° C. undergoes the intersystem crossing from the excited triplet state to the excited singlet state sufficiently with the heat of the device, thereby emitting delayed fluorescent light, and thus the use of the compound may drastically enhance the light emission efficiency.

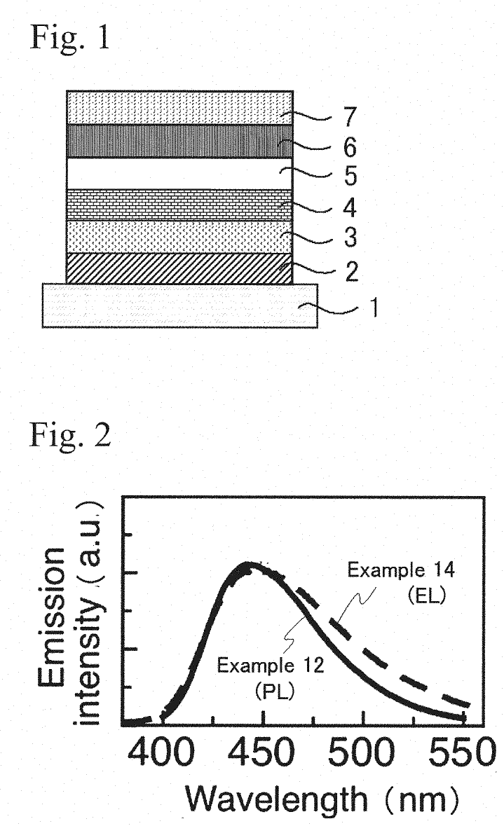

Using the light-emitting material of the present invention in a light-emitting layer, excellent organic light-emitting devices such as organic photoluminescent device (organic PL device) and an organic electroluminescent device (organic EL device) can be provided. An organic photoluminescent device has a structure where at least a light-emitting layer is formed on a substrate. An organic electroluminescent device has a structure including at least an anode, a cathode and an organic layer formed between the anode and the cathode. The organic layer contains at least a light-emitting layer, and may be formed of a light-emitting layer alone, or may has one or more other organic layers in addition to a light-emitting layer. The other organic layers include a hole transport layer, a hole injection layer, an electron blocking layer, a hole blocking layer, an electron injection layer, an electron transport layer, and an exciton blocking layer. The hole transport layer may be a hole injection transport layer having a bole injection function, and the electron transport layer may be an electron injection transport layer having an electron injection function. A configuration example of an organic electroluminescent device is shown in FIG. 1. In FIG. 1, 1 is a substrate, 2 is an anode, 3 is a hole injection layer, 4 is a hole transport layer, 5 is a light-emitting layer, 6 is an electron transport layer, and 7 is a cathode.

In the following, the constituent members and the layers of the organic electroluminescent device are described. The description of the substrate and the light-emitting layer given below may apply to the substrate and the light-emitting layer of an organic photoluminescent device.

### (Substrate)

The organic electroluminescent device of the invention is preferably supported by a substrate. The substrate is not particularly limited and may be those that have been commonly used in an organic electroluminescent device, and examples thereof used include those formed of glass, transparent plastics, quartz and silicon.

### (Anode)

The anode of the organic electroluminescent device used is preferably formed of as an electrode material a metal, an alloy or an electroconductive compound each having a large work function (4 eV or more), or a mixture thereof. Specific examples of the electrode material include a metal, such as Au, and an electroconductive transparent material, such as CuI, indium tin oxide (ITO), SnO₂ and ZnO. A material that is amorphous and is capable of forming a transparent electroconductive film, such as IDIXO (In₂O₃—ZnO), may also be used. The anode may be formed in such a manner that the electrode material is formed into a thin film by such a method as vapor deposition or sputtering, and the film is patterned into a desired pattern by a photolithography method, or in the case where the pattern may not require high accuracy (for example, approximately 100 μm or more), the pattern may be formed with a mask having a desired shape on vapor deposition or sputtering of the electrode material. In alternative, in the case where a material capable of being applied as a coating, such as an organic electroconductive compound, is used, a wet film forming method, such as a printing method and a coating method, may be used. In the case where emitted light is to be taken out through the anode, the anode preferably has a transmittance of more than 10%, and the anode preferably has a sheet resistance of several hundred Ohm per square or less. The thickness thereof may be generally selected from a range of from 10 to 1,000 nm, and preferably from 10 to 200 nm, while depending on the material used.

### (Cathode)

The cathode is preferably formed of as an electrode material a metal having a small work function (4 eV or less) (referred to as an electron injection metal), an alloy or an electroconductive compound each having a small work function (4 eV or less or a mixture thereof. Specific examples of the electrode material include sodium, a sodium-potassium alloy, magnesium, lithium, a magnesium-copper mixture, a magnesium-silver mixture, a magnesium-aluminum mixture, a magnesium-indium mixture, an aluminum-aluminum oxide (Al₂O₃) mixture, indium, a lithium-aluminum mixture, and a rare earth metal. Among these, a mixture of an electron injection metal and a second metal that is a stable metal having a larger work function than the electron injection metal, for example, a magnesium-silver mixture, a magnesium-aluminum mixture, a magnesium-indium mixture, an aluminum-aluminum oxide (Al₂O₃) mixture, a lithium-aluminum mixture, and aluminum, are preferred from the standpoint of the electron injection property and the durability against oxidation and the like. The cathode may be produced by forming the electrode material into a thin film by such a method as vapor deposition or sputtering. The cathode preferably has a sheet resistance of several hundred Ohm per square or less, and the thickness thereof may be generally selected from a range of from 10 nm to 5 μm, and preferably from 50 to 200 nm. For transmitting the emitted light, any one of the anode and the cathode of the organic electroluminescent device is preferably transparent or translucent, thereby enhancing the light emission luminance.

The cathode may be formed with the electroconductive transparent materials described for the anode, thereby forming a transparent or translucent cathode, and by applying the cathode, a device having an anode and a cathode, both of which have transmittance, may be produced.

### (Light-Emitting Layer)

The light-emitting layer is a layer in which holes and electrons injected from an anode and a cathode are recombined to give excitons for light emission. A light-emitting material may be used singly in the light-emitting layer, but preferably, the layer contains a light-emitting layer and a host material. Here, the light-emitting layer is one composed of the compound defined in the present invention (the light-emitting material of the present invention), and the layer may be composed of one kind of the compound defined in the present invention, or may contain two or more kinds of the compounds defined in the present invention.

In order that the organic electroluminescent device and the organic photoluminescent device of the present invention can express a high light emission efficiency, it is important to confine the singlet exciton and the triplet exciton formed in the light-emitting material to the light-emitting material. Accordingly, preferably, a host material is used in addition to the light-emitting material in the light-emitting layer. As the host material, an organic compound, of which at least any one of the excited singlet energy and the excited triplet energy is higher than that of the light-emitting material of the present invention, may be used. As a result, the singlet exciton and the triplet exciton formed in the light-emitting material can be confined to the molecule of the light-emitting material of the present invention to sufficiently derive the light emission efficiency thereof. Needless-to-say, there may be a case where a high light emission efficiency could be attained even though the singlet exciton and the triplet exciton could not be sufficiently confined, and therefore, any host material capable of realizing a high light emission efficiency can be used in the present invention with no specific limitation. In the organic light-emitting device or the organic electroluminescent device of the present invention, light emission occurs from the light-emitting material of the present invention contained in the light-emitting layer. The light emission may be any of ordinary fluorescent emission with no delay (simply referred to as “fluorescent emission”), or may contain both of fluorescent emission and delayed fluorescent emission. In addition, a part of light emission may be partially from a host material.

In the case where a hots material is used, the content of the compound of the present invention as a light-emitting material in the light-emitting layer is preferably 0.1% by weight or more, more preferably 1% by weight or more, and is preferably 50% by weight or less, more preferably 20% by weigh tor less, even more preferably 10% by weight or less.

The host material in the light-emitting layer is preferably an organic compound having hole transport competence and electron transport competence, capable of preventing prolongation of emission wavelength and having a high glass transition temperature.

### (Injection Layer)

The injection layer is a layer that is provided between the electrode and the organic layer, for decreasing the driving voltage and enhancing the light emission luminance, and includes a hole injection layer and an electron injection layer, which may be provided between the anode and the light-emitting layer or the hole transport layer and between the cathode and the light emitting layer or the electron transport layer. The injection layer may be provided depending on necessity.

### (Blocking Layer)

The blocking layer is a layer that is capable of inhibiting charges (electrons or holes) and/or excitons present in the light-emitting layer from being diffused outside the light-emitting layer. The electron blocking layer may be disposed between the light-emitting layer and the hole transport layer, and inhibits electrons from passing through the light-emitting layer toward the hole transport layer. Similarly, the hole blocking layer may be disposed between the light-emitting layer and the electron transport layer, and inhibits holes from passing through the light-emitting layer toward the electron transport layer. The blocking layer may also be used for inhibiting excitons from being diffused outside the light-emitting layer. Thus, the electron blocking layer and the hole blocking layer each may also have a function as an exciton blocking layer. The term “the electron blocking layer” or “the exciton blocking layer” referred to herein is intended to include a layer that has both the functions of an electron blocking layer and an exciton blocking layer by one layer.

### (Hole Blocking Layer)

The hole blocking layer has the function of an electron transport layer in a broad sense. The hole blocking layer has a function of inhibiting holes from reaching the electron transport layer while transporting electrons, and thereby enhances the recombination probability of electrons and holes in the light-emitting layer. As the material for the hole blocking layer, the material for the electron transport layer to be mentioned below may be used optionally.

### (Electron Blocking Layer)

The electron blocking layer has the function of transporting holes in a broad sense. The electron blocking layer has a function of inhibiting electrons from reaching the hole transport layer while transporting holes, and thereby enhances the recombination probability of electrons and holes in the light-emitting layer

### (Exciton Blocking Layer)

The exciton blocking layer is a layer for inhibiting excitons generated through recombination of holes and electrons in the light-emitting layer from being diffused to the charge transporting layer, and the use of the layer inserted enables effective confinement of excitons in the light-emitting layer, and thereby enhances the light emission efficiency of the device. The exciton blocking layer may be inserted adjacent to the light-emitting layer on any of the side of the anode and the side of the cathode, and on both the sides. Specifically, in the case where the exciton blocking layer is present on the side of the anode, the layer may be inserted between the hole transport layer and the light-emitting layer and adjacent to the light-emitting layer, and in the case where the layer is inserted on the side of the cathode, the layer may be inserted between the light-emitting layer and the cathode and adjacent to the light-emitting layer. Between the anode and the exciton blocking layer that is adjacent to the light-emitting layer on the side of the anode, a hole injection layer, an electron blocking layer and the like may be provided, and between the cathode and the exciton blocking layer that is adjacent to the light-emitting layer on the side of the cathode, an electron injection layer, an electron transport layer, a hole blocking layer and the like may be provided, in the case where the blocking layer is provided, preferably, at least one of the excited singlet energy and the excited triplet energy of the material used as the blocking layer is higher than the excited singlet energy and the excited triplet energy of the light-emitting layer, respectively, of the light-emitting material.

### (Hole Transport Layer)

The hole transport layer is formed of a hole transport material having a function of transporting holes, and the hole transport, layer may be provided as a single layer or plural layers.

The hole transport material has one of injection or transporting property of holes and blocking property of electrons, and may be any of an organic material and an inorganic material. Examples of known hole transport materials that may be used herein include a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer. Among these, a porphyrin compound, an aromatic tertiary amine compound and a styrylamine compound are preferably used, and an aromatic tertiary amine compound is more preferably used.

### (Electron Transport Layer)

The electron transport layer is formed of a material having a function of transporting electrons, and the electron transport layer may be a single layer or may be formed of plural layers.

The electron transport material (often also acting as a hole blocking material) may have a function of transmitting the electrons injected from a cathode to a light-emitting layer. The electron transport layer usable here includes, for example, nitro-substituted fluorene derivatives, diphenylquinone derivatives, thiopyran dioxide derivatives, carbodiimides, fluorenylidenemethane derivatives, anthraquinodimethane and anthrone derivatives, oxadiazole derivatives, etc. Further, thiadiazole derivatives derived from the above-mentioned oxadiazole derivatives by substituting the oxygen atom in the oxadiazole ring with a sulfur atom, and quinoxaline derivatives having a quinoxaline ring known as an electron-attractive group are also usable as the electron transport material. Further, polymer materials prepared by introducing these materials into the polymer chain, or having these material in the polymer main chain are also usable.

In producing the organic electroluminescent device, the compound represented by the general formula (1) may be used not only in the light-emitting layer but also in any other layer than the light-emitting layer. In so doing, the compound represented by the general formula (1) used in the light-emitting layer and the compound represented by the general formula (1) used in the other layer than the light-emitting layer may be the same as or different from each other. For example, the compound represented by the general formula (1) may be used in the above-mentioned injection layer, the blocking layer, the hole blocking layer, the electron blocking layer, the exciton blocking layer, the hole transport layer, and the electron transport layer. The method for forming these layers is not specifically limited, and the layers may be formed according to any of a dry process or a wet process.

Preferred materials for use for the organic electroluminescent device are concretely exemplified below. However, the materials for use in the present invention are not limitatively interpreted by the following exemplary compounds. Compounds, even though exemplified as materials having a specific function, can also be used as other materials having any other function. R, R′, R₁ to R₁₀ in the structural formulae of the following exemplary compounds each independently represent a hydrogen atom or a substituent. X represent a carbon atom or a hetero atom to form the ring skeleton, n represents an integer of 3 to 5, Y represents a substituent, and m represents an integer of 0 or more.

First, preferred compounds for use as a host material in a light-emitting layer are mentioned below.

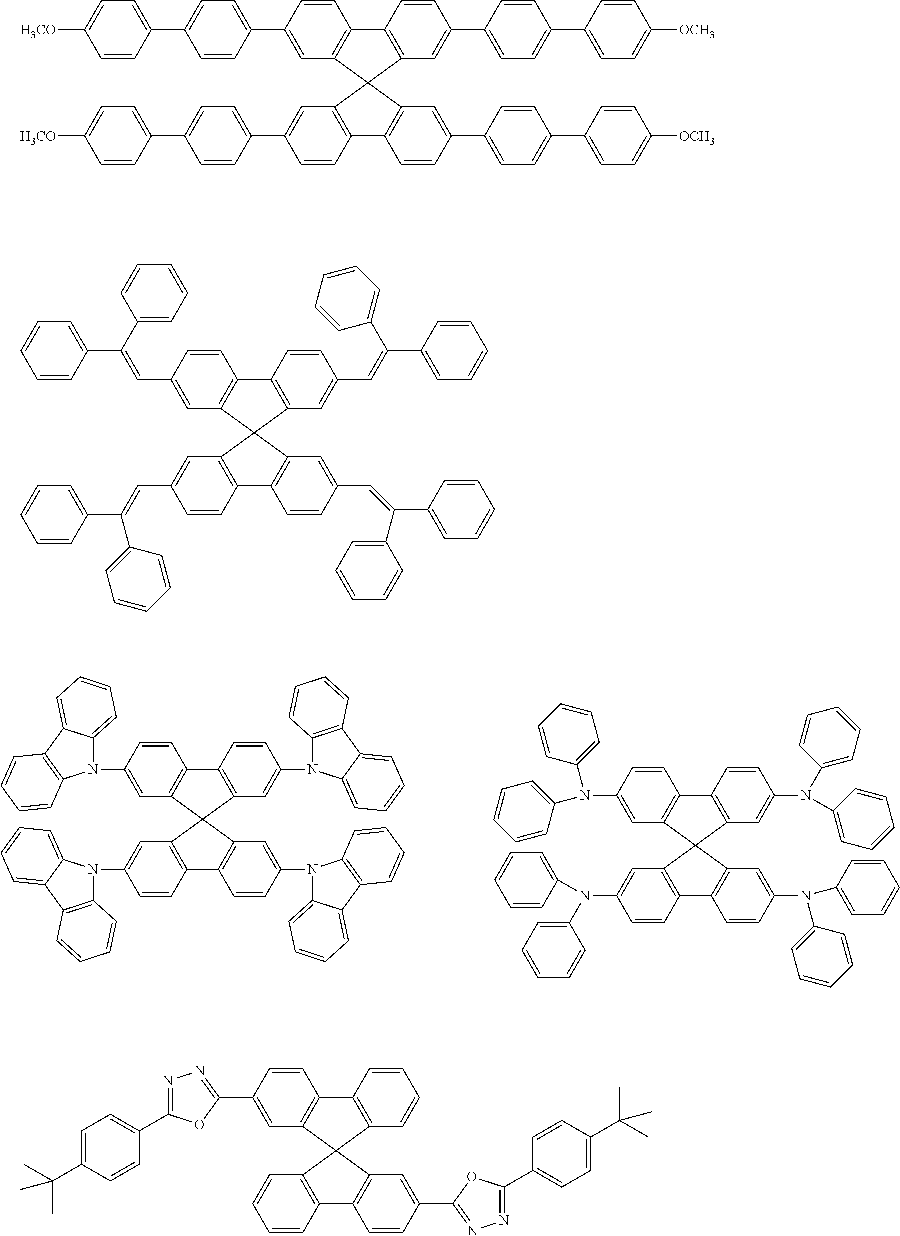

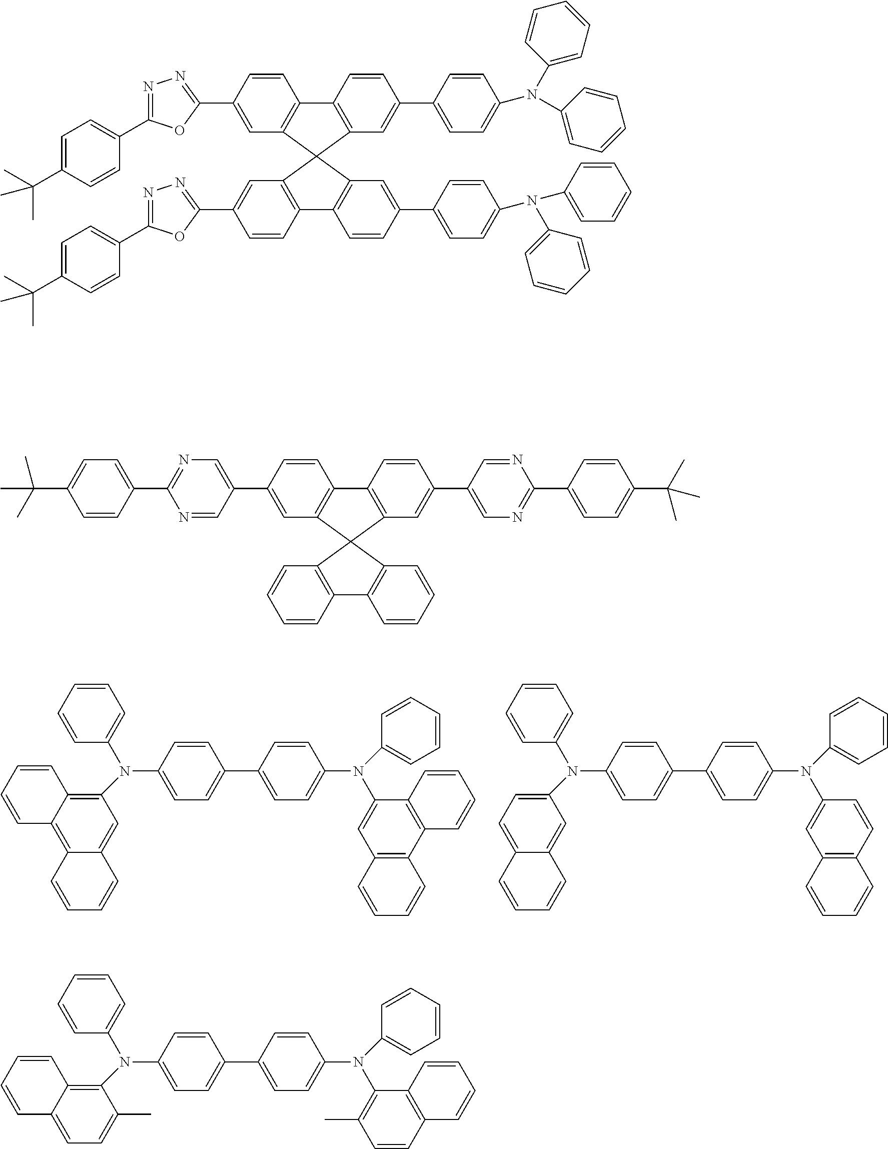

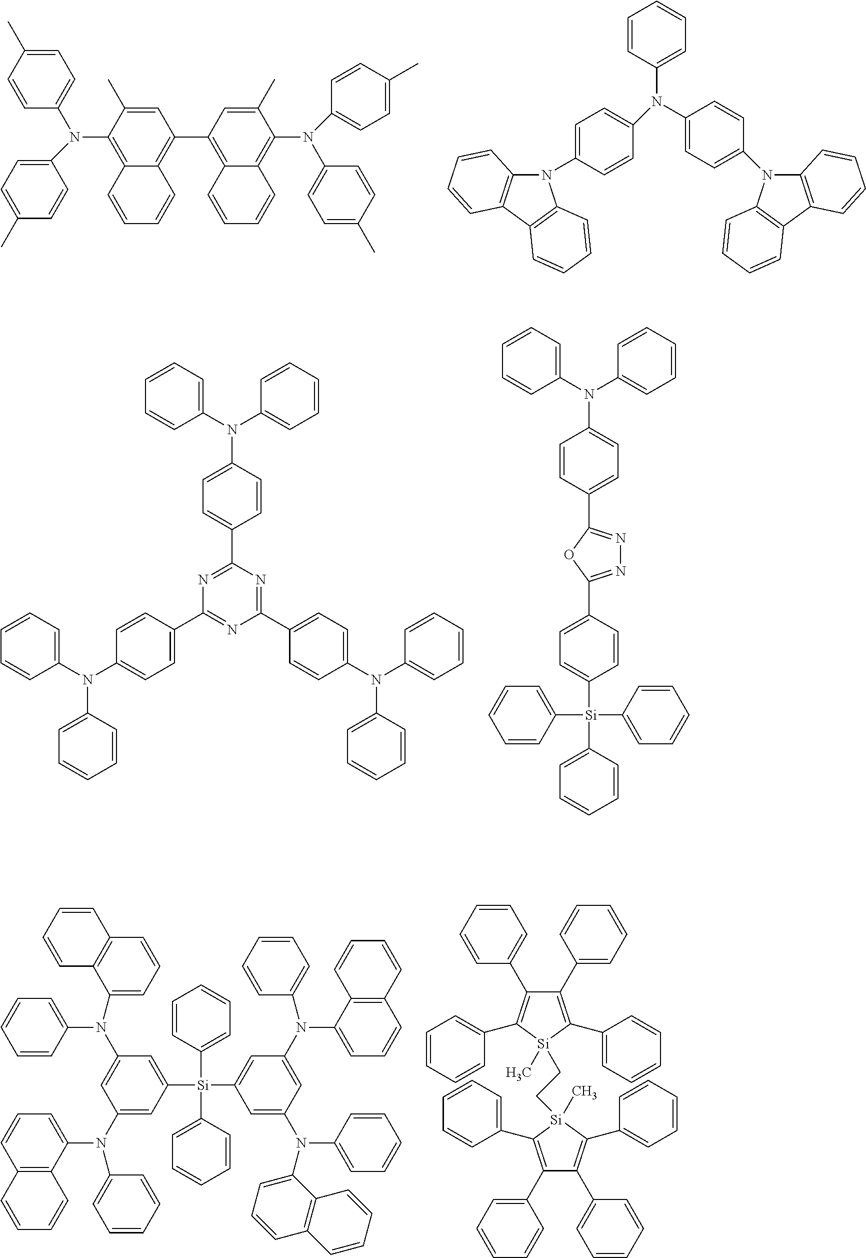

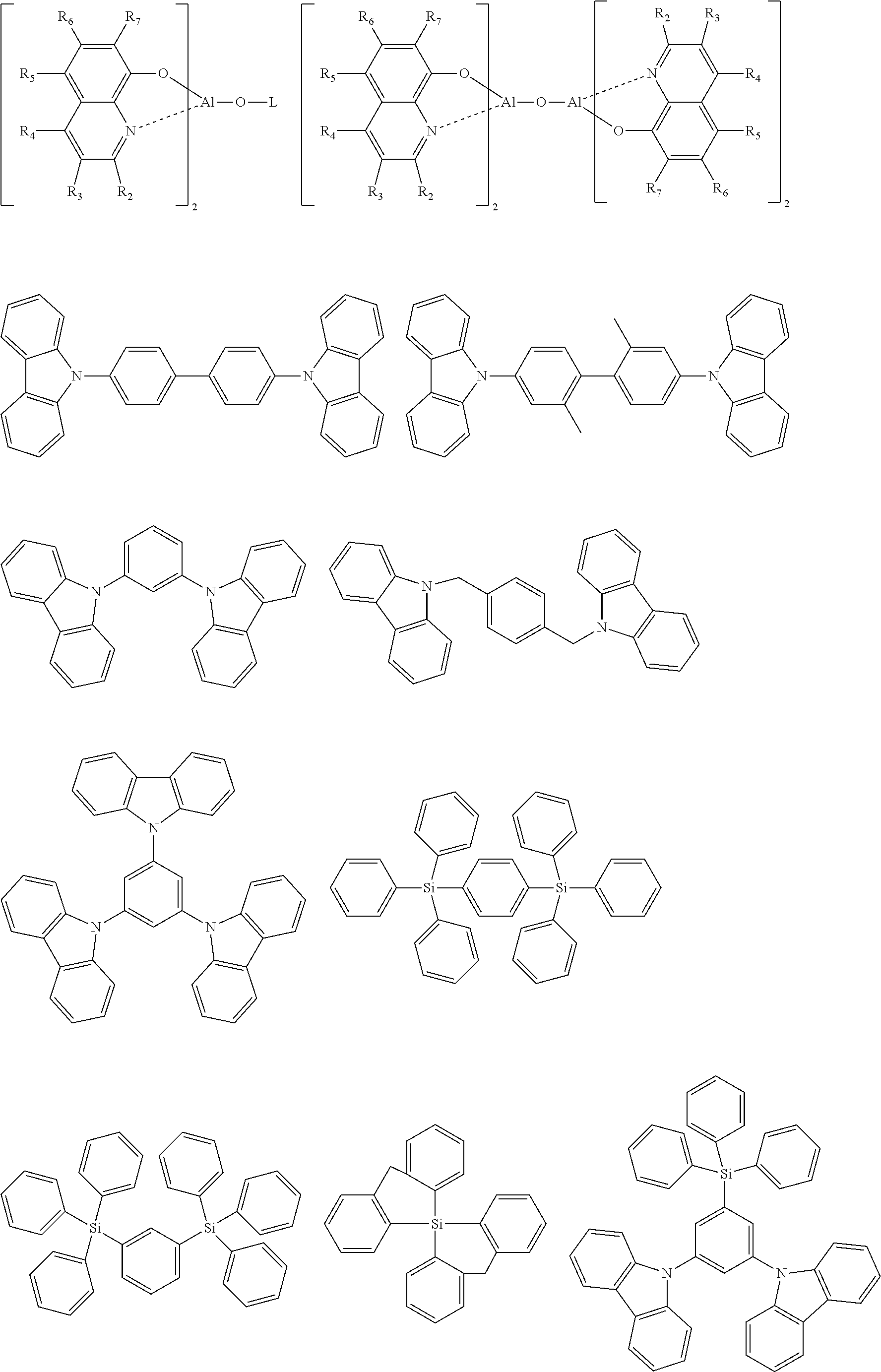

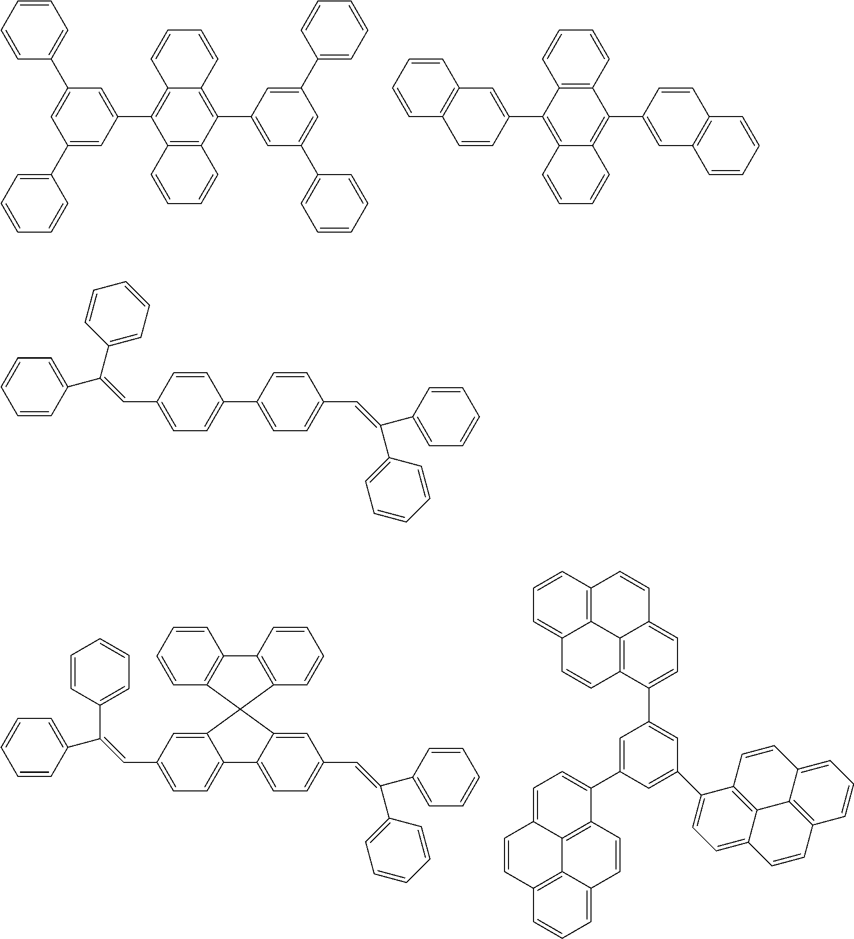

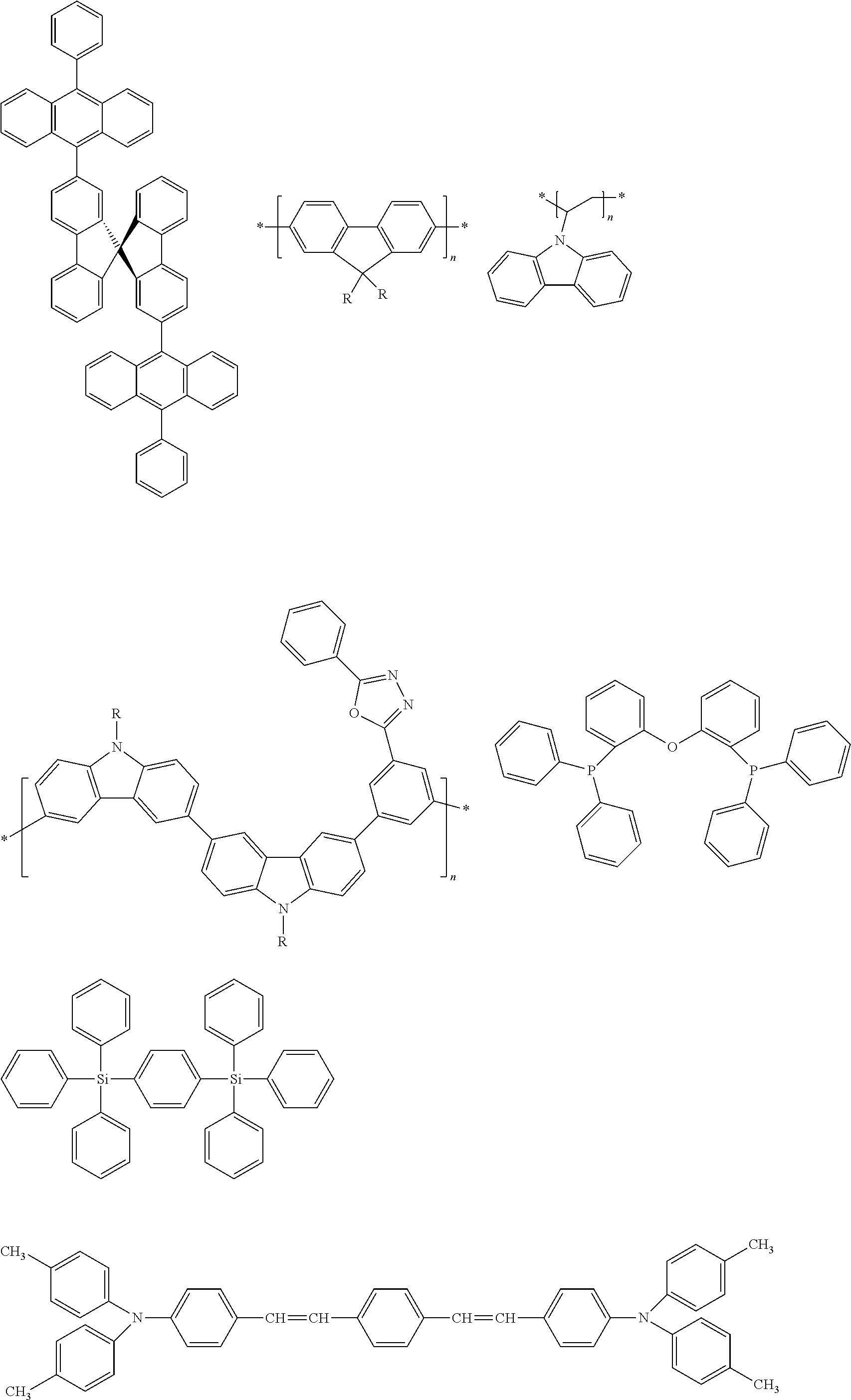

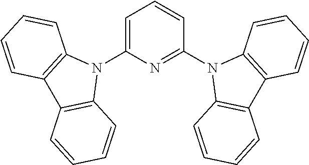 [SMILES: c1cc(-n2c3ccccc3c3ccccc32)nc(-n2c3ccccc3c3ccccc32)c1]

Next, preferred compounds for use as a hole injection. material are mentioned below.

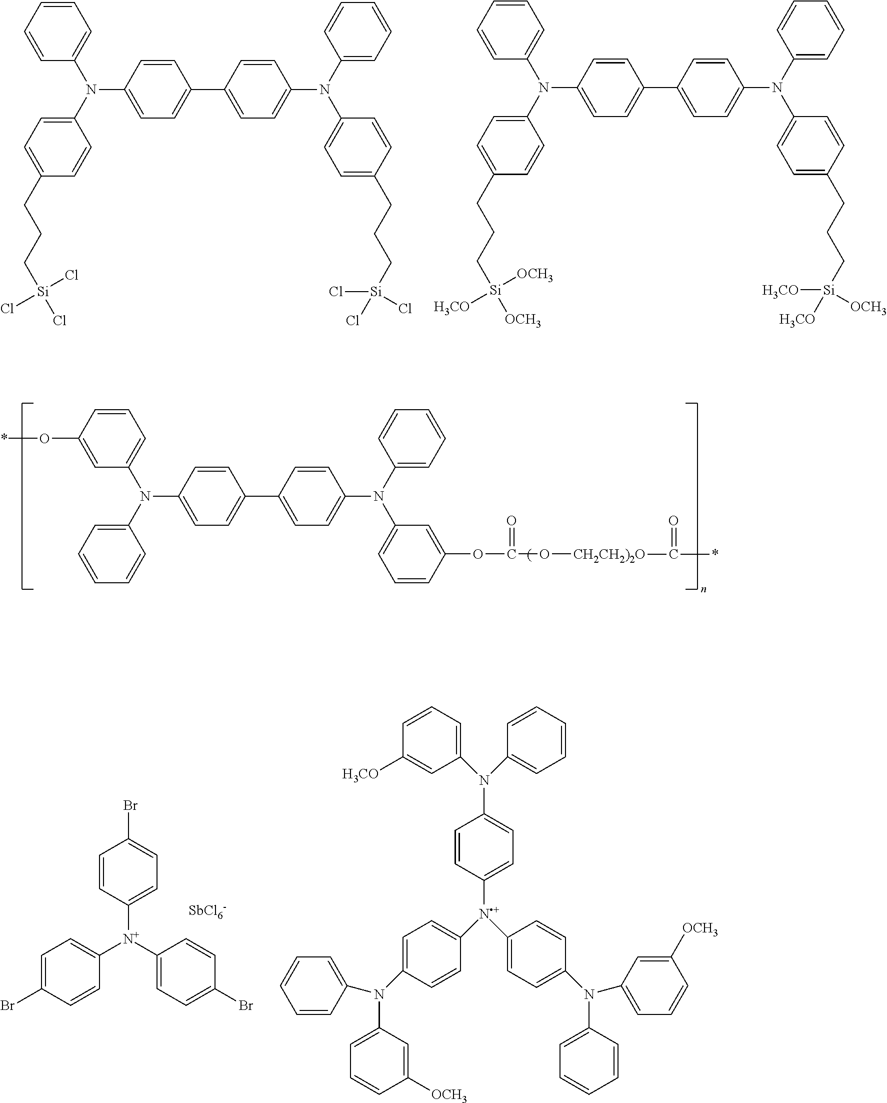

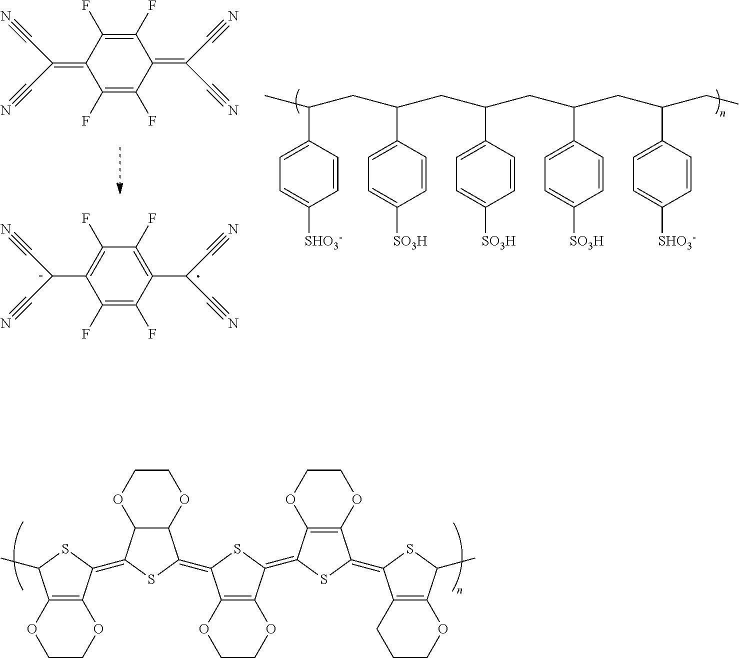

Next, preferred compounds for use as a hole transport material are mentioned below.

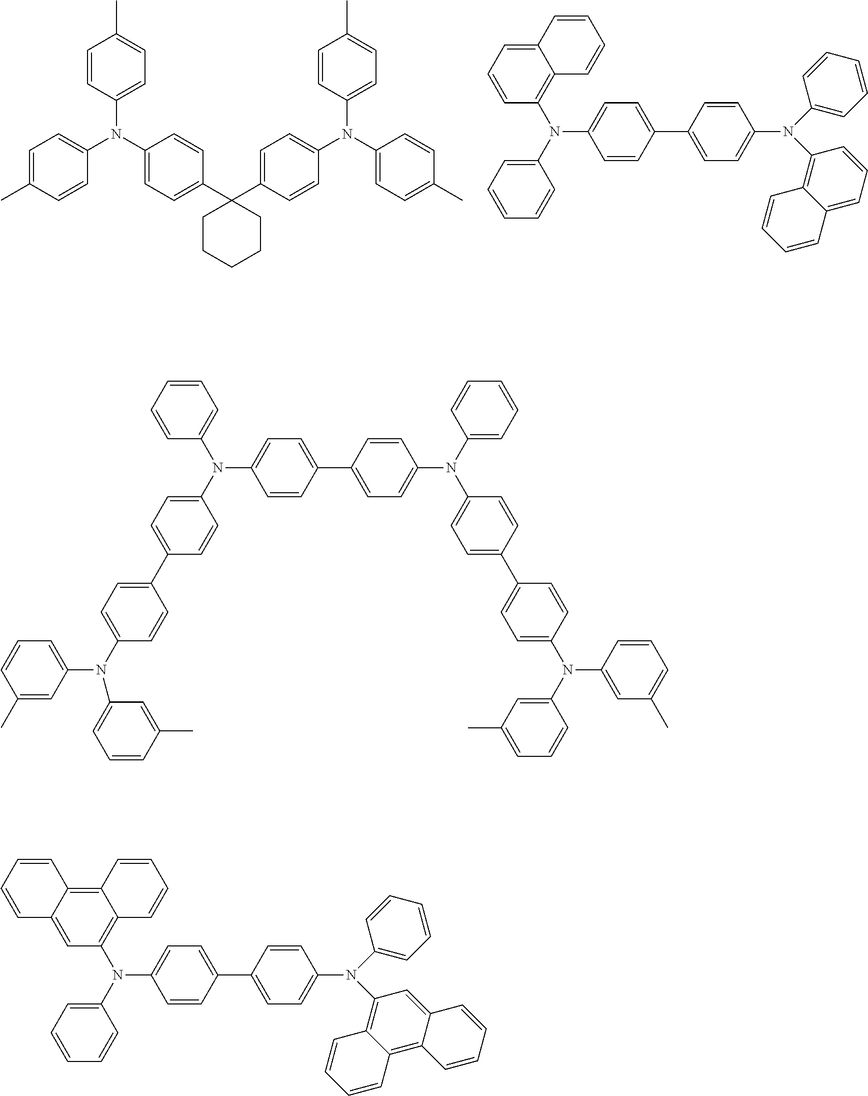

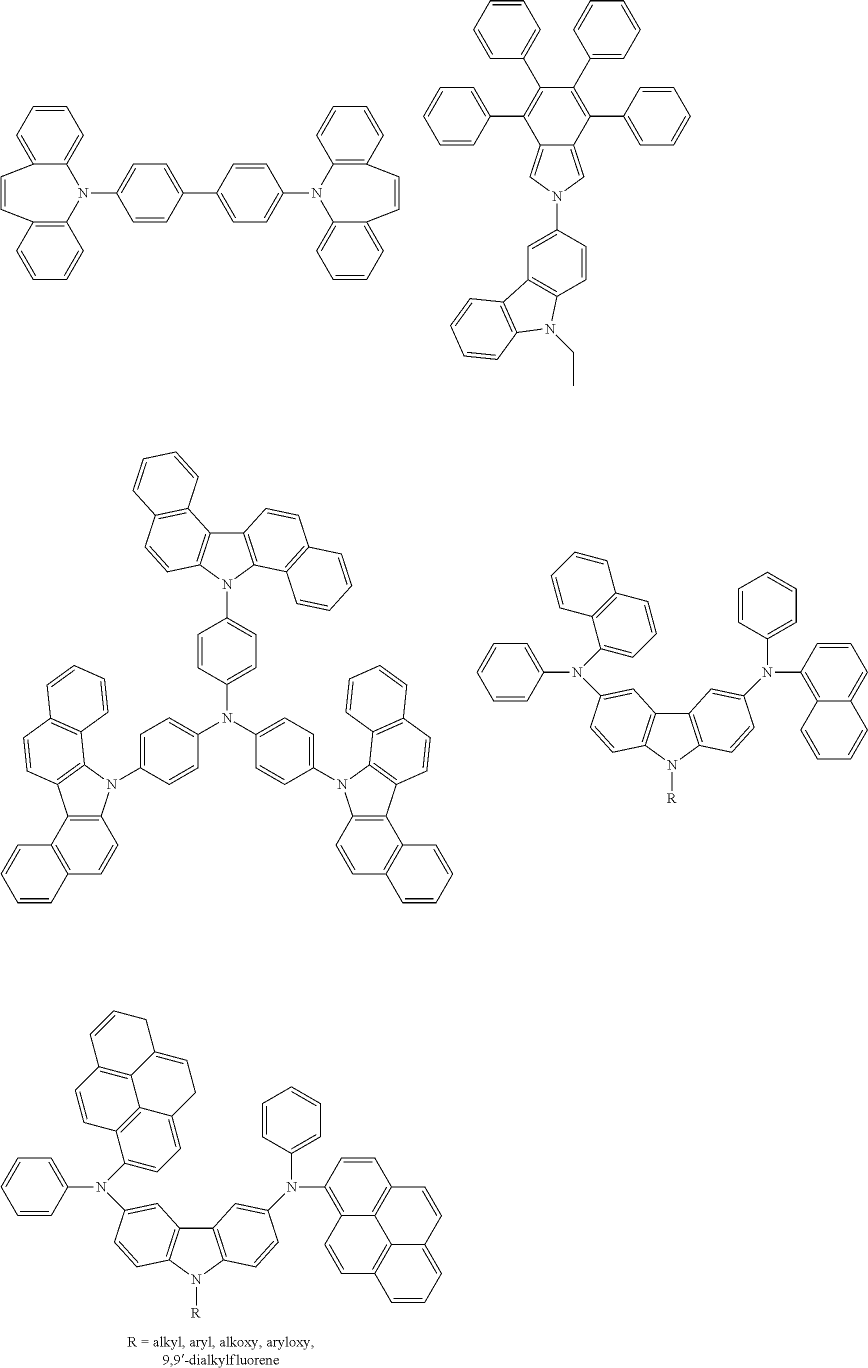

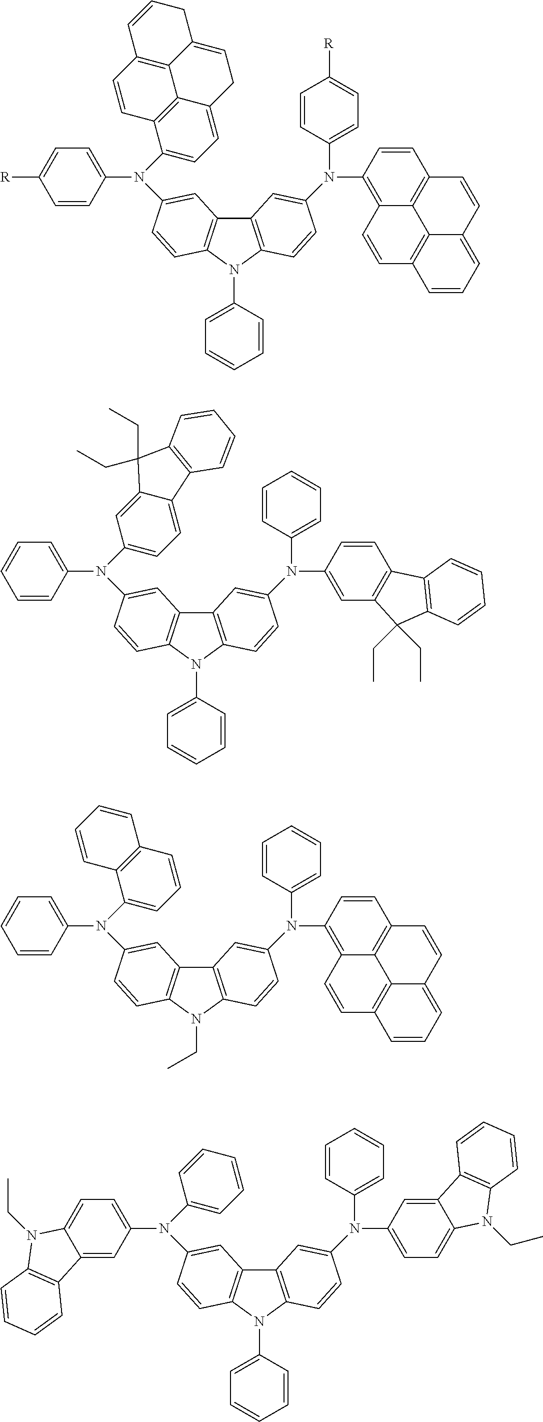

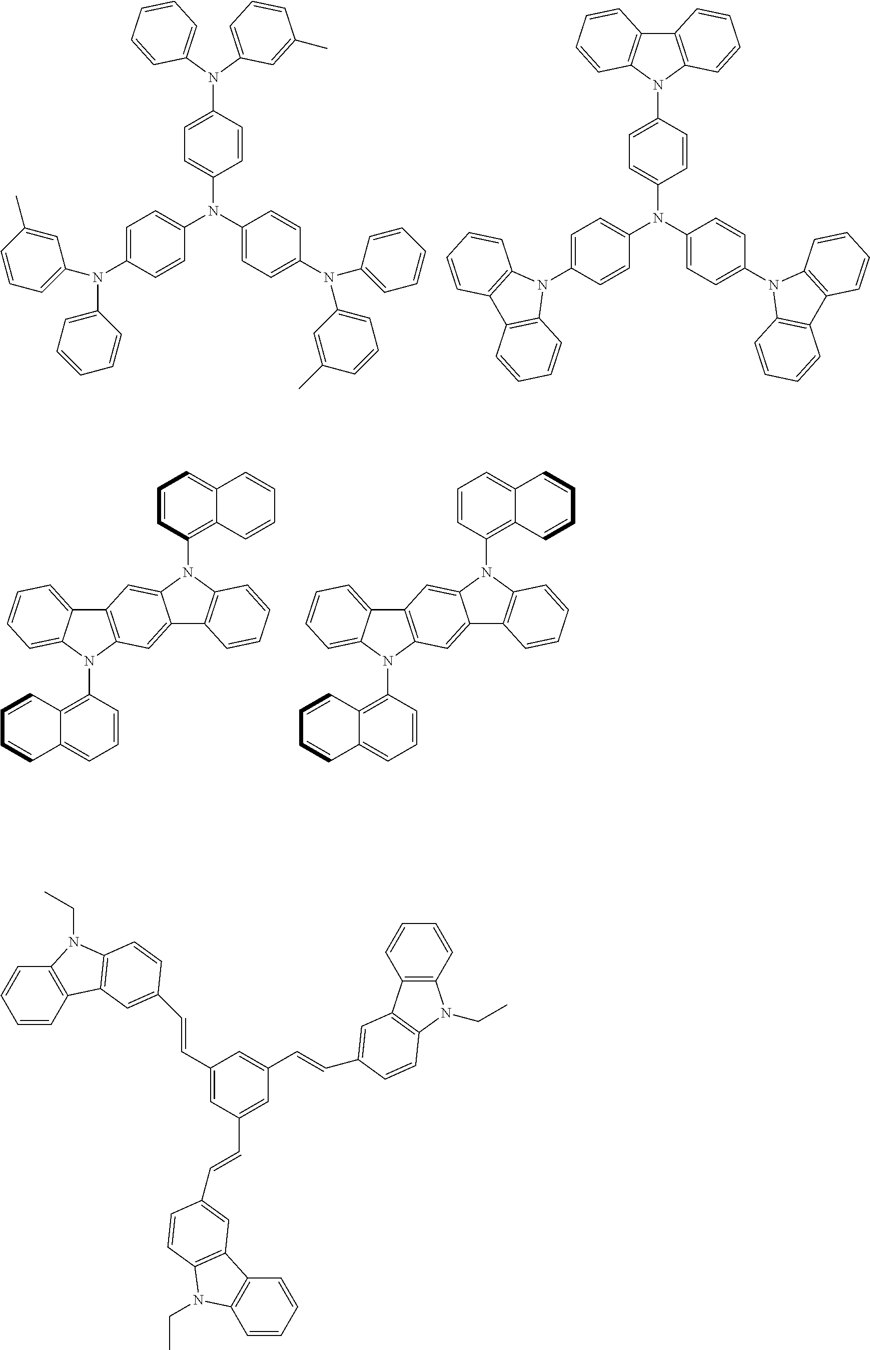

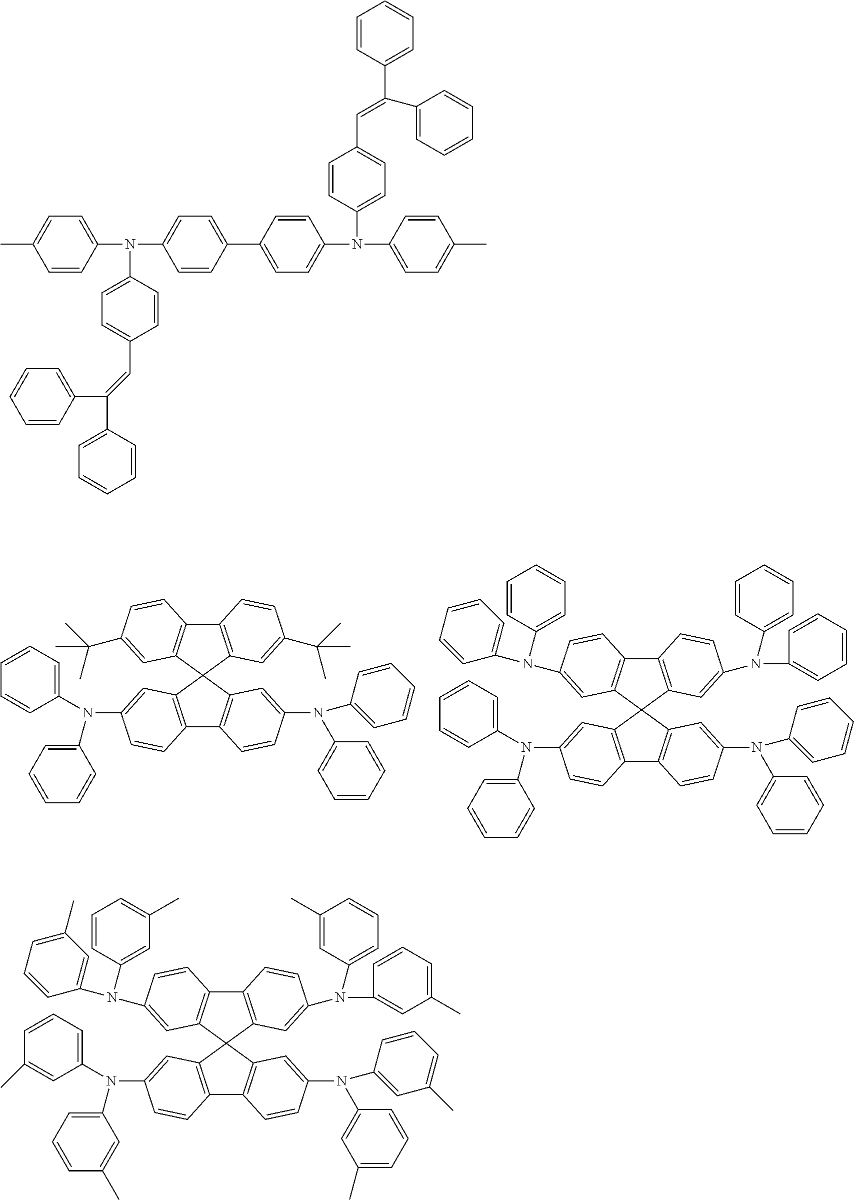

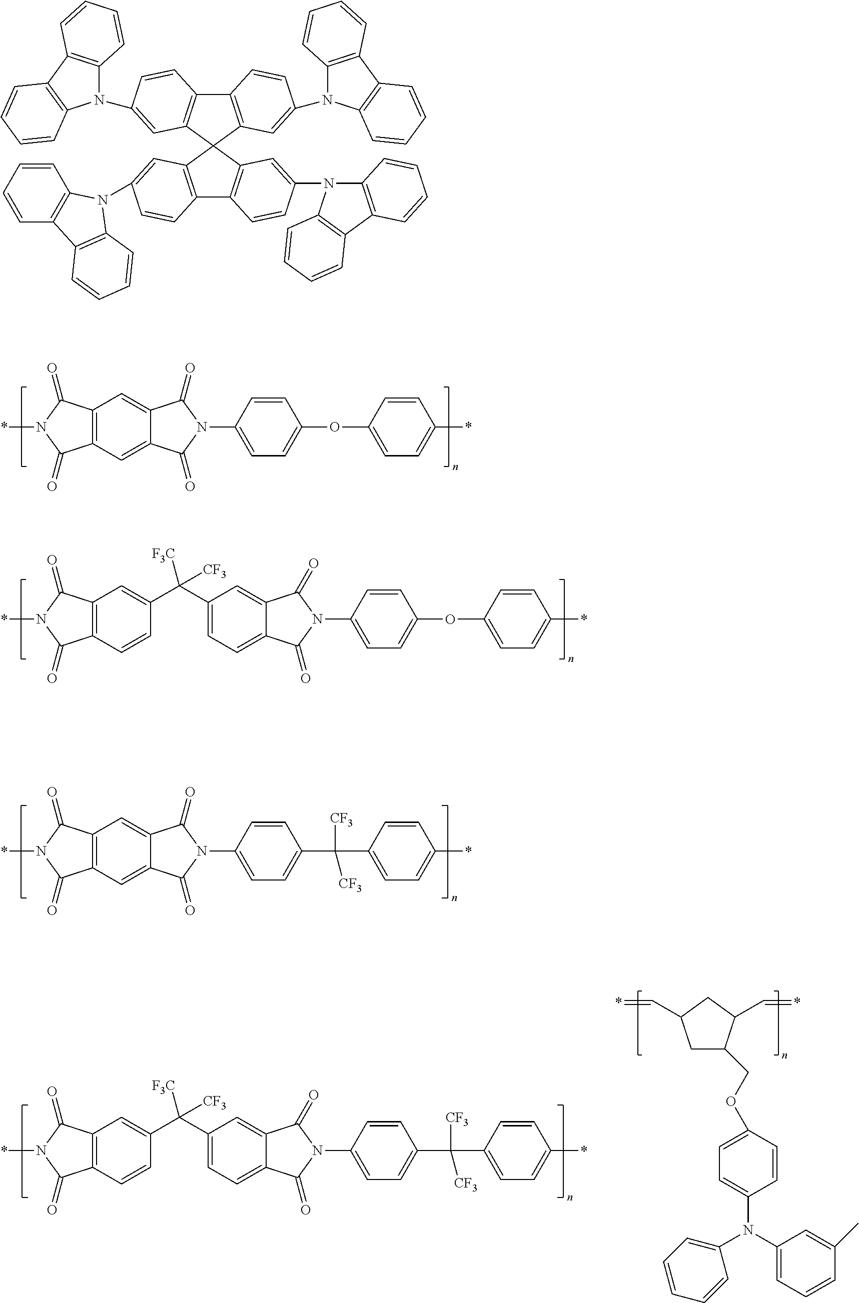

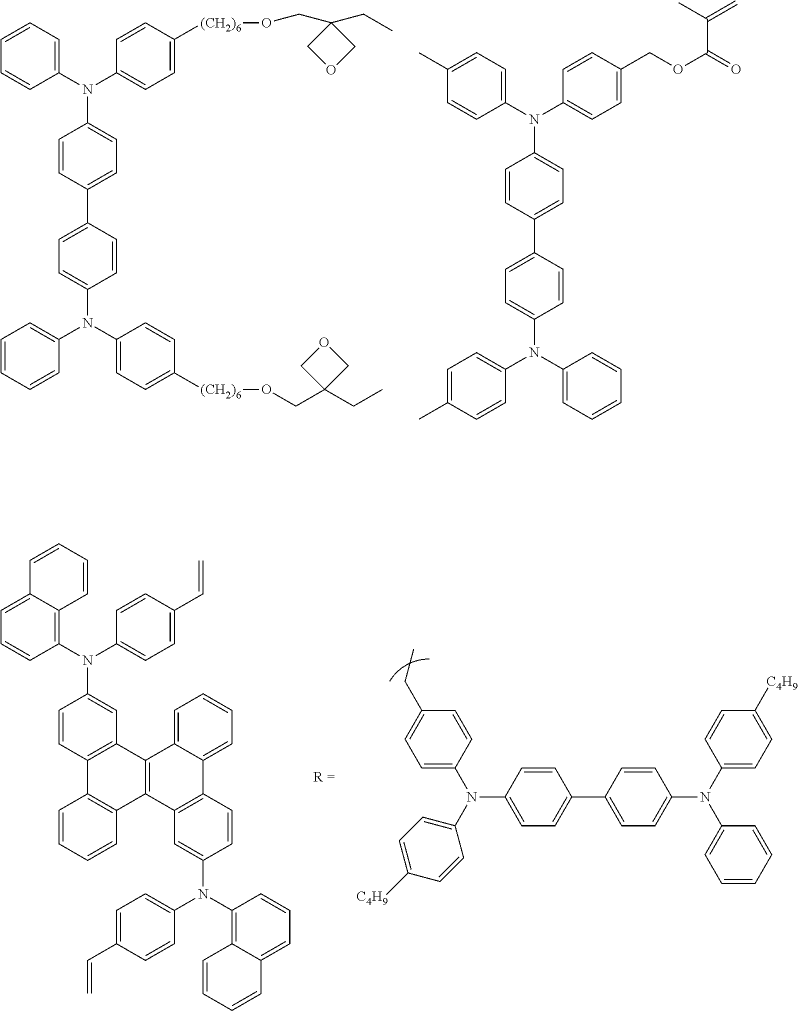

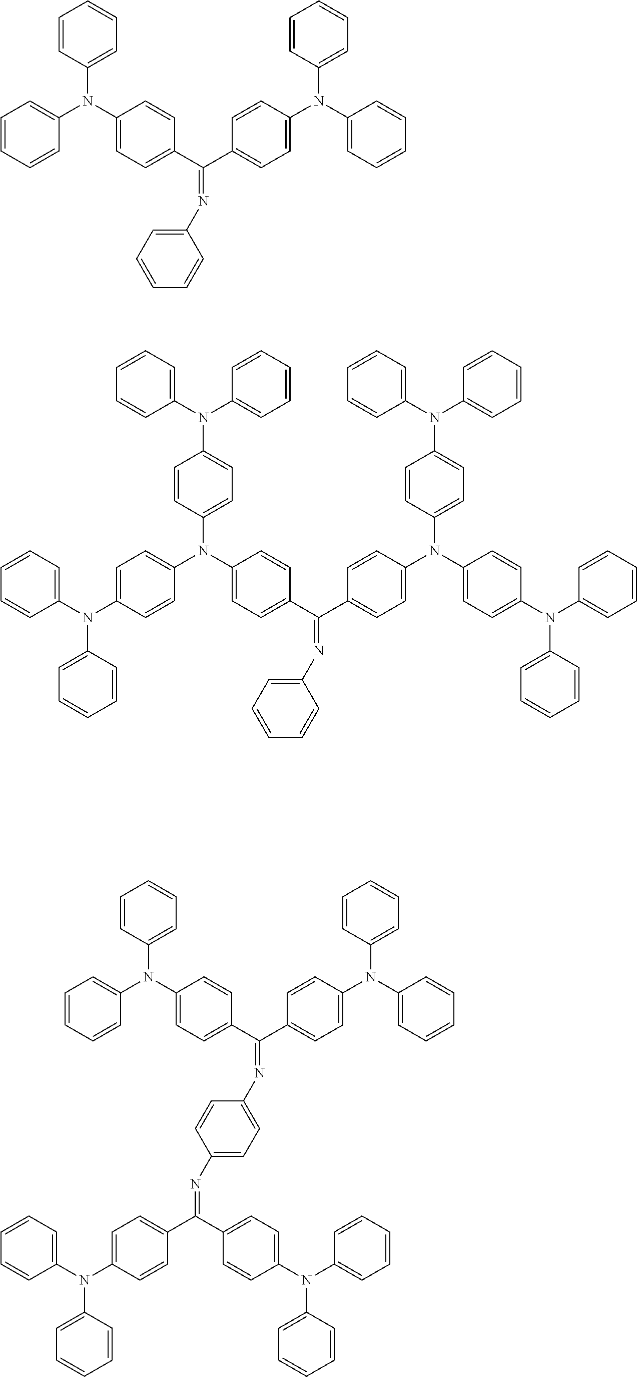 [SMILES: c1ccc(N=C(c2ccc(N(c3ccccc3)c3ccccc3)cc2)c2ccc(N(c3ccccc3)c3ccccc3)cc2)cc1 ; c1ccc(N=C(c2ccc(N(c3ccc(N(c4ccccc4)c4ccccc4)cc3)c3ccc(N(c4ccccc4)c4ccccc4)cc3)cc2)c2ccc(N(c3ccc(N(c4ccccc4)c4ccccc4)cc3)c3ccc(N(c4ccccc4)c4ccccc4)cc3)cc2)cc1 ; c1ccc(N(c2ccccc2)c2ccc(C(=Nc3ccc(N=C(c4ccc(N(c5ccccc5)c5ccccc5)cc4)c4ccc(N(c5ccccc5)c5ccccc5)cc4)cc3)c3ccc(N(c4ccccc4)c4ccccc4)cc3)cc2)cc1]

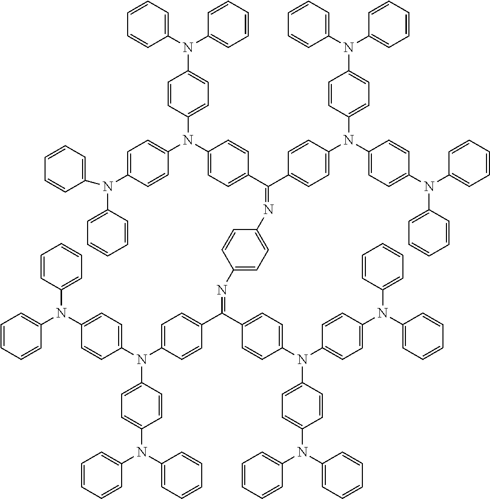 [SMILES: c1ccc(N(c2ccccc2)c2ccc(N(c3ccc(C(=Nc4ccc(N=C(c5ccc(N(c6ccc(N(c7ccccc7)c7ccccc7)cc6)c6ccc(N(c7ccccc7)c7ccccc7)cc6)cc5)c5ccc(N(c6ccc(N(c7ccccc7)c7ccccc7)cc6)c6ccc(N(c7ccccc7)c7ccccc7)cc6)cc5)cc4)c4ccc(N(c5ccc(N(c6ccccc6)c6ccccc6)cc5)c5ccc(N(c6ccccc6)c6ccccc6)cc5)cc4)cc3)c3ccc(N(c4ccccc4)c4ccccc4)cc3)cc2)cc1]

Next, preferred compounds for use as an electron blocking material are mentioned below.

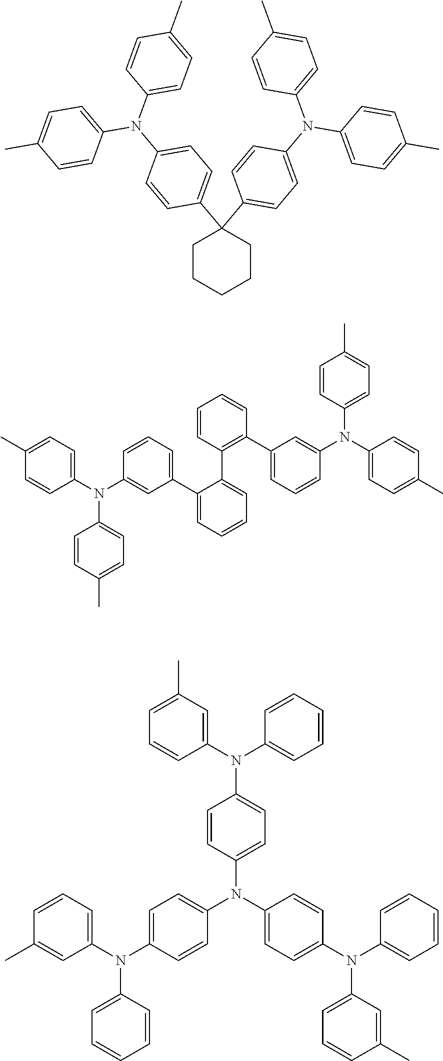

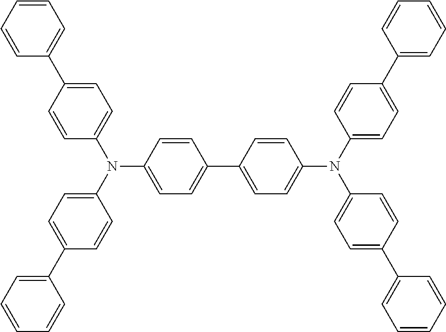 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

Next, preferred compounds for use as a hole blocking material are mentioned below.

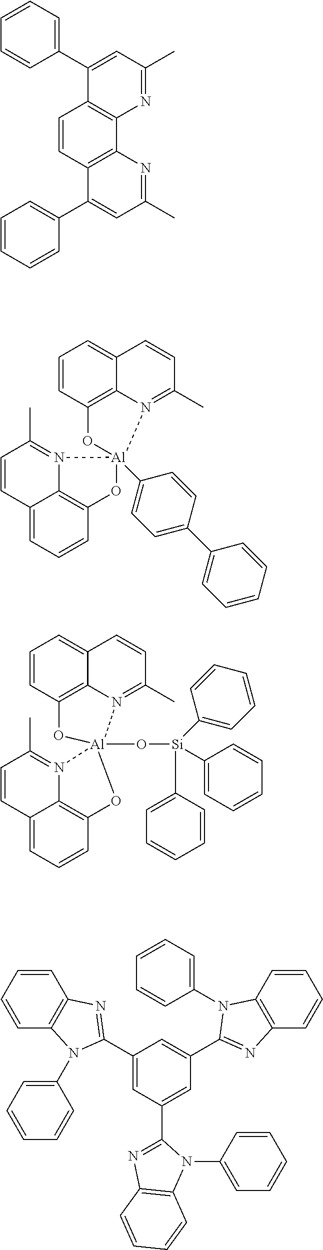

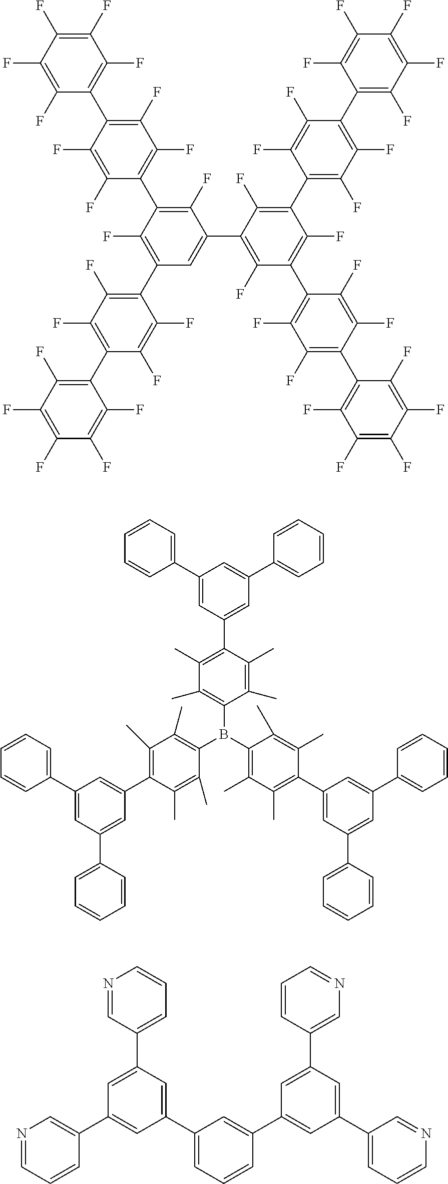 [SMILES: Fc1c(F)c(F)c(-c2c(F)c(F)c(-c3cc(-c4c(F)c(-c5c(F)c(F)c(-c6c(F)c(F)c(F)c(F)c6F)c(F)c5F)c(F)c(-c5c(F)c(F)c(-c6c(F)c(F)c(F)c(F)c6F)c(F)c5F)c4F)c(F)c(-c4c(F)c(F)c(-c5c(F)c(F)c(F)c(F)c5F)c(F)c4F)c3F)c(F)c2F)c(F)c1F ; Cc1c(C)c(-c2cc(-c3ccccc3)cc(-c3ccccc3)c2)c(C)c(C)c1B(c1c(C)c(C)c(-c2cc(-c3ccccc3)cc(-c3ccccc3)c2)c(C)c1C)c1c(C)c(C)c(-c2cc(-c3ccccc3)cc(-c3ccccc3)c2)c(C)c1C ; c1cncc(-c2cc(-c3cccnc3)cc(-c3cccc(-c4cc(-c5cccnc5)cc(-c5cccnc5)c4)c3)c2)c1]

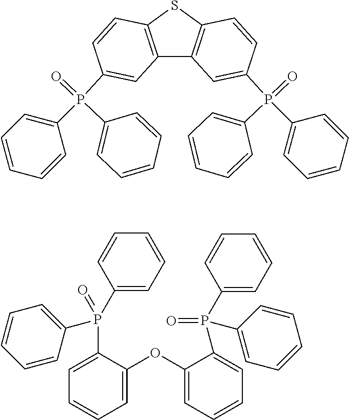 [SMILES: O=P(c1ccccc1)(c1ccccc1)c1ccc2sc3ccc(P(=O)(c4ccccc4)c4ccccc4)cc3c2c1 ; O=P(c1ccccc1)(c1ccccc1)c1ccccc1Oc1ccccc1P(=O)(c1ccccc1)c1ccccc1]

Next, preferred compounds for use as an electron transport material are mentioned below.

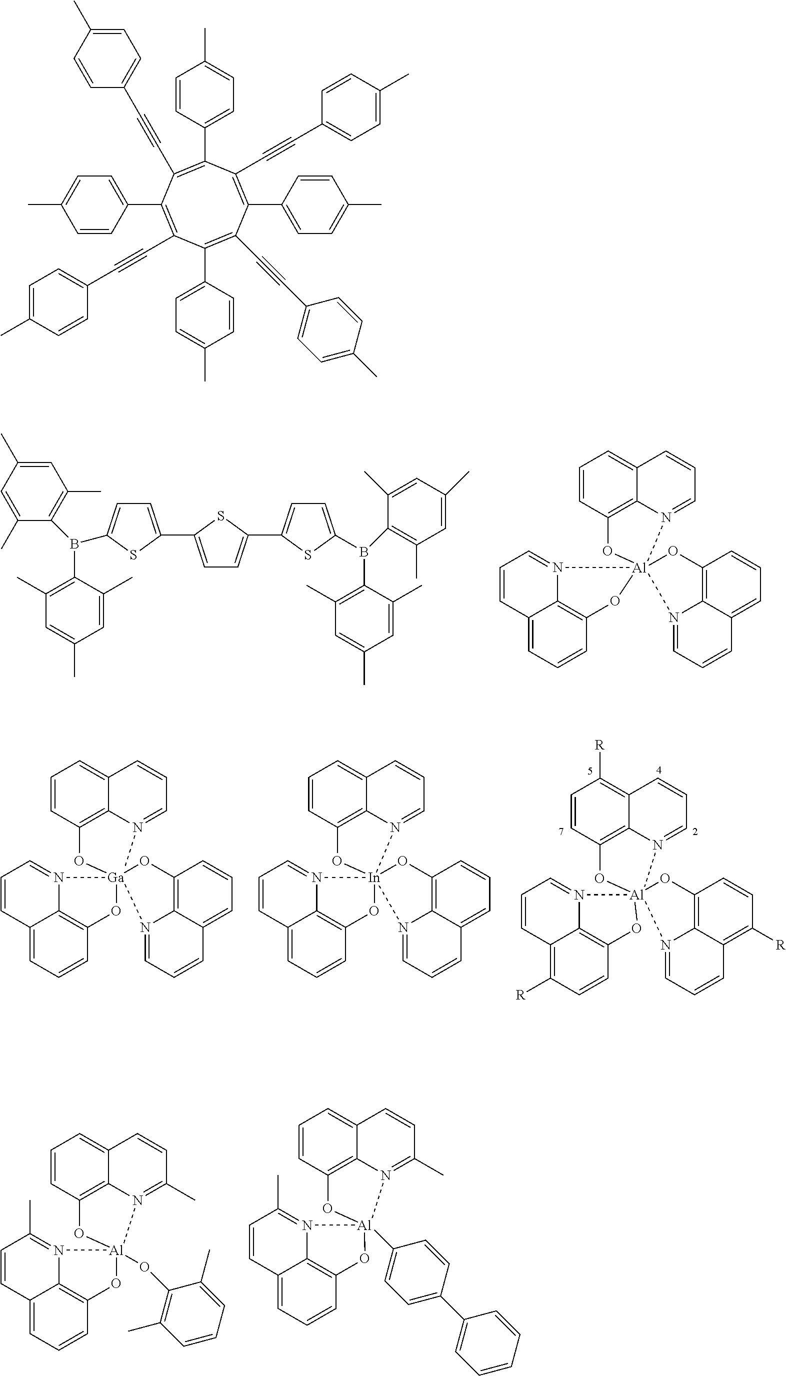

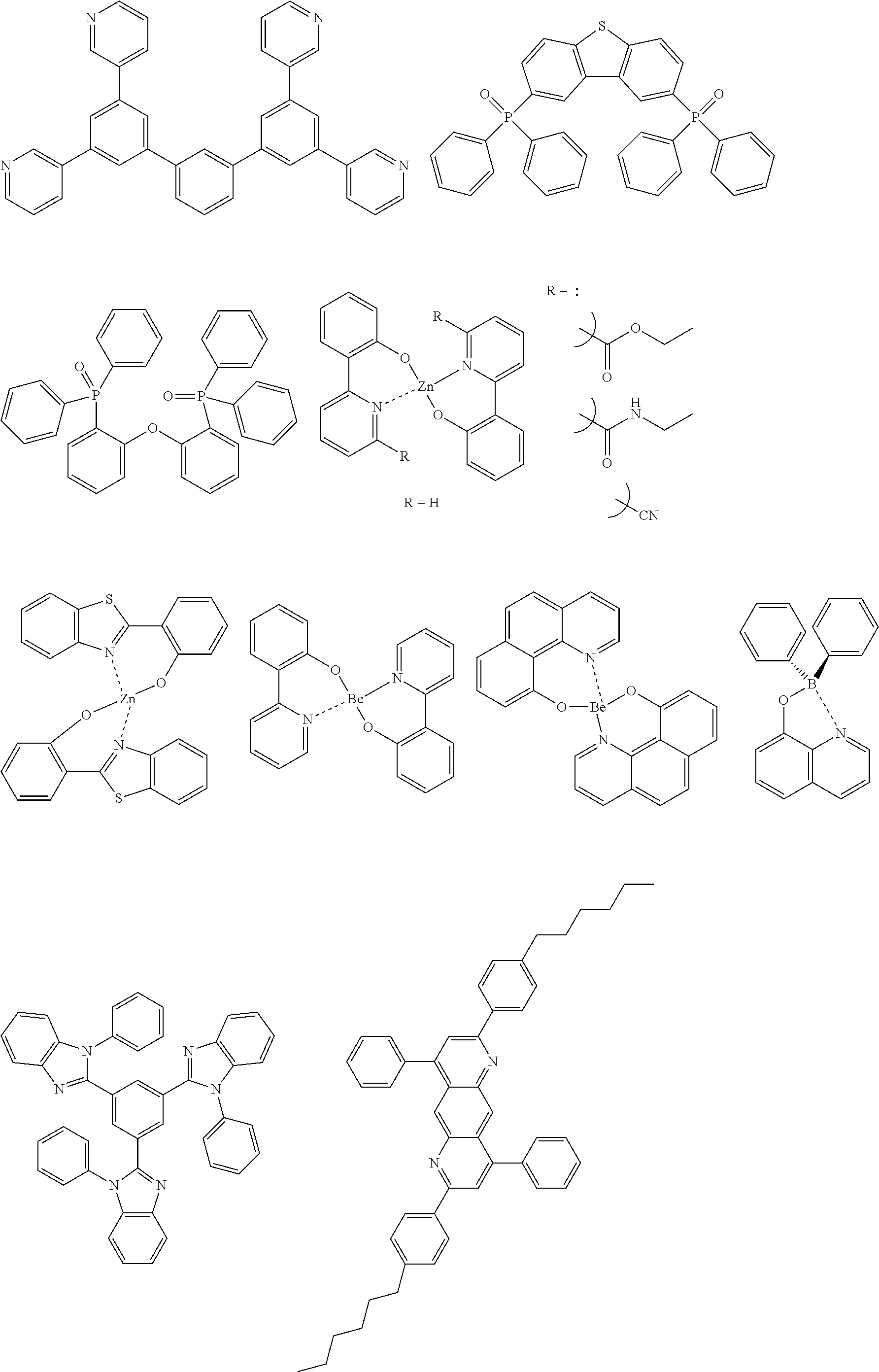

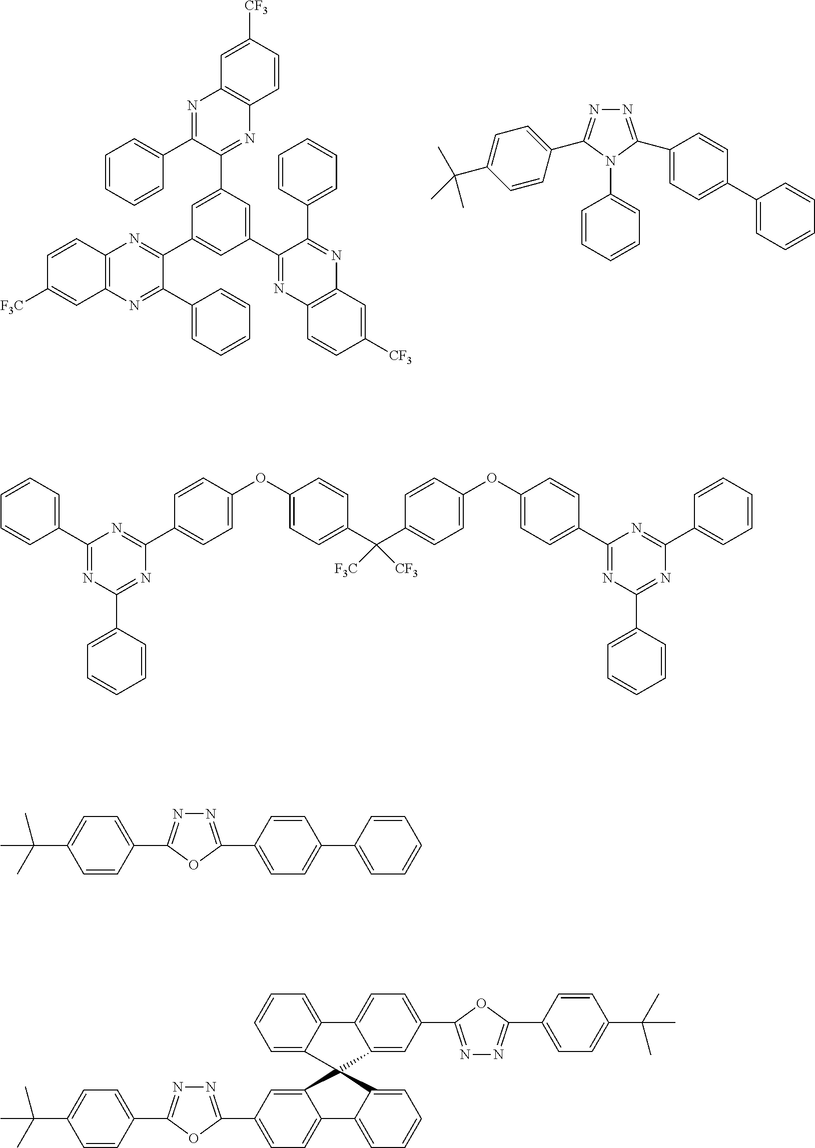

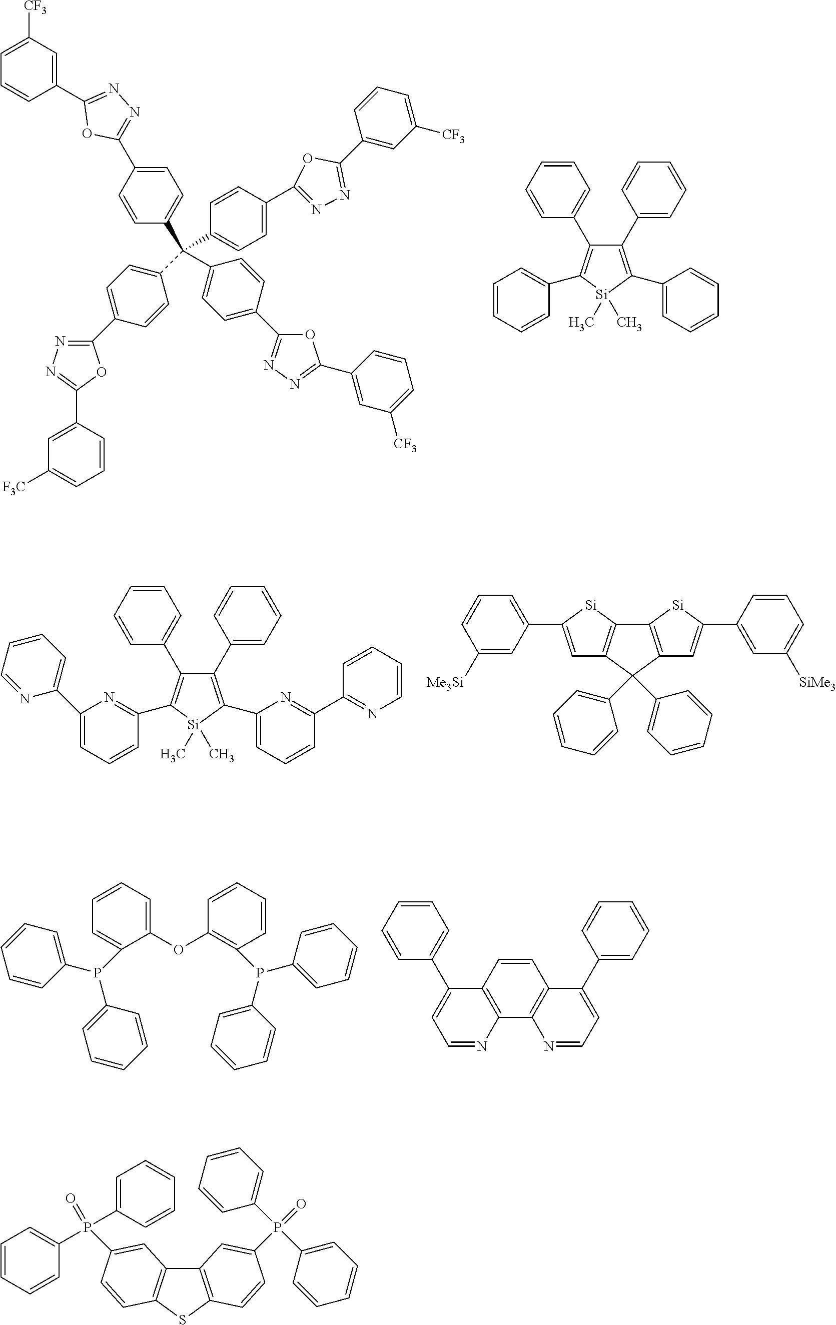

Next, preferred compounds for use as an electron injection material are mentioned below.

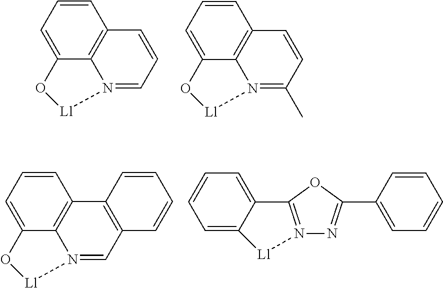

Further, preferred compounds for use as additional materials are mentioned below. For example, these are considered to be added as a stabilization material.

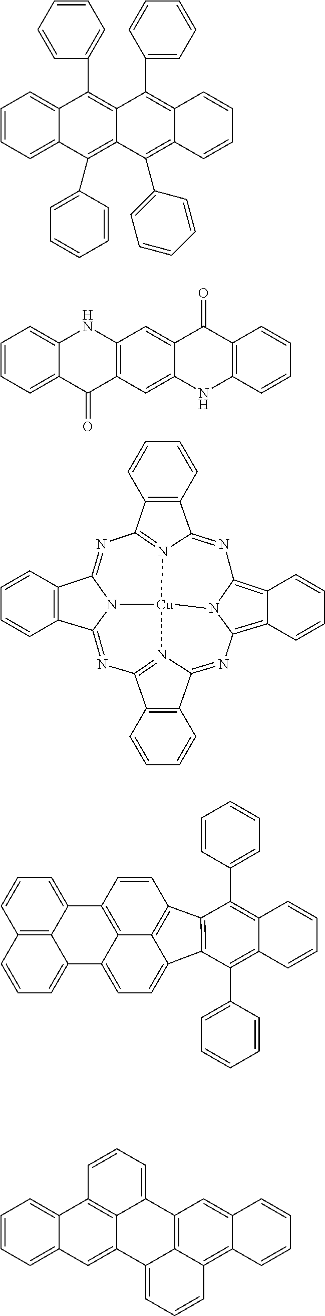

The organic electroluminescent device thus produced by the aforementioned method emits light on application of an electric field between the anode and the cathode of the device. In this case, when the light emission is caused by the excited singlet energy, light having a wavelength that corresponds to the energy level thereof may be confirmed as fluorescent light and delayed fluorescent light. When the light emission is caused by the excited triplet energy, light having a wavelength that corresponds to the energy level thereof may be confirmed as phosphorescent light. The normal fluorescent light has a shorter light emission lifetime than the delayed fluorescent light, and thus the light emission lifetime may be distinguished between the fluorescent light and the delayed fluorescent light.

On the other hand, the phosphorescent light may substantially not be observed with a normal organic compound such as the compound of the present invention at room temperature since the excited triplet energy is converted to heat or the like due to the instability thereof, and is immediately deactivated with a short lifetime. The excited triplet energy of the normal organic compound may be measured by observing light. emission under an extremely low temperature condition.

The organic electroluminescent device of the invention may be applied to any of a single device, a structure with plural devices disposed in an array, and a structure having anodes and cathodes disposed in an X-Y matrix. According to the present invention using a compound having a specific structure in a light-emitting layer, an organic light-emitting device having a markedly improved light emission efficiency can be obtained. The organic light-emitting device such as the organic electroluminescent device of the present invention may be applied to a further wide range of purposes. For example, an organic electroluminescent display apparatus may be produced with the organic electroluminescent device of the invention, and for the details thereof, reference may be made to S. Tokito, C. Adachi and H. Murata, “Yuki EL Display” (Organic EL Display) (Ohmsha, Ltd.). In particular, the organic electroluminescent device of the invention may be applied to organic electroluminescent illumination and backlight which are highly demanded.

### EXAMPLES

The features of the present invention will be described more specifically with reference to Synthesis Examples and Examples given below. The materials, processes, procedures and the like shown below may be appropriately modified unless they deviate from the substance of the invention. Accordingly, the scope of the invention is not construed as being limited to the specific examples shown below. The light emission characteristics were evaluated using a source meter (2400 Series, produced by Keithley Instruments Inc.), a semiconductor parameter analyzer (E5273A, produced by Agilent Technologies, Inc.), an optical power meter (1930C, produced by Newport Corporation), an optical spectrometer (USB2000, produced by Ocean Optics, Inc.), a spectroradiometer (SR-3, produced by Topcon Corporation), and a streak camera (Model C4334, produced by Hamamatsu Photonics K.K.).

### [Measurement of HOMO Energy Level and LUMO Energy Level]

Each energy level of HOMO and LUMO of the compounds used in Examples and Comparative Examples was measured according to the method mentioned below.

For the HOMO energy level, an oxidation potential (half value potential of a first oxidation wave) of each compound was measured in dichloromethane, and the HOMO energy level thereof was calculated according to the following expression provided in Org. Electronics, 2005, 6, 11-20.

HOMO(eV)=−1.4E_{1/2}(vs.Fc/Fc⁺)−4.6

In the above expression, E_{1/2}(vs.Fc/Fc⁺) is a half value potential of a first oxidation wave based on a ferrocene electrode.

For the LUMO energy level, the energy gap E_{gap} between the HOMO energy level and the LUMO energy level was determined from an absorption spectrum, and the a difference between the measured value of the HOMO energy level and the energy gap E_{gap} was calculated to determine the LUMO energy level. The energy gap E_{gap} was determined from the wavelength value at the intersection point between the tangent line to the rising on the short wavelength side of the absorption spectrum and the abscissa.

### Synthesis Example 1

### Synthesis of Compound 1

A compound 1 was synthesized according to the following reaction.

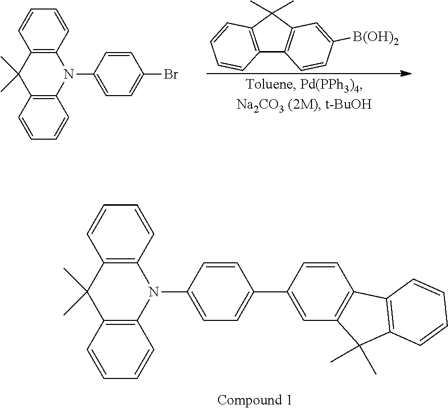 [SMILES: CC1(C)c2ccccc2N(c2ccc(Br)cc2)c2ccccc21 ; CC1(C)c2ccccc2-c2ccc(B(O)O)cc21 ; CC1(C)c2ccccc2-c2ccc(-c3ccc(N4c5ccccc5C(C)(C)c5ccccc54)cc3)cc21]

4-(9,9-Dimethyl-9,10-dihydroacridine)bromobenzene (1.1. g, 3 mmol), 9,9-dimethyl-2-fluoreneboronic acid (850 mg, 3.6 mmol), tetrakis(triphenylphosphine)palladium(0) (170 mg, 0.15 mmol), toluene (60 mL), t-butanol (15 mL) and an aqueous sodium carbonate solution (2 M, 20 mL) were put into a container, and the container was degassed under reduced pressure and purged with nitrogen. The container was put into an oil bath, and the mixture in the container was heated at 100° C. for 24 hours. After the heating, the reaction liquid was cooled to room temperature, whereupon it was separated into two layers of an aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane (1/3) as an eluent. The resultant fraction was concentrated to give a white solid of the intended compound 1 at a production quantity of 1.1 g and a yield of 77%.
¹H-NMR (500 MHz, CDCl₃): δ=7.92 (d, J=8.4 Hz, 2 H), 7.85 (d, J=7.9 Hz, 1H), 7.82-7.75 (m, 2H), 7.69 (dd, J=7.8, 1.6 Hz, 1H), 7.49-7.47 (m, 3H), 7.43 (d, J=8.4 Hz, 2H), 7.37 (pd, J=7.4; 1.4 Hz, 2H), 7.05-6.98 (m, 2H), 6.98-6.91 (m, 2H), 6.40 (dd, J=8.2, 1.2 Hz, 2H), 1.73 (s, 6H), 1.59 (s, 6H).
¹³C-NMR (125 MHz, CDCl₃): δ=154.4, 153.9, 141.4, 140.9, 140.2, 139.4, 138.9, 138.8, 131.6, 130.0, 129.5, 127.4, 127.1, 126.4, 126.3, 125.3, 122.7, 121.4, 120.5, 120.4, 120.2, 114.1, 47.0, 36.0, 31.3, 27.3.
APCI-MSm/z: 477 M⁺
Anal. Calcd for C₃₆H₃₁N: C, 90.53; H, 6.54; N, 2.93.

Found: C, 90.54; H, 6.53; N, 2.97.

### Synthesis Example 2

### Synthesis of Compound 2

First, an intermediate a was synthesized according to the following reaction

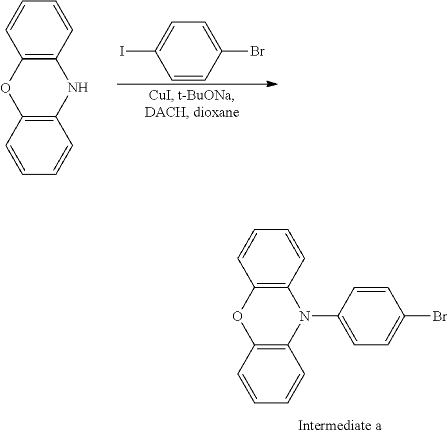 [SMILES: c1ccc2c(c1)Nc1ccccc1O2 ; Brc1ccc(I)cc1 ; Brc1ccc(N2c3ccccc3Oc3ccccc32)cc1]

Phenoxazine (3.67 g, 20 mmol), 4-iodo-bromobenzene (5.66 g, 20 mmol), copper iodide (110 mg, 0.6 mmol), sodium tert-butoxide (2.95 g, 30 mmol), 1,2-diaminocyclohexane (0.20 mL) and 1,4-dioxane (50 mL) were put into a container, then the container was purged with nitrogen, and the mixture in the container was stirred at 100° C. for 24 hours. After the stirring, the reaction liquid was cooled to room temperature and water (50 mL) was added thereto, whereupon the liquid was separated into two layers of an aqueous layer and an organic layer. Among these, the aqueous layer was collected, and extracted three times with ethyl acetate (30 mL). The resultant organic layer was washed two times with. saturated saline water (30 mL), then dried with sodium sulfate added thereto, and filtered. The solvent was removed froth the resultant filtrate, and the remaining residue was purified through silica gel column chromatography using hexane as an eluent. The resultant fraction was concentrated to give a white solid of the intermediate a at a production quantity of 5.25 g and a yield of 52%.
¹H-NMR (500 MHz, CDCl₃): δ=7.73 (d, J=8.6 Hz, 2H), 7.24 (d, J=8.6 Hz, 2H), 6.71-6.64 (m, 4H), 6.63-6.57 (m, 2H), 5.91 (dd, J=7.9, 1.5 Hz, 2H).
¹³C-NMR (125 MHz, CDCl₃): δ=143.9, 138.1, 134.4, 134.0, 132.7, 123.3, 122.4, 121.6, 115.6.
APCI-MSm/z: 337 M⁺, 339 M⁺
Anal. Calcd for C₁₈H₁₂BrNO: C, 63.93; H, 3.58; N, 4.14.

Found: C, 63.96; H, 3.63; N, 4.12.

Next, a compound 2 was synthesized according to the following reaction.

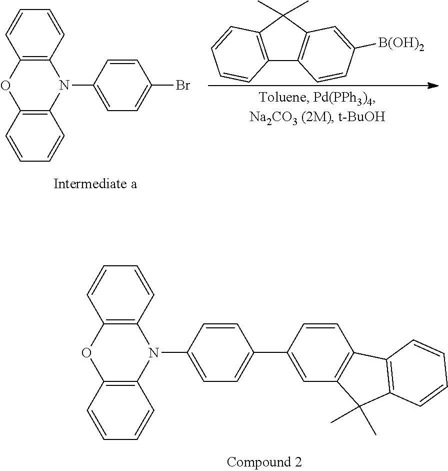

The intermediate a (4-phenoxazine-bromobenzene) (2.03 g, 6 mmol), 9,9-dimethyl-2-fluoreneboronic acid (2.11 g, 6.6 mmol), tetrakis(triphenylphosphine)palladium(0) (350 mg, 0.3 mmol), toluene (120 mL), t-butanol (30 mL) and an aqueous sodium carbonate solution (2 M, 50 mL) were put into a container, and the container was degassed under reduced pressure and purged with nitrogen. The container was put into an oil bath, and the mixture in the container was heated at 100° C. for 24 hours. After the heating, the reaction liquid was cooled to room temperature, whereupon it was separated into two layers of an aqueous layer and an organic layer. Among these, the aqueous layer was collected, and extracted three times with ethyl acetate (60 mL). The resultant organic layer was washed two times with saturated saline water (60 mL), then dried with sodium sulfate added thereto, and filtered. The solvent was removed from the resultant filtrate, and the remaining residue was purified through silica gel column chromatography using a mixed solvent of dichloromethane/hexane (1/4) as an eluent. The resultant fraction was concentrated to give a white solid of the intended compound 2 at a production quantity of 1.85 g and a yield of 68%.
¹-NMR (500 MHz, CDCl₃): δ=7.88 (d, J=7.6 Hz, 2H), 7.83 (d, J=7.8 Hz, 1H), 7.80-7.76 (m, 1H), 7.71 (d, J=1.3 Hz, 1H), 7.64 (dd, J=7.8, 1.7 Hz, 1H), 7.49-7.46 (m, 1H), 7.43 (d, J=8.0 Hz, 2H), 7.39-7.33 (m, 2H), 6.81-6.55 (m, 6H), 6.03 (s, 2H), 1.57 (s, 6H).
¹³C-NMR (125 MHz, CDCl₃): δ=154.4, 153.9, 144.0, 141.8, 139.2, 139.0, 138.7, 137.9, 134.4, 131.1, 129.7, 127.5, 127.1, 126.2, 123.3, 122.7, 121.4, 121.3, 120.4, 120.2, 115.4, 113.3, 47.0, 27.2.
APCI-MSm/z: 451 M⁺
Anal. Calcd for C₃₃H₂₅NO: C, 87.77; H, 5.58; N, 3.10.

Found: C, 87.82; H, 5.58; N, 3.12.

### Synthesis Example 3

### Synthesis of Compound 3

First, an intermediate b was synthesized according to the following reaction.

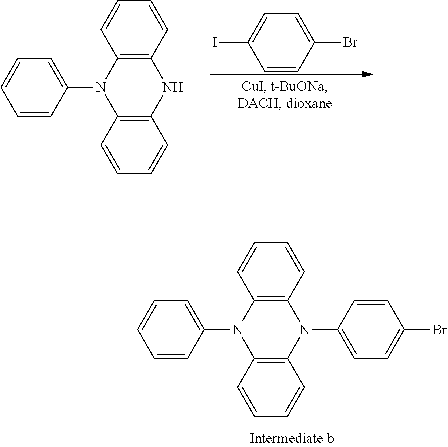 [SMILES: c1ccc(N2c3ccccc3Nc3ccccc32)cc1 ; Brc1ccc(I)cc1 ; Brc1ccc(N2c3ccccc3N(c3ccccc3)c3ccccc32)cc1]

5-Phenyl-5,10-dihydrophenazine (20 mmol, 30 mL as a toluene solution), 4-iodo-bromobenzene (5.66 g, 20 mmol), copper iodide (110 mg, 0.6 mmol), sodium tert-butoxide (2.95 g, 30 mmol), 1,2-diaminocyclohexane (0.20 mL) and 1,4-dioxane (50 mL) were put into a container, then the container was purged with nitrogen, and the mixture in the container was stirred at 100° C. for 24 hours. After the stirring, the reaction liquid was cooled to room temperature and water (50 mL) was added thereto, whereupon the liquid was separated into two layers of an aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane=1:10 as an eluent. The resultant fraction was concentrated to give a yellow solid of the intermediate b at a production quantity of 1.65 g and a yield of 20%.
¹H-NMR (500 MHz, Pyridine-D₅) δ=7.79 (d, J=8.6 Hz, 2H), 7.63 (t, J=7.8 Hz, 2H), 7.51-7.45 (m, 1H), 7.42 (dd, J=8.3, 1.1 Hz, 2H), 7.27 (d, J=8.6 Hz, 2H), 6.47-6.40 (m, 4H), 5.83 (dd, J=7.6, 1.6 Hz, 2H), 5.78 (dd, J=7.6, 1.6 Hz, 2H).
¹³C-NMR (126 MHz, Pyridine-D₅) δ=137.4, 137.0, 135.4, 134.0, 132.2, 131.8, 129.0, 122.1, 121.9, 113.6, 113.5.
APCI-MSm/z: 412M⁺, 414M⁺
Anal. Calcd for C₂₄H₁₇BrN₂: C, 69.74; H, 4.15; N, 6.78

Found: C, 69.94; H, 4.21; N, 6.72.

Next, a compound 3 was synthesized according to the following reaction.

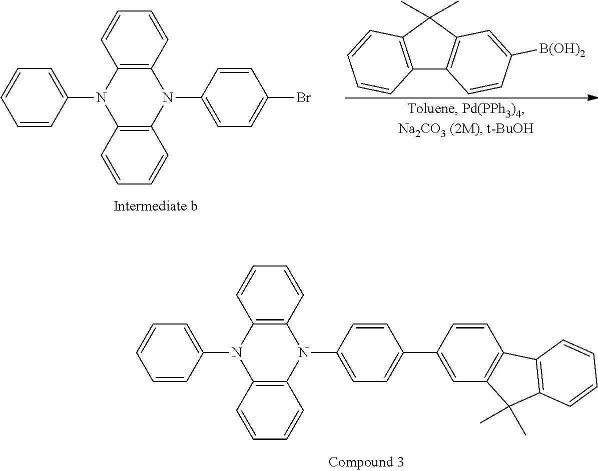 [SMILES: Brc1ccc(N2c3ccccc3N(c3ccccc3)c3ccccc32)cc1 ; CC1(C)c2ccccc2-c2ccc(B(O)O)cc21 ; CC1(C)c2ccccc2-c2ccc(-c3ccc(N4c5ccccc5N(c5ccccc5)c5ccccc54)cc3)cc21]

The intermediate b [4-(5-phenyl-5,10-dihydrophenazine)bromobenzene] (1.65 g, 4 mmol), 9,9-dimethyl-2-fluoreneboronic acid (1.14 g, 4.8 mmol), tetrakis(triphenylphosphine)palladium(0) (230 mg, 0.2 mmol), toluene (80 mL), t-butanol (15 mL) and an aqueous sodium carbonate solution (2 M, 30 mL) were put into a container, and the container was degassed under reduced pressure and purged with nitrogen. The container was put into an oil bath, and the mixture in the container was heated at 100° C. for 24 hours. After the heating, the reaction liquid was cooled to room temperature, whereupon it was separated into two layers of an aqueous layer and an organic layer. Among these, the aqueous layer was collected, and extracted three times with ethyl acetate (50 mL). The resultant organic layer was washed two times with saturated saline water (50 mL), then dried with sodium sulfate added thereto, and filtered. The solvent was removed from the resultant filtrate, and the remaining residue was purified through silica gel column chromatography using a mixed solvent of dichloromethane/hexane (1/4) as an eluent. The resultant fraction was concentrated to give a yellow solid of the intended compound 3 at a production quantity of 0.82 g and a yield of 39%.
¹H-NMR (500 MHz, Pyridine-D5): δ=8.05 (dd, J=10.9, 4.3 Hz, 4H), 7.98-7.94 (m, 1H), 7.88 (dd, j=7.8, 1.7 Hz, 1H), 7.65 (t, J=7.8 Hz, 2H), 7.60-7.57 (m, 1H), 7.56-7.52 (m, 2H), 7.52-7.41 (m, 5H), 6.49-6.42 (m, 4H), 5.98 (dd, J=7.6, 1.6 Hz, 2H), 5.87 (dd, J=7.6, 1.6 Hz, 2H), 1.63 (s, 6H).
¹³C-NMR (125 MHz, Pyridine-D5) δ=155.4, 154.8, 142.0, 141.1, 140.1, 140.0, 139.8, 139.5, 137.5, 137.5, 132.3, 132.2, 131.9, 130.8, 129.0, 128.5, 128.1, 127.1, 122.4, 121.9, 121.5, 121.1, 113.6, 113.6, 47.7, 27.6.
APCI-MSm/z: 526 M⁺
Anal. Calcd for C₃₉H₃₀N₂: C, 88.94; H, 5.74; N, 5.32

Found: C, 89.19; H, 5.74; N, 5.31

### Synthesis Example 4

### Synthesis of Compound 4

A compound 4 was synthesized according to the following reaction.

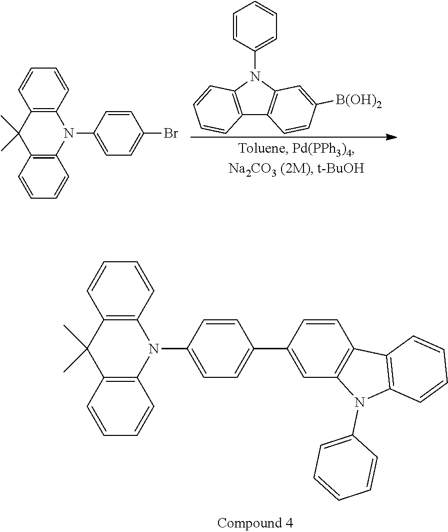

4-(9,9-dimethyl-9,10-dihydroacridine)bromobenzene (1.1 g, 3 mmol), 9-phenylcarbazole-3-boronic acid (1 g, 3.6 mmol), tetrakis(triphenylphosphine)palladium(0) (170 mg, 0.15 mmol), toluene (60 mL), t-butanol (15 mL) and an aqueous sodium carbonate solution (2 M, 20 mL) were put into a container, and the container was degassed under reduced pressure and purged with nitrogen. The container was put into an oil bath, and the mixture in the container was heated at 100° C. for 24 hours. After the heating, the reaction liquid was-cooled to room temperature, whereupon it was separated into two layers of an aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane (1/4) as an eluent. The resultant fraction was concentrated to give a white solid of the intended compound 4 at a production quantity of 1.15 g and a yield of 72%.
¹H-NMR (500 MHz, CDCl₃): δ=8.47 (d, J=1.5 Hz, 1H), 8.23 (d, J=7.7 Hz, 1H), 7.97 (d, J=8.4 Hz, 2H), 7.76 (dd, J=8.5, 1.8 Hz, 1H), 7.69-7.59 (m, 4H), 7.54-7.50 (m, 2H), 7.50-7.47 (m, 2H), 7.46-7.43 (m, 4H), 7.36-7.31 (m, 1H), 7.02 (ddd, J=8.4, 7.2, 1.6 Hz, 2H), 6.95 (td, J=7.6, 1.2 Hz, 2H), 6.43 (dd, J=1.1 Hz, 2H), 1.73 (s, 6H).
¹³C-NMR (125 MHz, CDCl₃): δ=141.9, 141.4, 141.0, 140.6, 139.6, 137.6, 132.5, 131.6, 130.00, 129.9, 129.6, 127.6, 127.1, 126.4, 126.3, 125.4, 125.2, 124.0, 12.3.4, 120.5, 120.4, 120.2, 118.9, 114.1, 110.2, 110.0, 36.0, 31.3.
APCI-MSm/z: 526 M⁺
Anal. Calcd for C₃₉H₃₀N₂: C, 88.94; H, 5.74; N, 5.32

Found: C, 88.97; H, 5.72; N, 5.37.

### Synthesis Example 5

### Synthesis of Compound 5

A compound 5 was synthesized according to the following reaction.

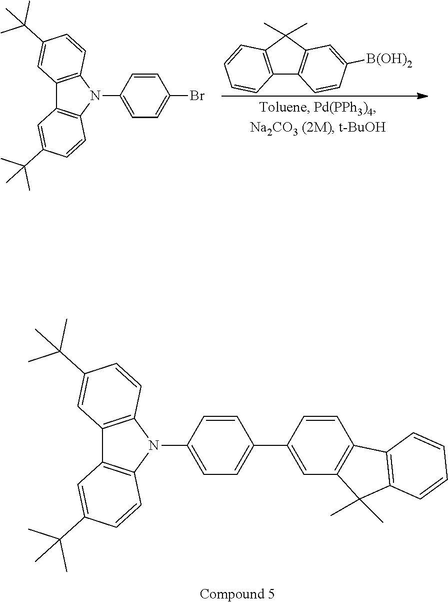 [SMILES: CC(C)(C)c1ccc2c(c1)c1cc(C(C)(C)C)ccc1n2-c1ccc(Br)cc1 ; CC1(C)c2ccccc2-c2ccc(B(O)O)cc21 ; CC(C)(C)c1ccc2c(c1)c1cc(C(C)(C)C)ccc1n2-c1ccc(-c2ccc3c(c2)C(C)(C)c2ccccc2-3)cc1]

4-(3,6-di-tert-butylcarbazole)bromobenzene (870 mg, 2 mmol), 9,9-dimethyl-2-fluoreneboronic acid (570 mg, 2.4 mmol), tetrakis(triphenylphosphine)palladium(0) (116 mg, 0.1 mmol), toluene (60 mL), t-butanol (15 mL) and an aqueous sodium carbonate solution (2 M, 20 mL) were put into a container, and the container was degassed under reduced pressure and purged with nitrogen. The container was put into an oil bath, and the mixture in the container was heated at 100° C. for 24 hours. After the heating, the reaction liquid was cooled to room temperature, whereupon it was separated into two layers of an aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane (1/5) as an eluent. The resultant fraction was concentrated to give a white solid of the intended compound 5 at a production quantity of 790 mg and a yield of 72%.
¹H-NMR (500 MHz, CDCl₃): δ=8.16 (d, J=1.8 Hz, 2H), 7.89-7.86 (m, 2H), 7.84 (d, J=7.7 Hz, 1H), 7.80-7.77 (m, 1H), 7.75 (d, J=1.3 Hz, 1H), 7.68 (dd, J=7.8, 1.7 Hz, 1H), 7.67-7.63 (m, 2H), 7.49 (ddd, J=7.3, 4.2, 1.9 Hz, 3H), 7.45-7.41 (m, 2H), 7.40-7.32 (m, 2H), 1.58 (s, 6H), 1.48 (s, 18H).
¹³C-NMR (125 MHz, CDCl₃): δ=154.4, 153.9, 142.9, 140.2, 139.5, 139.2, 138.78, 138.76, 137.2, 128.4, 127.6, 127.4, 127.09, 127.05, 127.0, 126.2, 123.6, 123.4, 122.7, 122.6, 121.4, 121.3, 120.4, 120.1, 120.0, 116.3, 109.3, 47.0, 34.8, 32.0, 27.3.
APCI-MSm/z: 547 M⁺
Anal. Calcd for C₄₁H₄₁N: C, 89.90; H, 7.54; N, 2.56

Found: C, 90.01; H, 7.49; N, 2.52.

### Synthesis Example 6

### Synthesis of Compound 6

A compound 6 was synthesized according to the following process.

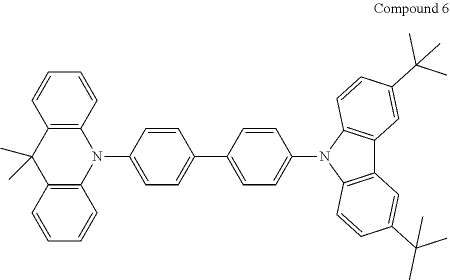 [SMILES: CC(C)(C)c1ccc2c(c1)c1cc(C(C)(C)C)ccc1n2-c1ccc(-c2ccc(N3c4ccccc4C(C)(C)c4ccccc43)cc2)cc1]

4-(9,9-Dimethyl-9,10-dihydroacridine)bromobenzene (728 mg, 2 mmol), 3,6-di-tert-butyl-9-(4-(4,4,5,5-tetramethyl-1,3,2-dioxabororan-2-yl)phenyl)-9H-carbazole (1.15 g, 2.4 mmol), tetrakis(triphenylphosphine)palladium(0) (116 mg, 0.1 mmol), toluene (60 mL), t-butanol (15 mL) and an aqueous sodium carbonate solution (2 M, 20 mL) were put into a container, and the container was degassed under reduced pressure and purged with nitrogen. The container was put into an oil bath, and the mixture in the container was heated at 100° C. for 24 hours. After the heating, the reaction liquid was cooled to room temperature, whereupon it was separated into two layers of an. aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane (1/5) as an eluent. The resultant fraction was concentrated to give a white solid of the intended compound 6 at a production quantity of 0.79 g and a yield of 62%.

3,6-Di-tert-butyl-9-(4-(4,4,5,5-tetramethyl -1,3,2-dioxabororan-2-yl)phenyl)-9H-carbazole was synthesized according to the method described in Lai, W.-Y.; He, Q.-Y.; Chen, D.-Y.; Huang, W. Chem. Lett. 2008, 37, 986.
¹H-NMR (500 MHz, CDCl₃): δ=8.17 (d, J=1.6 Hz, 2H), 7.95 (d, J=8.4 Hz, 2H), 7.91 (d, J=8.5 Hz, 2H), 7.70 (d, J=8.5 Hz, 2H), 7.53-7.42 (m, 8H), 7.04-6.99 (m, 2H), 6.95 (td, J=7.5, 1.3 Hz, 2H), 6.36 (dd, J=8.2, 1.2 Hz, 2H), 1.72 (s, 6H), 1.49(s, 18H).
¹³C-NMR (125 MHz, CDCl₃): δ=143.0, 141.0, 140.7, 140.2, 139.2, 138.7, 137.8, 131.8, 130.1, 129.5, 128.5, 127.0, 126.4, 125.3, 123.7, 123.5, 120.6, 116.3, 114.1, 109.2, 36.0, 34.8, 32.0, 31.3.
APCI-MSm/z: 638 M⁺
Anal. Calcd for C₄₇H₄₆N₂: C, 88.36; H, 7.26; N, 4.38

Found: C, 88.42; H, 7.23; N, 4.39

### Synthesis Example 7

### Synthesis of Compound 7

A compound 7 was synthesized according to the following process.

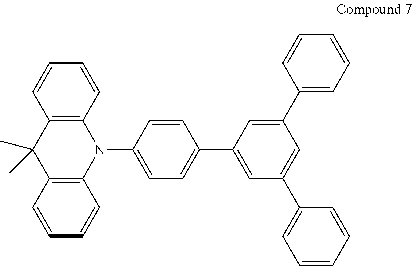

4-(9,9-Dimethyl-9,10-dihydroacridine)bromobenzene (1.1 g, 3 mmol), 3,5-biphenylbenzeneboronic acid (987 mg, 3.6 mmol), tetrakis(triphenylphosphine)palladium(0) (170 mg, 0.15 mmol), toluene (60 mL), t-butanol (15 mL) and an aqueous sodium carbonate solution (2 M, 20 mL) were put into a container, and the container was degassed under reduced pressure and purged with nitrogen. The container was put into an oil bath, and the mixture in the container was heated at 100° C. for 24 hours. After the heating, the reaction liquid was cooled to room temperature, whereupon it was separated into two layers of an aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane (1/5) as an eluent. The resultant fraction was concentrated to give a white solid of the intended compound 7 at a production quantity of 1.1 g and a yield of 70%.
¹H-NMR (500 MHz, CDCl₃): δ=7.99-7.93 (m, 2H), 7.90 (d, J=1.7 Hz, 2H), 7.86 (t, J=1.6 Hz, 1H), 7.78-7.73 (m, 4H), 7.55-7.37 (m, 10H), 7.04-6.98 (m, 2H), 6.95 (td, J=7.5, 1.3 Hz, 2H), 6.39 (dd, J=8.2, 1.2 Hz, 2H), 1.72 (s, 6H).
¹³C-NMR (125 MHz, CDCl₃): δ=142.5, 141.4, 141.0, 141.1, 141.0, 140.6, 131.7, 130.0, 129.7, 128.9, 127.7,127.4, 126.4, 125.5, 125.3, 125.2, 120.6, 114.1, 36.0, 31.3.
APCI-MSm/z: 513 M⁺
Anal. Calcd for C₃₉H₃₁N: C, 91.19; H, 6.08; N, 2.73

Found: C, 91.23; H, 6.00; N, 2.63.

### Synthesis Example 8

### Synthesis of Compound 8

A compound 8 was synthesized according to the following process.

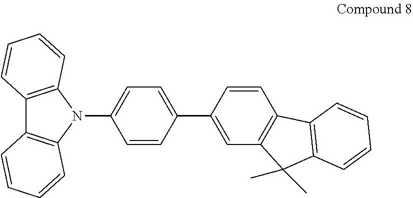 [SMILES: CC1(C)c2ccccc2-c2ccc(-c3ccc(-n4c5ccccc5c5ccccc54)cc3)cc21]

4-(Carbazol-9-yl)bromobenzene (967 mg, 3 mmol), 9,9-dimethyl-2-fluoreneboronic acid (786 mg, 3.3 mmol), tetrakis(triphenylphosphine)palladium(0) (170 mg, 0.15 mmol), potassium carbonate (6.91 g), tetrahydrofuran (100 mL) and water (50 mL) were put into a container, and the container was degassed under reduced pressure and purged with nitrogen. The container was put into an oil bath, and the mixture in the container was heated at 80° C. for 24 hours. After the heating, the reaction liquid was cooled to room temperature, whereupon it was separated into two layers of an aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane (1/3) as an eluent. The resultant fraction was concentrated to give a white solid of the intended compound 8 at a production quantity of 941 mg and a yield of 72%.
¹H-NMR (500 MHz, CDCl₃): δ=8.18 (d, J=7.8 Hz, 2H), 7.93-7.87 (m, 2H), 7.85 (d, J=7.8 Hz, 1H), 7.79 (d, J=6.9 Hz, 1H), 7.75 (s, 1H), 7.68 (dd, J=11.6, 5.0 Hz, 3H), 7.50 (t, J=7.6 Hz, 3H), 7.44 (t, J=7.6 Hz, 2H), 7.41-7.34 (m, 2H) 7.32 (t, J=7.4 Hz, 2H), 1.59 (s, 6H).
¹³C-NMR (125 MHz, CDCl₃): δ=140.9, 140.8, 140.7, 140.1, 139.3, 137.3, 131.9, 130.1, 129.5, 128.6, 128.5, 127.5, 127.4, 126.4, 126.0, 125.3, 123.5, 120.6, 120.4, 120.1, 114.1, 109.8, 36.0, 31.3.
APCI-MSm/z: 435 M⁺
Anal. Calcd for C₃₃H₂₅N: C, 91.00; H, 5.79; N, 3.22

Found: C, 91.09; H, 5.77; N, 3.24.

### Synthesis Example 9

### Synthesis of Compound 9

First, an intermediate c was synthesized according to the following process.

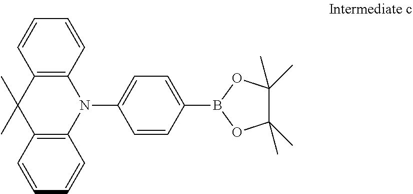

4-(9,9-Dimethyl-9,10-dihydroacridine)bromobenzene (1.46 g, 4 mmol), bis(pinacolato)diborane (1.52 g, 6 mmol), [1,1′-bis(diphenylphosphino)ferrocene]dichloropalladium(II) (90 mg, 0.12 mmol), potassium acetate (1.18 g) and 1,4-dioxane (50 mL) were put into a container, and the container was degassed under reduced pressure and purged with nitrogen. The container was put into an oil bath, and the mixture in the container was heated at 80° C. for 24 hours. After the heating, the reaction liquid was cooled to room temperature and water (50 mL) was added thereto, whereupon the liquid was separated into two layers of an aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane (1/1) as an eluent. The resultant fraction was concentrated to give a white solid of the intermediate c at a production quantity of 1.56 g and a yield of 95%.
¹H-NMR (500 MHz, CDCl₃): δ=8.06 (d, 8.2 Hz, 2H), 7.45 (dd, J=7.5, 1.8 Hz, 2H), 7.34 (d, J=8.2 Hz, 2H), 6.98-6.87 (m, 4H), 6.25 (dd, J=7.9, 1.5 Hz, 2H), 1.69 (s, 6H), 1.40 (s, 12H).
¹³C-NMR (125 MHz, CDCl₃): δ=144.1, 140.9, 137.5, 130.8, 130.1, 126.5, 125.4, 120.7, 114.2, 84.3, 83.7, 36.1, 31.5, 25.2, 25.1
APCI-MSm/z: 411 M⁺

Next, a compound 9 was synthesized according to the following process.

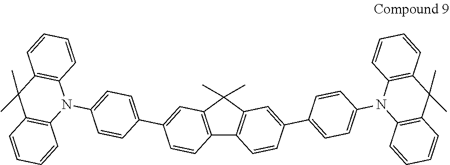

9,9-Dimethyl-10-(4-(4,4,5,5-tetramethyl-1,3,2-dioxabororan-2-yl)phenyl)-9,10-dihydroacridine (2.05 g, 5 mmol), di-2,7-bromo-9,9-dimethylfluorene (704 mg, 2 mmol), tetrakis(triphenylphosphine)palladium(0) (232 mg, 0.2 mmol), potassium carbonate (6.91 g), tetrahydrofuran (150 mL) and water (70 mL) were put into a container, and the container was degassed under reduced pressure and purged with. nitrogen. The container was put into an oil bath, and the mixture in the container was heated at 80° C. for 24 hours. After the heating, the reaction liquid was cooled to room temperature, and the precipitated deposit was collected through filtration. The resultant crude product was purified according to a sublimation method to give a white solid of the intended compound 9 at a production quantity of 852 mg and a yield of 56%.
¹H-NMR (500 MHz, CDCl₃): δ=7.97-7.91 (m, 4H), 7.90 (d, J=7.8 Hz, 2H), 7.80 (d, J=1.3 Hz, 2H), 7.73 (dd, J=7.8, 1.6 Hz, 2H), 7.48 (dd, J=7.7, 1.5 Hz, 4H), 7.44 (d, J=8.3 Hz, 4H), 7.04-6.97 (m, 4H), 6.95 (td, J=7.5, 1.2 Hz, 4H), 6.40 (dd, J=8.2, 1.1 Hz, 4H), 1.72 (s, 12H), 1.67 (s, 6H).
¹³C-NMR (125 MHz, CDCl₃): δ=154.9, 141.53, 141.1, 140.4, 139.7, 138.6, 131.8, 130.2, 129.7, 126.6, 126.5, 125.4, 121.7, 120.8, 120.7, 114.3, 47.4, 36.2, 31.5, 27.5.
APCI-MSm/z: 760 M⁺
Anal. Calcd for C₅₇H₄₈N₂: C, 89.96; H, 6.36; N, 3.68

Found: C, 89.87; H, 6.33; N, 3.73.

The starting substance 4-(9,9-dimethyl-9,10-dihydroacridine)bromobenzene was synthesized according to the method described in J. Am. Chem. Soc. 2014, 136, 18070-18081, 4-(3,6-di-tert-butylcarbazole)bromobenzene was synthesized according to the method described in W. Chem. Lett. 2008, 37, 986, and 5-phenyl-5,10-dihydrophenazine was synthesized according to the method described in J. Org. Chem. 70, 10073-10081 (2005).

### Synthesis Example 10

### Synthesis of Compound 12

Next, a compound 12 was synthesized according to the following process.

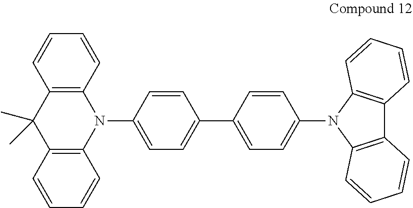 [SMILES: CC1(C)c2ccccc2N(c2ccc(-c3ccc(-n4c5ccccc5c5ccccc54)cc3)cc2)c2ccccc21]

4-(9,9-Dimethyl-9,10-dihydroacridine)bromobenzene (1.1 g, 3 mmol), 4-(carbazol-9-yl)benzeneboronic acid (1.03 g, 3.6 mmol), tetrakis(triphenylphosphine)palladium(0) (170 mg, 0.15 mmol), toluene (60 mL), t-butanol (15 mL) and an aqueous sodium carbonate solution (2 M, 20 mL) were put into a container, and the container was degassed under reduced pressure and purged with nitrogen. The container was put into an oil bath, and the mixture in the container was heated at 100° C. for 24 hours. After the heating, the reaction liquid was cooled to room temperature, whereupon the liquid was separated into two layers of an aqueous layer and an organic layer. Among these, the aqueous layer was collected, and extracted three times with ethyl acetate (30 mL). The resultant organic layer was washed two times with saturated saline water (30 mL), then dried with sodium sulfate added thereto, and filtered. The solvent was removed from the resultant filtrate, and the remaining residue was purified through silica gel column chromatography using a mixed solvent of dichloromethane/hexane (1/3) as an eluent. The resultant fraction was concentrated to give a white solid of the intended compound 12 at a production quantity of 1.03 g and a yield of 65%.
¹H-NMR (500 MHz, CDCl₃): δ=8.19 (d, J=7.8 Hz, 2H), 7.99-7.89 (m, 4H), 7.74-7.69 (m, 2H), 7.53-7.44 (m, 8H), 7.37-7.28 (m, 2H), 7.09-7.00 (m, 2H), 6.96 (td, J=7.5, 1.3 Hz, 2H), 6.40 (dd, J=8.2, 1.2 Hz, 2H), 1.73 (s, 6H).
¹³C-NMR (125 MHz, CDCl₃): δ 154.6, 154.1, 1411, 140.9, 139.5, 139.0, 138.9, 136.9, 128.7, 127.6, 127.5, 127.3, 126.3, 126.1, 123.6, 122.8, 121.6, 120.6, 120.5, 120.3, 120.1, 110.0, 47.2, 27.4.
APCI-MSm/z: 526 M⁺
Anal. Calcd for C₃₉H₃₀N₂: C, 88.94; H, 5.74; N, 5.32

Found: C, 89.01; H, 5.68; N, 5.39

Compounds 10 and 11 were synthesized according to the above-mentioned Synthesis Examples.

### Examples 1 to 11

### Production and Evaluation of Solutions Using Compounds 1 to 11

A toluene solution (concentration 10⁻⁵ mol/L) of any of the compounds 1 to 11 was prepared and purged with nitrogen gas.

Thus prepared, each compound solution was measured for the absorption spectrum and the emission spectrum with 340 nm excitation light. Table 1 shows the maximum absorption wavelength of the absorption spectrum of each solution and the minimum emission wavelength of the emission spectrum thereof. In addition, Table 1 also show the HOMO level and the LUMO level.

TABLE 1

| | | Maximum | | | |
|---|---|---|---|---|---|
| | | Absorp- | Minimum | | |
| | | tion | Emission | | |
| | | Wave- | Wave- | HOMO | LUMO |
| | | length | length | Level | Level |
| Example No. | Compound No. | (nm) | (nm) | (eV) | (eV) |
| Example 1 | Compound 1 | 292 | 412 | −5.3 | −2.0 |
| Example 2 | Compound 2 | 313 | 448 | −5.0 | −2.0 |
| Example 3 | Compound 3 | 372 | 522 | −4.6 | −1.9 |
| Example 4 | Compound 4 | 340 | 397 | −5.3 | −1.8 |
| Example 5 | Compound 5 | 319 | 360 | −5.6 | −2.2 |
| Example 6 | Compound 6 | 334 | 399 | −5.3 | −1.9 |
| Example 7 | Compound 7 | 258^{b} | 411 | −5.3 | −1.9 |
| Example 8 | Compound 8 | 321 | 367 | −5.7 | −2.3 |
| Example 9 | Compound 9 | 326 | 397 | −5.1 | −1.8 |
| Example 10 | Compound 10 | 342 | 386 | −5.6 | −2.2 |
| Example 11 | Compound 11 | 329 | 457 | −5.0 | −2.0 |

As shown in Table 1, all the solutions of the compounds 1 to 11 provided detectable light emission.

### Example 12

### Production and Evaluation of Solid Organic Thin Film Using Compound 2

According to a vacuum vapor deposition method, a thin film of the compound 2 was formed to have a thickness of 250 nm on a quartz substrate under a vacuum degree of 2×10⁻⁴ Pa to be a solid organic thin film.

Table 3 shows the maximum emission wavelength and the photoluminescence quantum efficiency of the formed thin film of the compound 2.

### Example 13

### Production and Evaluation of Solid Organic Thin Film Using Compound 11

According to a vacuum vapor deposition method, a thin film of the compound 11 was formed to have a thickness of 200 nm on a quartz substrate under a vacuum degree of 2×10⁻⁴ Pa to be a solid organic thin film.

Apart from this, the compound 11, and PPT or DPEPO were co-deposited on a quartz substrate according to a vacuum vapor deposition method from different evaporation sources under a vacuum degree of 2×10⁻⁴ Pa thereby forming a thin film having a thickness of 200 nm and having a concentration of the compound 11 of 8% by weight to be a solid organic thin film.

Thus formed, each thin film was measured for the maximum emission wavelength and the photoluminescence quantum yield (PL quantum yield), and the results are shown in Table 2.

TABLE 2

| | | Maximum | |
|---|---|---|---|
| | | Emission | PL Quantum |
| | | Wavelength | Yield PLQY |
| Example No. | Composition of Thin Film | (nm) | (%) |
| Example 12 | Compound 2 = 100% by weight | 442 | 12.1 |
| Example 13 | Compound 11 = 100% by weight | 466 | 19.1 |
| | Compound 11/PPT = 8% by weight/92% by weight | 459 | 20.1 |
| | Compound 11/DPEPO = 8% by weight/92% by weight | 459 | 21.4 |

### Example 14

### Production and Evaluation of Organic Electroluminescent Device Using Compound 2

On a glass substrate with an anode of indium tin oxide (ITO) having a thickness of 100 nm formed thereon, thin films were layered according to a vacuum vapor deposition method under a vacuum degree of 2×10⁻⁴ Pa. First, on ITO, α-NPD was formed in a thickness of 40 nm, and mCP was formed thereon in a thickness of 10 nm. Next, the compound 2 was vapor-deposited in a thickness of 25 nm to form a light-emitting layer, and TPBi was formed thereon in a thickness of 40 nm. Further, lithium fluoride (LiF) was formed in a thickness of 1 nm, and then aluminum (Al) was vapor-deposited thereon in a thickness of 100 nm to form a cathode, thereby producing an organic electroluminescent device. Apart from this and according to the same process as above, three organic electroluminescent devices having the same layer configuration were produced, and thus, four organic electroluminescent devices were produced in total. The organic electroluminescent devices are referred to as devices 14-1 to 14-4.

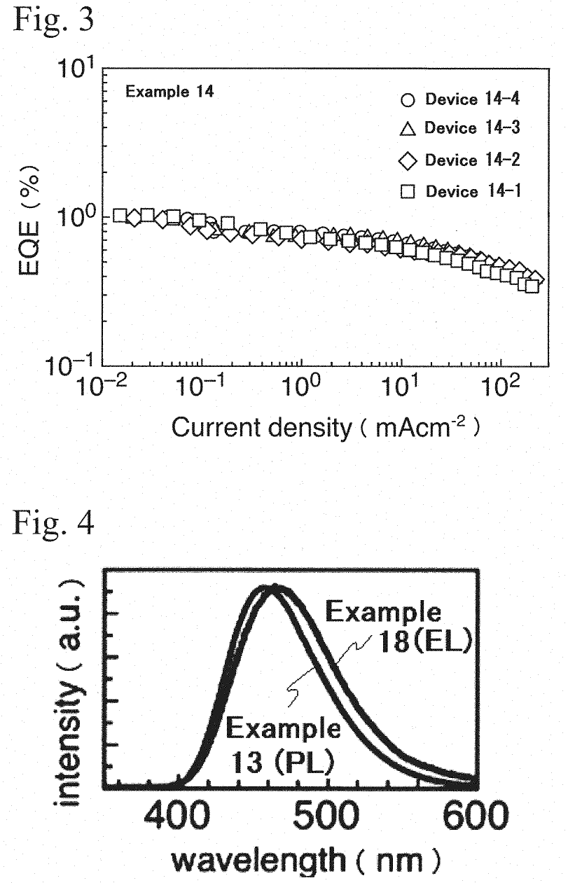

FIG. 2 shows an emission spectrum (EL) of the produced device 14-2; and FIG. 3 shows a current density-external quantum efficiency characteristic of the devices 14-1 to 14-4. As a typical case, the device characteristics of the device 14-2 are shown in Table 3. In FIG. 2, an emission spectrum (PL) of the solid organic thin film produced in Example 12 is also shown for reference.

### Example 15

### Production and Evaluation of Organic Electroluminescent Device Using Compound 11 [1]

On a glass substrate with an anode of indium tin oxide (ITO) having a thickness of 100 nm formed thereon, thin films were layered according to a vacuum vapor deposition method under a vacuum degree of 2×10⁻⁴ Pa. First, on ITO, TAPC was formed in a thickness of 40 nm. Next, the compound 11 was vapor-deposited in a thickness of 20 nm to form a light-emitting layer. Subsequently, DPEPO was formed in a thickness of 10 nm, and TPBi was thrilled thereon in a thickness of 40 nm. Further, lithium fluoride (LiF) was formed in a thickness of 1 nm, and then aluminum (Al) was vapor-deposited thereon in a thickness of 100 nm to form a cathode, thereby producing an organic electroluminescent device.

The device characteristics of the produced organic electroluminescent device are shown in Table 3.

### Example 16

### Production and Evaluation of Organic Electroluminescent Device Using Compound 11 [2]

On a glass substrate with an anode of indium tin oxide (ITO) having a thickness of 100 nm formed thereon, thin films were layered according to a vacuum vapor deposition method under a vacuum degree of 2×10⁻⁴ Pa. First, on ITO, TAPC was formed in a thickness of 40 nm. Next, the compound 11 and PPT were co-deposited from different evaporation sources to form a layer having a thickness of 20 nm. The layer is a light-emitting layer. At this time, the concentration of the compound 11 was 8% by weight. Subsequently, PPT was formed in a thickness of 10 nm, and TPBi was formed thereon in a thickness of 40 nm. Further, lithium fluoride (LiF) was formed in a thickness of 1 nm, and then aluminum (Al) was vapor-deposited thereon in a thickness of 100 nm to form a cathode, thereby producing an organic electroluminescent device.

The device characteristics of the produced organic electroluminescent device are shown in Table 3.

### Example 17

### Production and Evaluation of Organic Electroluminescent Device Using Compound 11 [3]

On a glass substrate with an anode of indium tin oxide (ITO) having a thickness of 100 nm formed thereon, thin films were layered according to a vacuum vapor deposition method under a vacuum degree of 2×10⁻⁴ Pa. First, on ITO, TAPC was formed in a thickness of 40 nm. Next, the compound 11 and DPEPO were co-deposited from different evaporation sources to form a layer having a thickness of 20 nm. The layer is a light-emitting layer. At this time, the concentration of the compound 11 was 8% by weight. Subsequently, DPEPO was formed in a thickness of 10 nm, and TPBi was formed thereon in a thickness of 40 nm. Further, lithium fluoride (LiF) was formed in a thickness of 1 nm, and then aluminum (Al) was vapor-deposited thereon in a thickness of 100 nm to form a cathode, thereby producing an organic electroluminescent device.

The device characteristics of the produced organic electroluminescent device are shown in Table 3.

### Example 18

### Production and Evaluation of Organic Electroluminescent Device Using Compound 11 [4]

On a glass substrate with an anode of indium tin oxide (ITO) having a thickness of 100 nm formed thereon, thin films were layered according to a vacuum vapor deposition method under a vacuum degree of 2×10⁻⁴ Pa. First, on ITO, TAPC was formed in a thickness of 40 nm. Next, the compound 11 and DPEPO were co-deposited from different evaporation sources to form a layer having a thickness of 20 nm. The layer is a light-emitting layer. At this time, the concentration of the compound 11 was 8% by weight. Subsequently, a layer gradationally changing from DPEPO to TPBi was formed in a thickness of 10 nm. Further, TPBi was formed thereon in a thickness of 40 nm, then lithium fluoride (LiF) was formed in a thickness of 1 nm, and aluminum (Al) was vapor-deposited thereon in a thickness of 100 nm to form a cathode, thereby producing an organic electroluminescent device.

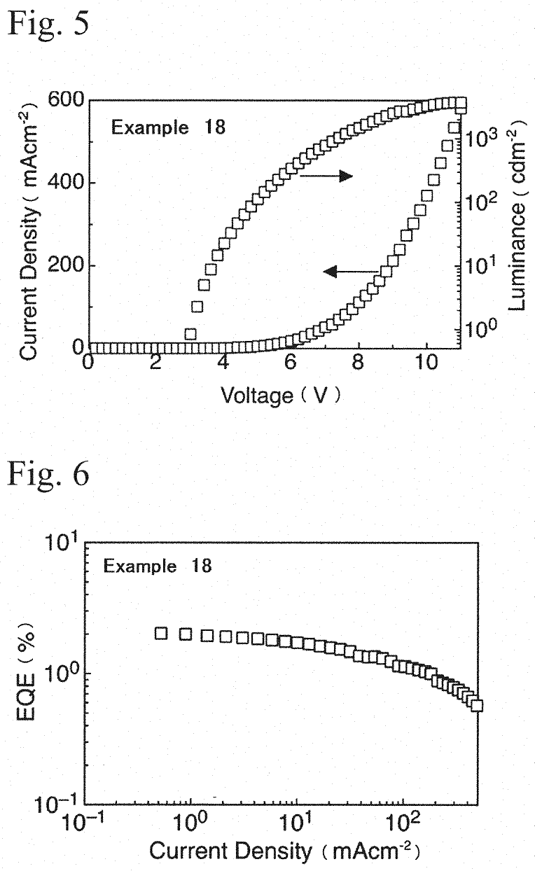

An emission spectrum of the produced organic electroluminescent device is shown in FIG. 4, a voltage-current density-luminance characteristic thereof is in FIG. 5, and the current density-external quantum efficiency characteristic thereof is in FIG. 6. The device characteristics of the produced organic electroluminescent device are shown in Table 3. For reference, FIG. 4 additionally shows an emission spectrum (PL) of the solid organic thin film produced in Example 13 where the composition of the thin film is compound 11/DPEPO=8% by weight/92% by weight.

TABLE 3

| | | Maximum External | Internal Quantum | | |
|---|---|---|---|---|---|
| | | Quantum Efficiency | Yield | On-Voltage | Maximum Emission |
| Example No. | Composition of Light-Emitting Layer | EQEₘₐₓ (%) | X (%) | Vₒₙ (V) | Wavelength (nm) |
| Compound 14 | Compound 2 = 100 wt % | 1.026 | 42.3 | 5.5 | 448 |
| Compound 15 | Compound 11 = 100 wt % | 1.15 | 30.1 | 3.7 | 470 |
| Compound 16 | Compound 11/PPT = 8 wt %/92 wt % | 1.53 | 38.1 | 3.9 | 462 |
| Compound 17 | Compound 11/DPEPO = 8 wt %/92 wt % | 1.65 | 39 | 3.7 | 461 |
| Compound 18 | Compound 11/DPEPO = 8 wt %/92 wt % | 2.03 | 47 | 3.4 | 463 |

The produced organic electroluminescent devices all had good device characteristics. From this, it is confirmed that the compound having a donor group but not having an acceptor group can exhibit a sufficient function as a light-emitting material for organic electroluminescent devices.

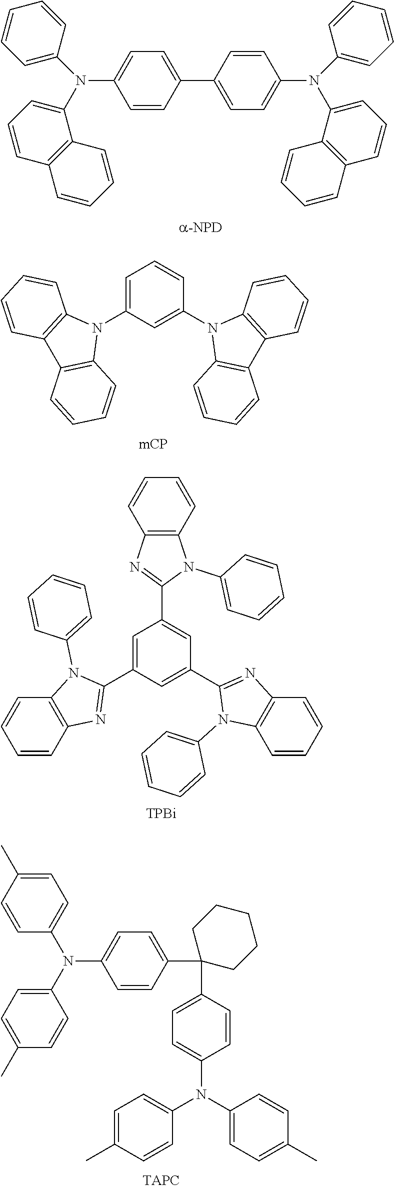

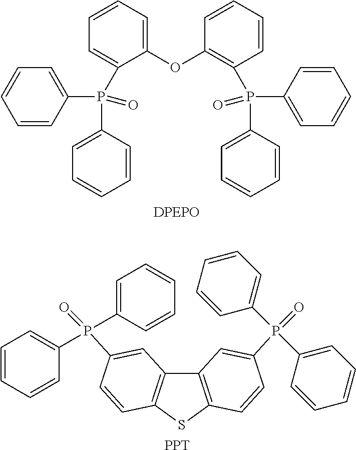

### INDUSTRIAL APPLICABILITY

The compound of the present invention is useful as a light-emitting material. Accordingly, the compound of the present invention can be effectively used as a light-emitting material for organic light-emitting devices such as organic electroluminescent devices, and therefore can provide organic light-emitting devices having a high light emission efficiency since the material to emit delayed fluorescence is included in the compound of the present invention. Consequently, the industrial applicability of the present invention is great.

### REFERENCE SIGNS LIST

1 Substrate
2 Anode
3 Hole injection Layer
4 Hole Transport Layer
5 Light-Emitting Layer
6 Electron Transport Layer
7 Cathode

1. An organic light-emitting device containing a compound having two or more donor groups and one or more linking groups, wherein:
the compound has donor groups differing from each other in point of the structure,
the linking group links at least the two donor groups and is an aromatic group composed of one or more benzene rings optionally substituted with an alkyl group or a halogeno group, and
the compound emits light.

2. (canceled)

3. The organic light-emitting device according to claim 1, wherein the compound has a structure represented by the following general formula (1):
L¹[-D¹{-L²-(D^{2′}-L^{2′})ₙ₁-D²}ₙ₂]ₘ General Formula (1)
wherein L¹, L² and L^{2′} each independently represent an aromatic group composed of one or more benzene rings optionally substituted with an alkyl group or a halogeno group, D¹, D² and D^{2′} each independently represent a donor group, provided that at least two donor groups existing in the molecule of the compound having the structure represented by the general formula (1) each have a different structure, m represents an integer of 2 or more, n1 represents an integer of 0 or more, n2 represents an integer of 0 or more, when m is 2 or more, plural D¹s, L²s, D^{2′}s, L^{2′}s, D²s, n1's and n2's each may be the same or different, when n1 is 2 or more, plural D^{2′}s and L^{2′}s each may be the same or different, when n2 is 2 or more, plural L²s, D^{2′}s, L^{2′}s, D²s and n1's each may be the same or different.

4. The organic light-emitting device according to claim 1, wherein the compound has a structure represented by the following general formula (2):
D^{1′}-L¹-D¹{-L²-D²}_{n2′} General Formula (2)
wherein L¹ and L² each independently represent an aromatic group composed of one or more benzene rings optionally substituted with an alkyl group or a halogeno group, D^{1′}, D¹ and D² each independently represent a donor group, provided that at least two donor groups existing in the molecule of the compound having the structure represented by the general formula (2) each have a different structure, and n2′ represents 0 or 1.

5. (canceled)

6. The organic light-emitting device according to claim 1, wherein the compound has a structure represented by the following general formula (3):
D^{1′}-Ph¹-D¹{-L²-D²}_{n2′} General Formula (3)
wherein Ph¹ represents a phenylene group optionally substituted with an alkyl group or a halogeno group, D^{1′}, D¹ and D² each independently represent a donor group except a substituted or unsubstituted diarylamino group, provided that at least two donor groups existing in the molecule of the compound having the structure represented by the general formula (3) each have a different structure, and n2′ represents 0 or 1.

7. The organic light-emitting device claim 4, wherein D^{1′}, D¹ and D² each independently have an aromatic polycyclic structure.

8-10. (canceled)

11. The organic light-emitting device according to claim 4, wherein D¹ is a group bonding to the linking group via a nitrogen atom, and D^{1′} is a group bonding to the linking group via a carbon atom.

12. The organic light-emitting device according to claim 11, wherein D² is a group bonding to the linking group via a carbon atom.

13. The organic light-emitting device according to claim 4, wherein D¹ is a group bonding to the linking group via a carbon atom, and D^{1′} is a group bonding to the linking group via a nitrogen atom.

14. The organic light-emitting device according to claim 13, wherein D² is a group bonding to the linking group via a nitrogen atom.

15. The organic light-emitting device according to claim 11, wherein the group bonding to the linking group via a carbon atom is a group bonding to the linking group via the carbon atom constituting the ring structure of a benzene ring.

16. The organic light-emitting device according to claim 11, wherein the group bonding to the linking group via a nitrogen atom is a group represented by the following general formula (5): 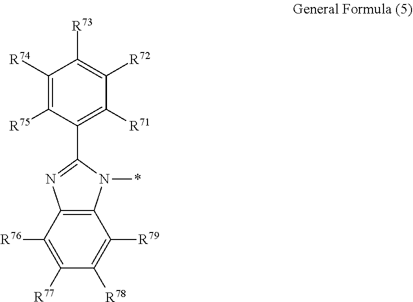
wherein R⁷¹ to R⁷⁹ each independently represent a hydrogen atom or a substituent, R⁷¹ and R⁷², R⁷² and R⁷³, R⁷³ and R⁷⁴, R⁷⁴ and R⁷⁵, R⁷⁶ and R⁷⁷, R⁷⁷ and R⁷⁸, and R⁷⁸ and R⁷⁹ each may bond to each other to form a cyclic structure, * represents a bonding position to the linking group, in the case where the group bonding to the linking group via the nitrogen atom is divalent, the group further bonds at any of R⁷¹ to R⁷⁹.

17. The organic light-emitting device according to claim 11, wherein the group bonding to the linking group via the nitrogen atom is a group represented by any of the following general formulae (6) to (10): 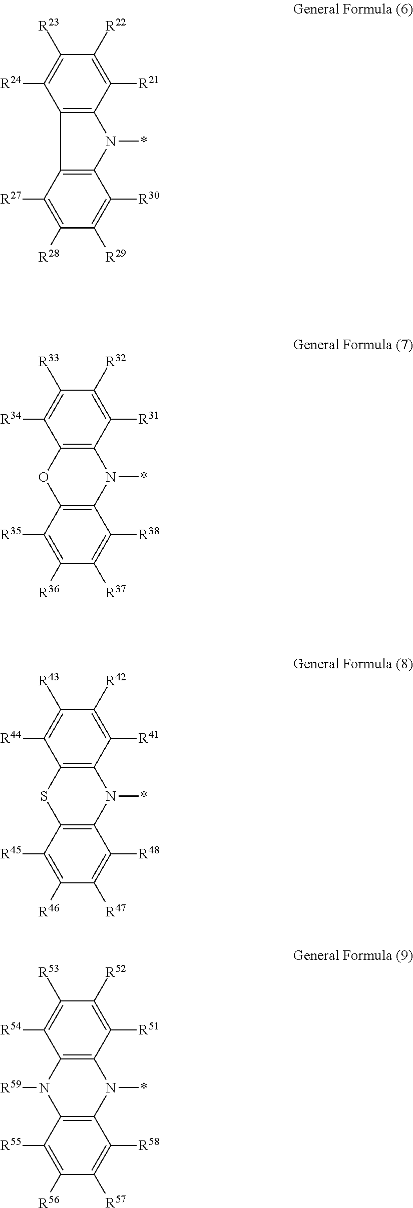 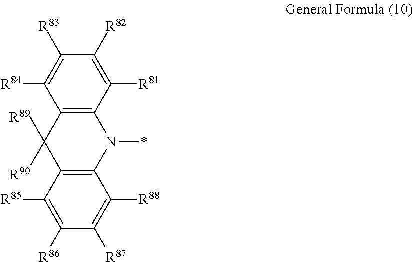
wherein R²¹ to R²⁴, R²⁷ to R³⁸, R⁴¹ to R⁴⁸, R⁵¹ to R⁵⁹, and R⁸¹ to R⁹⁰ each independently represent a hydrogen atom or a substituent, R²¹ and R²², R²² and R²³, R²³ and R²⁴, R²⁷ and R²⁸, R²⁸ and R²⁹, R²⁹ and R³⁰, R³¹ and R³², R³² and R³³, R³³ and R³⁴, R³⁵ and R³⁶, R³⁶ and R³⁷, R³⁷ and R³⁸, R⁴¹ and R⁴², R⁴² and R⁴³, R⁴³ and R⁴⁴, R⁴⁵ and R⁴⁶, R⁴⁶ and R⁴⁷, R⁴⁷ and R⁴⁸, R⁵¹ and R⁵², R⁵² and R⁵³, R⁵³ and R⁵⁴, R⁵⁵ and R⁵⁶, R⁵⁶ and R⁵⁷, R⁵⁷ and R⁵⁸, R⁵⁴ and R⁵⁹, R⁵⁵ and R⁵⁹, R⁸¹ and R⁸², R⁸² and R⁸³, R⁸³ and R⁸⁴, R⁸⁵ and R⁸⁶, R⁸⁶ and R⁸⁷, R⁸⁷ and R⁸⁸, and R⁸⁹ and R⁹⁰ each may bond to each other to form a cyclic structure, * represents a bonding position to the linking group, in the case where the group bonding to the linking group via the nitrogen atom is divalent, the group further bonds at any of R²¹ to R²⁴, R²⁷ to R³⁸, R⁴¹ to R⁴⁸, R⁵¹ to R⁵⁹, and R⁸¹ to R⁹⁰.

18. The organic light-emitting device according to claim 11, wherein the group bonding to the linking group via a carbon atom is a group represented by the following general formulae (11): 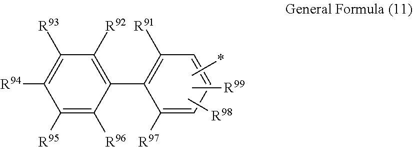
wherein R⁹¹ to R⁹⁹ each independently represent a hydrogen atom or a substituent. R⁹¹ and R⁹², R⁹² and R⁹³, R⁹³ and R⁹⁴, R⁹⁴ and R⁹⁵, R⁹⁵ and R⁹⁶, R⁹⁶ and R⁹⁷, R⁹⁷ and R⁹⁸, R⁹⁸ and R⁹⁹, and R⁹¹ and R⁹⁹ each may bond to each other to form a cyclic structure, * represents a bonding position to the linking group, in the case where the group bonding to the linking group via a carbon atom is divalent, the group further bonds at any of R⁹¹ to R⁹⁹.

19. The organic light-emitting device according to claim 1, wherein the energy difference between HOMO and LUMO of the compound is 2.5 to 3.6 eV.

20. The organic light-emitting device according to claim 1, wherein the energy level of HOMO of the compound is −5.7 eV or more.

21. The organic light-emitting device according to claim 1, wherein the energy level of HOMO of the compound is −5.3 eV or more.

22. The organic light-emitting device according to claim 1, wherein the difference ΔE_{ST} between the lowest excited singlet energy level E_{S1} and the lowest excited triplet energy level E_{T1} of the compound is 0.3 eV or less.

23. The organic light-emitting device according to claim 1, wherein the compound has one of the following structures:

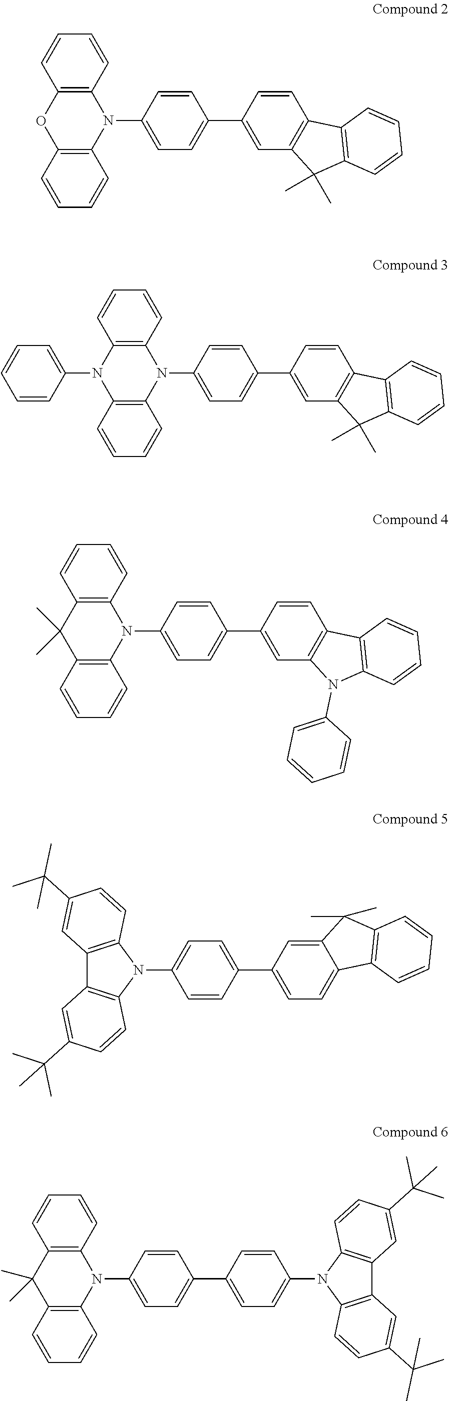 [SMILES: CC1(C)c2ccccc2-c2ccc(-c3ccc(N4c5ccccc5Oc5ccccc54)cc3)cc21 ; CC1(C)c2ccccc2-c2ccc(-c3ccc(N4c5ccccc5N(c5ccccc5)c5ccccc54)cc3)cc21 ; CC1(C)c2ccccc2N(c2ccc(-c3ccc4c5ccccc5n(-c5ccccc5)c4c3)cc2)c2ccccc21 ; CC(C)(C)c1ccc2c(c1)c1cc(C(C)(C)C)ccc1n2-c1ccc(-c2ccc3c(c2)C(C)(C)c2ccccc2-3)cc1 ; CC(C)(C)c1ccc2c(c1)c1cc(C(C)(C)C)ccc1n2-c1ccc(-c2ccc(N3c4ccccc4C(C)(C)c4ccccc43)cc2)cc1]

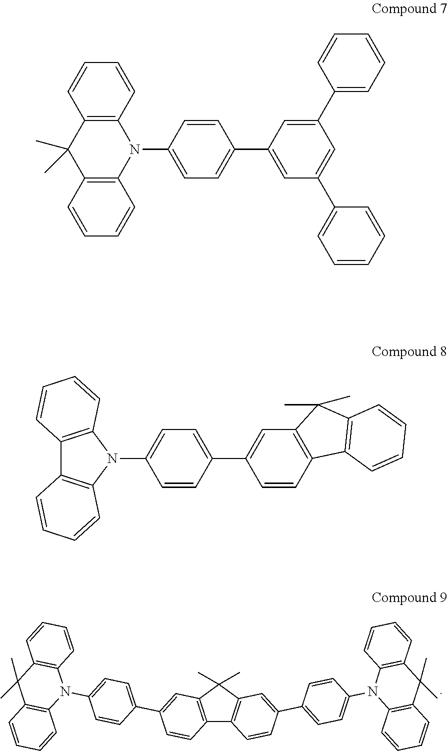

24. A compound represented by the following general formula (3):
D^{1′}-Ph¹-D¹{-L²-D²}_{n2′} General Formula (3)
wherein Ph¹ represents a phenylene group optionally substituted with an alkyl group or a halogeno group, D^{1′}, D¹ and D² each independently represent a donor group except a substituted or unsubstituted diarylamino group, provided that at least two donor groups existing in the molecule of the compound having the structure represented by the general formula (3) each have a different structure, and n2′ represents 0 or 1.

25. A compound having one of the following structures: 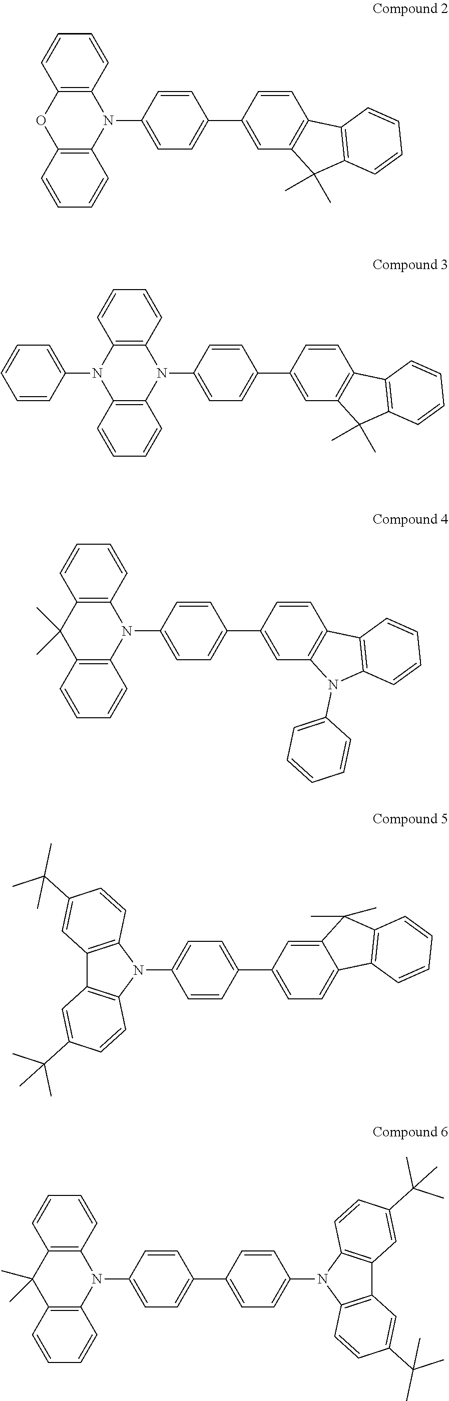 [SMILES: CC1(C)c2ccccc2-c2ccc(-c3ccc(N4c5ccccc5Oc5ccccc54)cc3)cc21 ; CC1(C)c2ccccc2-c2ccc(-c3ccc(N4c5ccccc5N(c5ccccc5)c5ccccc54)cc3)cc21 ; CC1(C)c2ccccc2N(c2ccc(-c3ccc4c5ccccc5n(-c5ccccc5)c4c3)cc2)c2ccccc21 ; CC(C)(C)c1ccc2c(c1)c1cc(C(C)(C)C)ccc1n2-c1ccc(-c2ccc3c(c2)C(C)(C)c2ccccc2-3)cc1 ; CC(C)(C)c1ccc2c(c1)c1cc(C(C)(C)C)ccc1n2-c1ccc(-c2ccc(N3c4ccccc4C(C)(C)c4ccccc43)cc2)cc1] [chemical structure]
